(19) United States
(12) Patent Application Publication
(10) Pub. No.: US 2017/0301479 A1
(43) Pub. Date: Oct. 19, 2017

(54) Photodetector

(71) Applicant: ECOLE POLYTECHNIQUE FEDERALE DE LAUSANNE (EPFL), Lausanne (CH)

(72) Inventors: Thomas MOEHL, Lausanne (CH); Mohammad Khaja NAZEERUDDIN, Ecublens (CH); Michael GRÄTZEL, Saint-Sulpice (CH); Jeong-Hyeok IM, Lausanne (CH); Nam-Gyu PARK, Gyeonggi-do (KR); Konrad DOMANSKI, Lausanne (CH)

(21) Appl. No.: 15/509,867

(22) PCT Filed: Aug. 31, 2015
(86) PCT No.: PCT/IB2015/056600

§ 371 Date: Mar. 9, 2017

(30) Foreign Application Priority Data
Sep. 10, 2014 (IB) PCT/IB2014/064406
Sep. 18, 2014 (IB) PCT/IB2014/064627
May 8, 2015 (IB) PCT/IB2015/053363

(51) Int. Cl. H01G 9/20; H01L 51/44; H01L 51/42; H01L 51/00

(52) U.S. Cl. CPC H01G 9/209; H01L 51/447; H01L 51/442; H01L 51/4253; H01L 51/006; H01G 9/2018; H01L 51/0051; H01G 9/2027; H01G 9/2022; H01L 51/0056

(57) ABSTRACT

The present invention concerns a device for room temperature reverse-bias operation photo-detection. The device comprising:—a planar first electrode extending in a planar direction;—a second electrode positioned above the first electrode in a direction substantially perpendicular to said planar direction; and—an active region sandwiched between the first and second electrode. The active region consists of a light absorbing perovskite and wherein the light absorbing perovskite is in direct contact with at least one of the first and second electrodes.

### CROSS-REFERENCE TO RELATED APPLICATIONS

This application claims the benefit of international patent application PCT/IB2014/064406 filed Sep. 10, 2014 the entire contents of which are incorporated herein by reference, of international patent application PCT/IB2014/064627 filed on Sep. 18, 2014 the entire contents of which are incorporated herein by reference and of international patent application PCT/IB2015/053363 filed on May 8, 2015 the entire contents of which are incorporated herein by reference.

### FIELD OF THE INVENTION

The present invention relates to photodetectors, in particular, low voltage high gain photo-detectors and methods for producing and operating said photodetectors. The present invention also relates to a method for amplifying a photocurrent.

### BACKGROUND OF THE INVENTION

Known photodetectors providing amplification (or gain) of the photocurrent generated by the incident light, such as avalanche photodetectors (APD) based on Silicon, require high voltages for amplification of the photocurrent, as shown in FIG. 0. The present invention addresses this problem and permits such amplification of the photocurrent to be obtained at low voltage, very much lower than those presently used in the known avalanche photodetectors.

### SUMMARY OF THE INVENTION

The inventors show that the combination of a perovskite absorber with a direct contact (or within a carrier tunneling distance) to a conductive substrate or layer (electrode) provides a very efficient photocurrent amplification at low reverse voltage bias.

The perovskite absorber of the photodetector is in direct contact with at least one or both electrodes of the photodetector.

For example, a direct contact may be formed via the deposition of the perovskite directly on an electrode and/or the deposition of an electrode directly on the perovskite. Preferably, in such a case, the electrodes comprise or consist of different materials.

Alternatively, a direct contact (or contacts) may be formed between the perovskite absorber and at least one electrode (or both electrodes) of the device via the layer(s) or material located between the perovskite and said electrode.

For, example, a transparent conductive oxide (TCO) substrate on one side paired with an electron blocking contact (or hole-transporting material (HTM)) and an evaporated metal contact on the other side of the perovskite absorber provides a very efficient photocurrent amplification at low reverse voltage bias. The present invention also provides methods for producing such low voltage high gain photodetectors, having, for example, the above mentioned structures or an inverted structure and comprising an organic-inorganic perovskite film and/or layer.

### DESCRIPTION OF THE DRAWINGS

FIG. 0 illustrates a typical gain vs reverse bias operating voltage for a Si APD;

FIG. 1 is a SEM image of a porous under-layer on an electrode (FTO);

FIG. 2a is a further SEM image of the porous under-layer illustrated in FIG. 1;

FIG. 2b is a SEM image of the exposed surface of the porous under-layer illustrated in FIGS. 1 and 2a;

FIG. 2c is a further SEM image of the exposed surface of the porous under-layer illustrated in the previous Figures;

FIG. 2d is a further SEM image of the exposed surface of the porous under-layer illustrated in the previous Figures;

FIG. 3 is a SEM image of layers of the photodetector according to the present invention;

FIG. 4 is a SEM image of layers of the photodetector according to the present invention;

FIG. 5 shows an example schema of a photodetector device according to the present invention;

FIG. 6 is a graph of the measured dark current of the presented device of FIG. 5 in which the inset shows the dark current in logarithmic scale;

FIG. 7a is a comparison of the dark and the photocurrent of a MaPbI3 based device;

FIG. 7b is a comparison of the dark and the photocurrent of a MaPbI3 based device and also includes the measured current of a similar device but having a non-porous compact under-layer;

FIG. 8 is a schema showing a porous TiO₂ under-layer (UL) infiltrated by a perovskite (P) enabling a charge transfer at this interface in reverse bias;

FIG. 9 shows a schematic of an example of a photodetector device according to the present invention;

FIG. 10(a) shows a schematic of another example of a photodetector device according to the present invention;

FIG. 10(b) shows a schematic of another example of a photodetector device according to the present invention;

FIG. 10(c) shows a schematic of another example of a photodetector device according to the present invention;

FIG. 11 shows a schematic of yet another example of a photodetector device according to the present invention;

FIG. 12(a) shows a schematic of yet another example of a photodetector device according to the present invention;

FIG. 12(b) shows a schematic of yet another example of a photodetector device according to the present invention;

FIG. 12(c) shows a schematic of yet another example of a photodetector device according to the present invention;

FIG. 13(a) shows a schematic of yet another example of a photodetector device according to the present invention relating to an inverted structure;

FIG. 13(b) shows a schematic of yet another example of a photodetector device according to the present invention relating to an inverted structure;

FIG. 14 shows a schematic of yet another example of a photodetector device according to the present invention also relating to an inverted structure;

FIG. 15 shows a schematic of yet another example of a photodetector device according to the present invention also relating to an inverted structure;

FIG. 16(a) shows a schematic of yet another example of a photodetector device according to the present invention also relating to an inverted structure;

FIG. 16(b) shows a schematic of yet another example of a photodetector device according to the present invention also relating to an inverted structure;

FIG. 16(c) shows a schematic of yet another example of a photodetector device according to the present invention also relating to an inverted structure;

FIG. 17 shows the results of a cyclic voltammetry measurements (CV) of pure FTO, a spin coated under-layer and a spray coated under-layer as well as a complete photoanode made with the spin coated under-layer in 0.5 M KCl (pH=2) with 0.5 mM [Fe(CN)6]3-/[Fe(CN)6]4-, Scan velocity: 50 mV/s; Potential vs. Ag/AgCl (sat.), the inset shows the same plot in log scale;

FIG. 18 shows data values plotted in FIGS. 7a and 7b;

FIG. 19 shows data values plotted in FIGS. 7a and 7b;

FIG. 20 shows data values plotted in FIGS. 7a and 7b;

FIG. 21 shows data values plotted in FIGS. 7a and 7b;

FIG. 22(a) shows a structure of a model device;

FIG. 22(b) shows a schematic energy diagram of the hybrid perovskite photodetector, the work function of fluorine-doped tin oxide (FTO) is not fixed and it can be changed by interface modification as well as surface treatments where cp: work function, CB: conduction band, VB: valence band, HOMO: highest occupied molecular orbital;

FIG. 22 (c) shows a dark and photocurrent density under 1 sun illumination as measured under −1 V for devices with different architectures, where the ellipses represent standard deviation, and devices with 11 different architectures and overall more than 100 devices were fabricated, where BL: blocking layer; and MP: mesoporous scaffold (see also Table S1 of Figure X);

FIG. 23(a) shows dark J-V characteristics of devices with no blocking layer (BL), 2 nm-thick atomic layer-deposited (ALD) compact BL ˜30 nm-thick spin-coated porous BL(UL 5), with ˜30 nm-thick spray-pyrolized compact one;

FIG. 23(b) shows J-V characteristics of a champion device (without a blocking layer) in the dark and under simulated 1-Sun illumination, Scan rate: 200 mV s^{-1;}

FIG. 24 shows the optoelectronic response of the perovskite photodetector, in which FIG. 24(a) shows the IPCE of the perovskite photodetector (the inset in logarithmic scale); FIG. 24(b) shows the responsivity at short-circuit conditions and under −0.6 V reverse bias, the inset shows the gain spectrum of the photodetector; FIG. 24(c) shows the photocurrent and responsivity dependence on light intensity, where the lines are fits to a power law; and FIG. 24(d) shows the dependence of saturation intensity and linear dynamic range (LDR) on the operating voltage;

FIG. 25 shows a light-transient response of the perovskite photodetector, where FIG. 25(a) shows a transient current response to 60 s-long, 0.53 mW cm⁻²-pulses of 550 nm light under different reverse bias where the steady-state dark currents are subtracted for each bias; FIG. 25(b) shows a transient current response normalized to the steady-state value at 60 s; FIG. 25(c) shows an integrated charge flowing after light is switched-off and FIG. 25(d) shows the dependence of responsivity on operating bias: under 0.53 mW cm⁻²-illumination and under illumination within linear dynamic range; the inset is in logarithmic scale;

FIG. 26 shows light intensity-dependent J-V characteristics of the perovskite photodetector, where the inset shows the results in logarithmic scale, Scan rate: 10 mV s⁻¹;

FIG. 27(a) shows the effect of the scan rate on the J-V hysteresis of the photodetector (illumination: 550 nm, 530 μW cm⁻²), where the inset shows a schematic voltage transient;

FIG. 27(b) shows the response of the device when the potential is step-changed from V_{oc} to −1 V for different light intensities and normalized to the steady-state photocurrent at 60 s;

FIG. 27(c) shows J-V characteristics of the detector following 60 s of pre-conditioning at different potentials; illumination: 0.72 mW cm⁻² for −1 V- and 0.53 mW cm⁻² for 0 V-pre-conditioned data, dJ/dV is found constant between −1 V and −0.6 V in forward scan;

FIG. 27(d) presents the dJ/dV in the linear region as a function of illumination intensity when the detector is pre-conditioned at −1 V for 60 s, the linearity of conductivity with light intensity indicates photoconductive behavior;

FIG. 28 shows the effect of temperature on the behavior of perovskite photodetector, and a transient response of the device when the potential is step-changed from V_{oc} to −1 V at different temperatures normalized to current value at 40 s, where FIG. 28(a) is in the dark, FIG. 28(b) is under 0.53 mW cm⁻² illumination, and FIG. 28(c) is the corresponding decay time constants erdecay) of the transient data fitted to equation (3), and FIG. 28(d) is the scan rate- and temperature-dependent J-V characteristics of the detector under 1 mW cm⁻² illumination; scan rates are selected to visualize the similarity of J-V curves measured at an approx. 3 times lower rate when the temperature was decreased by 20 K;

FIG. 29 shows the emergence of transient behavior when the device is kept in the dark and it is subjected to a step-change in potential; where FIG. 28 (a) showing that immediately after applying reverse bias, no current flows through the device since the work function of FTO is too low for hole injection; FIG. 28(b) shows ions traveling to FTO/perovskite interface downshifting FTO work function and enabling hole injection into perovskite; FIG. 28(c) shows that as ions accumulate at the interface, they screen the electric field, which results in the decrease of the current; where red charges represent the electric charges on electrodes, green—mobile ions and blue—holes injected from FTO and the current-time, as well as the distribution of the ions plots are schematic where FTO: fluorine-doped tin oxide;

FIG. 30 shows a transmittance spectrum of a perovskite photodetector, the absorption edge of the detector is found around 780 nm (1.59 eV);

FIG. 31 shows the photo-response of the photodetector at short circuit conditions under different illumination wavelengths, where the measurement at 100 mW cm⁻² was done under white LED light;

FIG. 32 illustrates the On-off dynamics of the perovskite photodetector, with Illumination: 0.53 mW cm⁻² , 550 nm monochromatic light;

FIG. 33 shows the response of the device when the potential is step-changed from V_{oc} to −1 V for different light intensities, normalized to the steady-state photocurrent; where recorded data and fits to the equation (S1) are presented;

FIG. 34 shows time constants of current rise and decay (equation (S1)) as a function of illumination intensity;

FIG. 35 shows the transient response of the device when the potential is step-changed from V_{oc} to −1 V at different temperatures, where FIG. 35(a) is in the dark, and FIG. 35(b) is under 0.53 mW cm⁻² illumination, recorded data and fits to the equation (S1) are presented;

FIG. 36 shows time constants of current rise and decay (equation (S1)) as a function of temperature;

FIG. 37 shows scan rate- and temperature-dependent J-V characteristics of the detector under 1 mW cm⁻² illumination, scan rates are selected to visualize the similarity of J-V curves measured at an approx. 3 times lower rate when the temperature was decreased by 20 K;

FIG. 38 shows the specific conductivity of Spiro-MeOTAD as a function of temperature, the thickness of this film was unknown;

FIGS. 39(a) and (b) presents the experimental conditions and dark and photocurrent densities measured under −1 V potential for samples shown in FIG. 23, where photocurrent was measured under 100 mW cm⁻² white LED light, Scan rate: 200 mV

FIG. 40 shows a table containing a summary of the prepared structures of the photodetector according to the present invention;

FIG. 41 shows current-voltage characteristics of a device of type S1 with a porous TiO₂ under-layer;

FIG. 42 shows current-voltage characteristics of a device of type S1 with a porous TiO₂ under-layer dipped in a solution of TiCl₄;

FIG. 43 shows current-voltage characteristics of a device of type S2 with a TiO₂ surface increasing scaffold;

FIG. 44 shows a current-voltage characteristics of a device of type S2 with a TiO₂ surface increasing scaffold dipped in a solution of TiCl₄;

FIG. 45 shows current-voltage characteristics of a device of type S2 with a Al₂O₃ surface increasing scaffold;

FIG. 46 shows the current-voltage characteristics of the device of type S3 with the perovskite absorber prepared by spin coating of mixture of perovskite precursors;

FIG. 47 shows the current-voltage characteristics of the device of type S3 with the perovskite absorber prepared by sequential spin coating of perovskite precursors;

FIG. 48 shows current-voltage characteristics of the device of type S3 with the perovskite absorber prepared by evaporation of perovskite precursors;

FIG. 49 shows the current-voltage characteristics of the device of type S4; and

FIG. 50(a) shows a schematic of another example of a photodetector device according to the present invention and FIG. 50(b) shows the current-voltage characteristics of the device of FIG. 50(a).

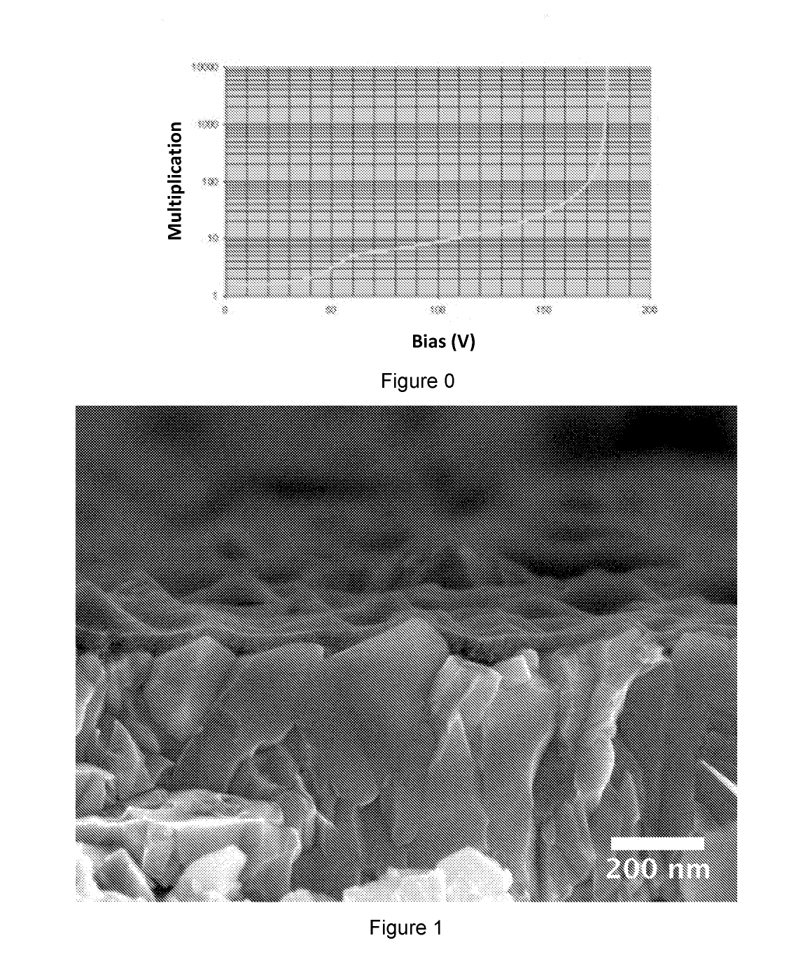

### DETAILED DESCRIPTION

The present invention concerns photodetectors having a non-conventional design and architecture, in particular low voltage high gain/amplification photodetectors as well as a new method for producing said photodetectors.

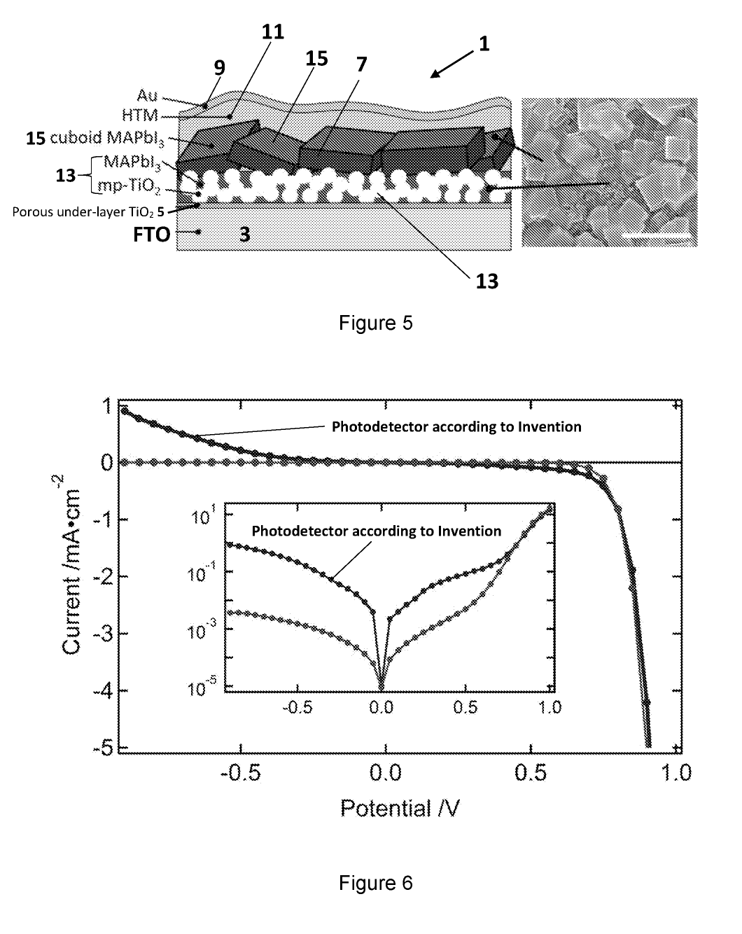

FIG. 5 and FIGS. 9 to 16 illustrate a schematic of examples of a device or photodetector according to the present invention. Photodetectors according to the present invention will now be described with particular reference to these Figures.

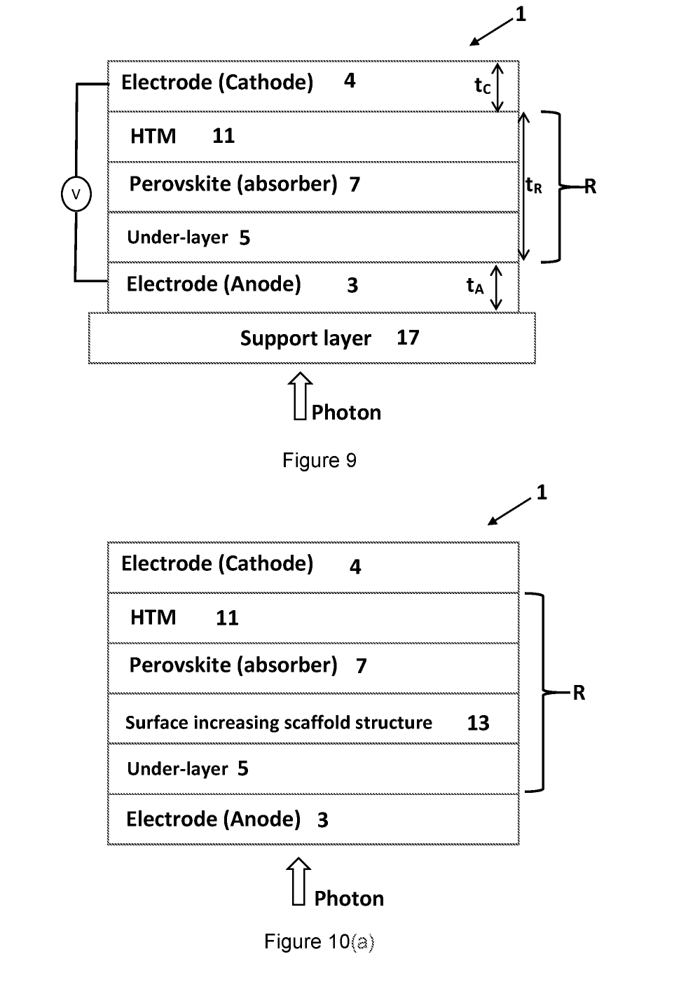

The device 1 according to the present invention is a reverse-bias operation and photo-detection device. The device 1 includes a first electrode 3 and a second electrode 4 sandwiching an active or intermediate region R (see FIGS. 9 to 16).

The layers or elements of the device 1 are superposed one upon another. The first electrode 3, the second electrode 4 and the active region R (see FIGS. 9 to 16) are superposed one upon another. That is, for example, the second electrode is placed or positioned above and upon the active region R and the active region R is placed or positioned above and upon the first electrode.The layers or elements of the active region R may also be are superposed one upon another.

The device 1 of the present invention operates for example at room temperature, for example, at approximately 21° C. or in the range between 20 and 26° C.

Nevertheless, the device 1 also operates at other temperatures different to a room temperature of 21° C. and outside in the range between 20 and 26° C.

The device 1 has a planar structure. The first electrode and the active region R extend in directions substantially parallel to their interface to each define a planar layer. The second electrode extends in directions substantially parallel to its interface with the active region R to also define a planar layer.

The first electrode, the second electrode and the active region R have a thickness t extending along a first direction (see FIG. 9 for example). This direction, for example, substantially corresponds to a direction of the incident light to be detected or measured by the device 1.

The first electrode, the second electrode and the active region R each extend in a second direction defining a length and a third direction defining a width respectively of the first electrode, the second electrode and the active region R. The second direction and the third direction define a plane or planar layer that extends substantially perpendicular to said first direction (thickness). The planar second and third directions are substantially perpendicular.

In general, the thickness t of the first electrode is smaller than the length and width of the first electrode. This is also the case for the second electrode, the active region R as well as each constituent layer of the active region R.

As can be seen in the Figures, the planar first electrode extends in the planar direction and the second electrode is positioned above or below the first electrode at a position located in a direction substantially perpendicular to said planar direction. That is, the second electrode is displaced with respect to the first electrode in a direction of the device thickness and in a direction perpendicular to the plane defined by the first electrode. The active region is sandwiched between the first and second electrode.

The incident light to be detected or measured is incident on the device and enters the device through the first and second electrode and passes through the superposed layers of the device and active region R to be aborbed in a perovskite layer.

The active region R directly contacts only one electrode or both electrodes because a direct contact is formed via the provision or deposition of the perovskite directly on the first electrode and/or the provision or deposition of a second electrode directly on the perovskite. Preferably, in such a case, the electrodes comprise or consist of different materials or the electrodes comprise or consist of materials having different work functions.

Alternatively, a direct contact (or contacts) may be formed between the perovskite absorber and at least one electrode (or both electrodes) of the device via the layer(s) or material located between the perovskite and said electrode. That is, via some or all of the elements or layers of the active region R.

The layer (element) or layers (elements) of device 1 located between the perovskite absorber and the first and/or second electrode includes a plurality of charge carrier conducting channels or a network of charge carrier conducting channels that form a direct contact or a plurality of direct contacts between the perovskite absorber and the electrode.

For example, in an non-inverted architecture, the active region comprise a light absorbing perovskite layer and an additional layer located between the absorbing perovskite layer and one of the first or second electrodes, the additional layer including a plurality of hole conducting channels or a network of hole conducting channels inside the additional layer permitting a direct contact with said at least one first or second electrode.

The device of the present invention may function in photoconductive mode.

According to an exemplary first embodiment of the present invention (see for example FIG. 9), the photodetector 1 comprises the first electrode 3 for receiving a first carrier type, the second electrode 4 for receiving a second carrier type, and the active region R comprising or consisting solely of an under-layer 5 provided on (for example, directly in contact with) the first electrode, a perovskite (absorber layer) 7 provided above or on (for example, directly in contact with) the under-layer 5, and a second carrier transporting material 11 provided between the second electrode 4 and the perovskite 7.

The first electrode 3 is for example an anode electrode and the second electrode 4 is for example a cathode electrode.

The under-layer 5 includes a plurality of second carrier conducting channels or a network of second carrier conducting channels inside the under-layer 5, the plurality of second carrier conducting channels or the network of second carrier conducting channels being in electrical communication with the first electrode 3 and the perovskite 7 to permit second carrier conduction between the first electrode 3 and the perovskite 7 via the plurality of second carrier conducting channels or the network of second carrier conducting channels.

The under-layer 5 can also further include a plurality of first carrier conducting channels or a network of first carrier conducting channels inside the under-layer 5, the plurality of first carrier conducting channels or the network of first carrier conducting channels being in electrical communication with the first electrode 3 and the perovskite 7 to permit first carrier conduction between the first electrode 3 and the perovskite 7 via the plurality of first carrier conducting channels or the network of first carrier conducting channels.

The first carrier conducting channels permit only the first carriers to be conducted and not the second carrier type. The second carrier conducting channels permit only the second carriers to be conducted and not the first carrier type. For example, the first carrier type can be electrons and the second carrier type can be holes.

More particularly, the photodetector 1 comprises an anode electrode (electron collecting electrode) 3, an under-layer 5, a perovskite (absorber layer) 7 provided above or on the under-layer 5, a cathode electrode (hole collecting electrode) 4, a hole-transporting material 11 provided between the cathode electrode 4 and the perovskite 7. The under-layer 5 includes a plurality of hole conducting channels or a network of hole conducting channels inside the under-layer 5, the plurality of hole conducting channels or the network of hole conducting channels being in electrical communication with the anode electrode 3 and the perovskite 7 to permit hole conduction between the anode electrode 3 and the perovskite 7 via the plurality of hole conducting channels or the network of hole conducting channels.

At least one of the plurality of hole conducting channels, or the plurality of hole conducting channels, or the network of hole conducting channels includes the perovskite 7, or the perovskite and perovskite preparation elements inside the channels and the perovskite 7 directly physically contacts the anode electrode 3 to form a rectifying contact with the anode electrode 3, or a perovskite preparation element directly physically contacts the anode electrode 3 to form a rectifying contact with the anode electrode 3.

Alternatively, at least one of the plurality of hole conducting channels, the plurality of hole conducting channels, or the network of hole conducting channels includes the perovskite 7, or the perovskite 7 and perovskite preparation elements inside the channels and the perovskite 7 is located at least within a carrier tunnelling distance of the anode electrode 3, or a perovskite preparation element is located at least within a carrier tunnelling distance of the anode electrode 3.

The under-layer 5 is porous and is a layer or structure including a plurality of pores. The under-layer 5 comprises a (solid) body, the body defining the plurality of pores. The plurality of pores are present entirely throughout the layer, from the upper surface facing the perovskite 7 to the bottom surface facing the electrode 3.

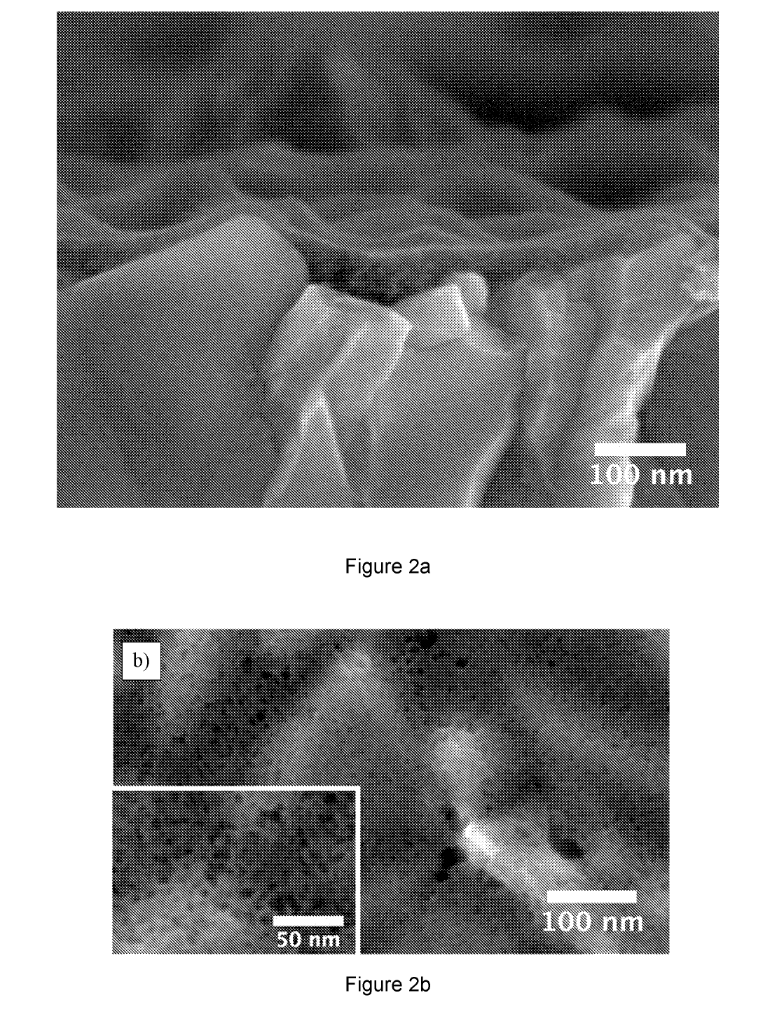

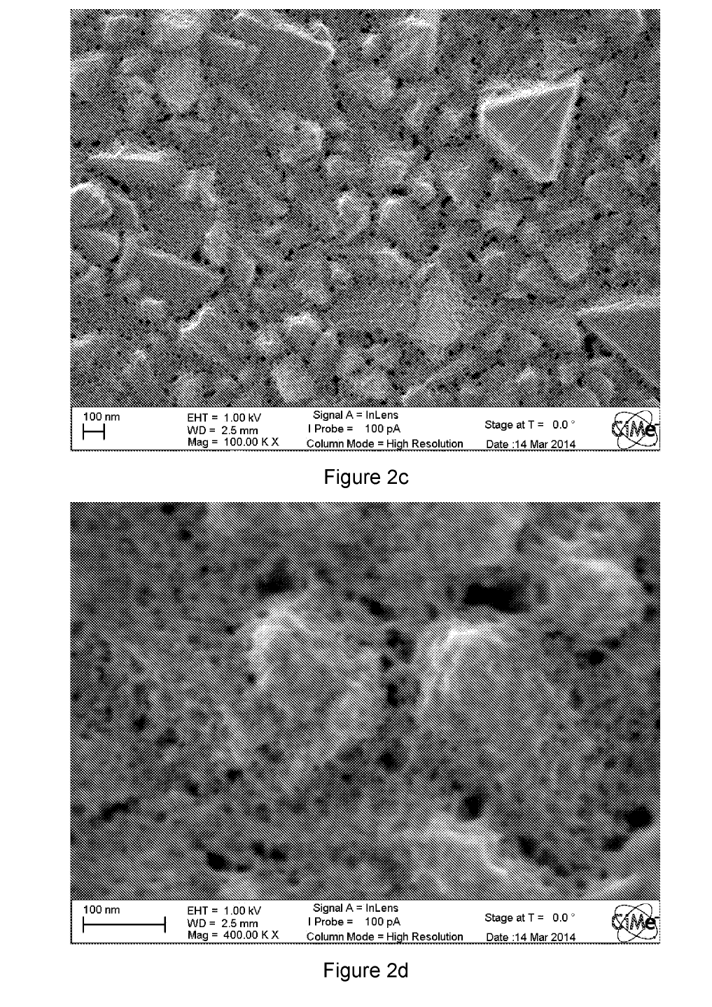

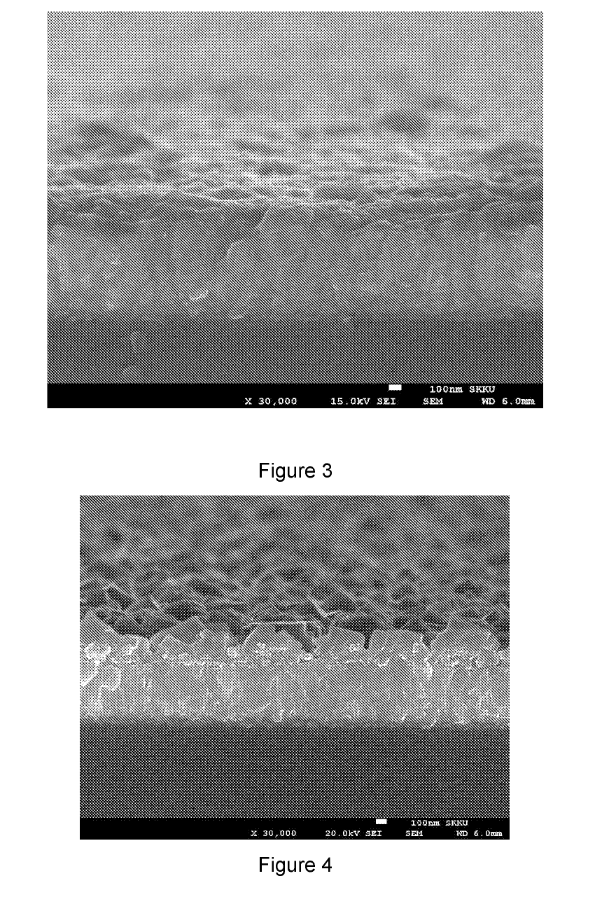

The under-layer 5 comprises a plurality of pores interconnected via a body portions (or body portions) of irregular shape. The under-layer 5 comprises a plurality of pores of irregular shape and body portions of irregular shape. The pores are interconnected via the irregular shaped body portions. The pores vary in size or opening and the body portions vary in size or distance interconnecting two pores (as can be seen, for example, in FIG. 2c).

The under-layer 5 has, for example, the form, shape or structure of a sponge.

The size or opening S of the pores are 100 nm or less, or 50 nm≧size S≧2 nm or 2 nm≧size S≧0.2 nm.

The pore size or opening S is measured using SEM and corresponds to the width of a pore at its widest points for a cross-sectional measurement taken, for example, after deposition of the under-layer 5, for example, on the electrode 3 (that is a measurement taken on the surface of the under-layer 5 after deposition or after removal of the upper device layers).

The under-layer 5 includes pores of size or opening S that are 100 nm or less as well as pores of size or opening S of 50 nm≧size S≧2 nm.

The under-layer 5 includes pores of size or opening S that are 100 nm or less as well as pores of size or opening S of 2 nm≧size S≧0.2 nm.

The under-layer 5 includes pores of size or opening S that are 50 nm≧size S≧2 nm as well as pores of size or opening S of 2 nm≧size S≧0.2 nm.

The under-layer 5 includes pores of size or opening S that are 50 nm≧size S≧2 nm and pores of size or opening S of 2 nm≧size S≧0.2 nm and pores of size or opening S that are 100 nm or less.

A conducting channel of the under-layer 5 is formed by a plurality of pores comprising the perovskite or the perovskite and perovskite preparation elements.

At least one hole conducting channel, or the plurality of hole conducting channels or the network of hole conducting channels are formed in a plurality of said pores. All of the pores may be forming the plurality of hole conducting channels or the network of hole conducting channels, or only part of the plurality of pores may be forming the plurality of hole conducting channels or the network of hole conducting channels.

A plurality of pores are filled or partially filled by the perovskite or the perovskite and perovskite preparation elements.

A conducting channel is formed via a plurality of pores that are filled and in electrical communication with each other and running through under-layer 5 to form a conducting channel from the perovskite side of under layer 5, through under-layer 5, to the electrode 3 side of the under-layer 5.

The filled pores may be in direct electrical or physical contact, or may be within a carrier tunnelling distance thus also permitting electrical conduction. The pores containing the perovskite or the perovskite and perovskite preparation elements form (perovskite) wires that are in direct electrical or physical contact with each other, or that are within a carrier tunnelling distance of each other permitting electrical conduction from the perovskite 7 to electrode 3.

The electrode hole blocking structure or layer 5 includes a plurality of conducting (perovskite or, perovskite and perovskite preparation elements) nano-wires or a network of conducting (perovskite, or perovskite and perovskite preparation elements) nano-wires.

The under-layer 5 is a non-compact structure or layer or is compact structure-less or compact layer-less.

The porous under-layer 5 is deposited from a metal precursor solution. The under-layer 5 can be a metal oxide under-layer 5 made of conducting metal oxides such as TiO₂, ZnO or SnO₂ but also nonconductive layers like Al₂O₃ or ZrO₂ can be applied. In a further embodiment, the porous under-layer 5 comprises one or more materials being selected from [6,6]-phenyl-C₆₁-butyric acid methyl ester (PCBM), 1,4,5,8,9,11-hexazatriphenylene-hexacarbonitrile (HAT-CN), (C₆₀-Iₕ)[5,6]fullerene (C60), (C70-D5h)[5,6]fullerene (C70), [6,6]-Phenyl C₇₁ butyric acid methyl ester (PC70BM), 2,9-dimethyl-4,7-diphenyl-1,10-phenanthroline (BCP), 1,3,5-tri(phenyl-2-benzimi-dazolyl)-benzene (TPBI), preferably PCBM, HAT-CN, C60, C70, PC70BM, and metal oxide. The metal oxide is an oxide of a metal selected from a group of metals consisting of: Ti, Sn, Cs, Fe, Zn, W, Nb, SrTi, Si, Ti, Al, Cr, Sn, Mg, Mn, Zr, Ni, and Cu.

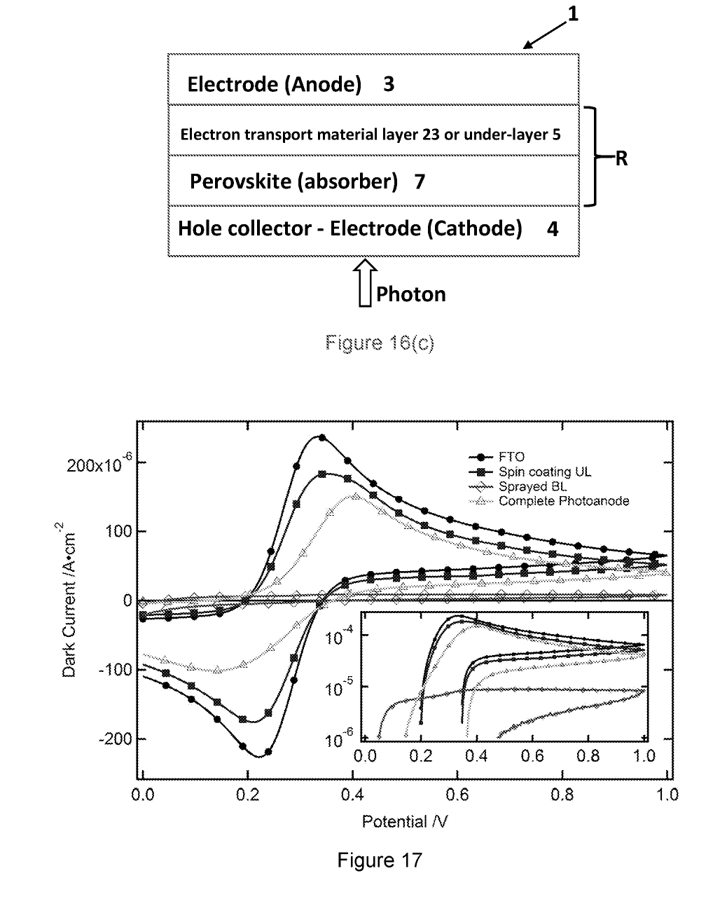

In order to demonstrate the porous nature of the under-layer 5 of the present invention, two types of deposition techniques for a TiO₂ under-layer were carried out and compared: (i) spray pyrolysis of titanium diisopropoxide bis(acetylacetonate) (TAA) and (ii) spin coating of a TiO₂ precursor solution (also from TAA) onto FTO (electrode 3). These layers have been analyzed by cyclic voltammetry CV (the results of which are shown in FIG. 17), and in complete devices.

The layer made by the spin coating had a thickness of about 40 nm and forms porous structure on top of the FTO. In contrast the layer made by spray pyrolysis is thinner and shows a compact composition.

One would expect a rather low blocking ability for the spin coated sample. Therefore cyclic voltammetry measurements in aqueous electrolyte were performed to test the blocking efficiency towards charge transfer reactions at the FTO (TiO₂)/electrolyte interface. The electrolyte contains a one electron redox system which can react with FTO but not with TiO₂. In FIG. 17 the cyclic voltammograms of the different electrodes are presented. One can clearly see how the charge transfer at the FTO is greatly reduced for the deposition of the sprayed TiO₂ layer (blocking layer BL). In contrast, for the spin coated under-layer (UL) there is a significant amount of current flowing, indicating that vast areas of the FTO are exposed directly to the electrolyte.

The spin coated under-layer UL for a photoanode PA in a device is further treated during the fabrication process. The additional deposition of a mesoporous TiO₂ (scaffold structure) and a TiCl₄ treatment could lead to a further blocking ability of the PA (while on the other hand the heating steps may reduce it). Therefore we also conducted a CV test on a PA with the spin coated UL, the mesoporous TiO₂ and subsequent TiCl₄ treatment as well as the necessary heat treatments. As visible in FIG. 17 this further treatment steps have only a small effect on the blocking capability (lack off) of the under-layer, reducing the peak current and increasing the peak to peak distance but the PA clearly does not possess a valid blocking layer for the charge transfer reaction in contrast to the sprayed samples. The above measurements demonstrate that this under-layer UL is a porous under-layer and a porous under-layer in the photodetector according to the present invention.

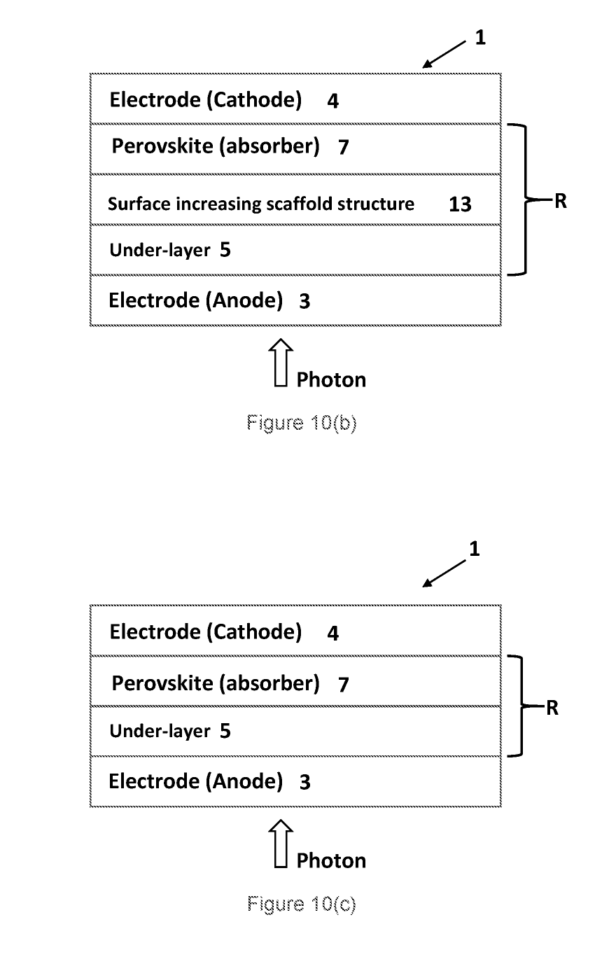

According to a second embodiment, the photodetector and more particularly the active region R includes or in addition to the elements of the active region R of FIG. 9 consists of a surface increasing scaffold structure 13 located between the under-layer 5 and the perovskite 7 (see, for example, FIGS. 10(a) and 5), wherein the perovskite 7 or perovskite preparation elements is/are provided on the surface increasing scaffold structure 13 and the perovskite 7 or perovskite preparation elements infiltrate through the surface increasing scaffold structure 13 to form a plurality of hole conducting channels or a network of hole conducting channels in and through the surface increasing scaffold structure 13, and also infiltrate the under-layer 5 so as to form the plurality of hole conducting channels or said network of hole conducting channels in the under-layer 5. The surface increasing scaffold structure 13 thus includes a plurality of passages formed or delimited by a skeleton structures through which the perovskite 7 or perovskite preparation elements pass to reach the under-layer 5. According to a third embodiment, this photodetector includes or the active region R in addition to the elements of the active region R of FIG. 10 consists of a further perovskite (absorber layer) 15 is formed on the surface increasing scaffold structure 13 (see for example, FIG. 5) after deposition of previous perovskite 7. The further perovskite layer 15 can be different to the preceding deposited perovskite layer. Indeed, this can be carried out in the case of any of the embodiments and the active region R of anyone of the embodiments mentioned herein can, in addition to the elements of the active region R mentioned in these embodiments consists of having this further perovskite layer 15.

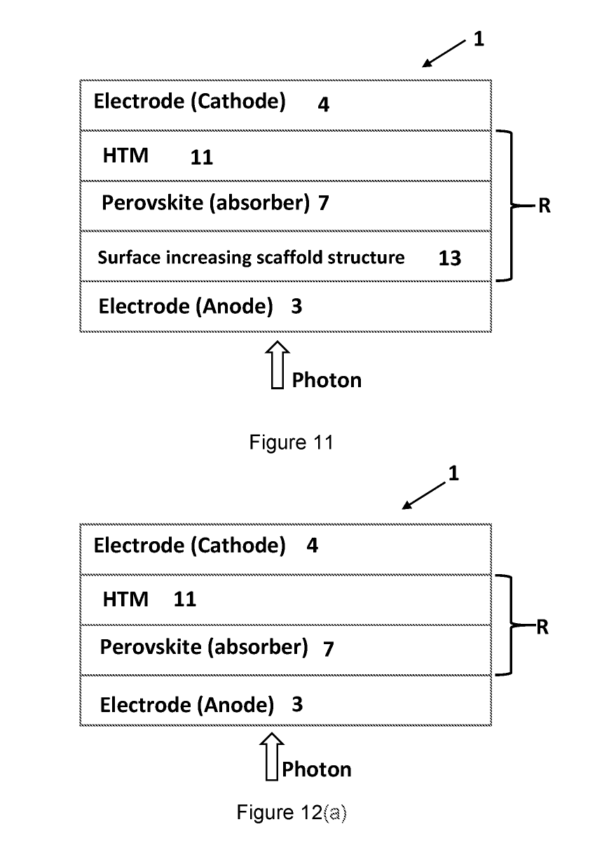

According to a fourth embodiment, the photodetector according to the second or third embodiment does not include under-layer 5 (see for example, FIG. 11). The photodetector 1 comprises a first electrode 3, a second electrode 9 and an active region R. The active region R includes or consists solely of: a surface increasing scaffold structure 13, a perovskite 7 provided on the surface increasing scaffold structure 13 and infiltrated through the surface increasing scaffold structure 13 and a hole-transporting material 11 provided between the cathode electrode 4 and the perovskite 7.

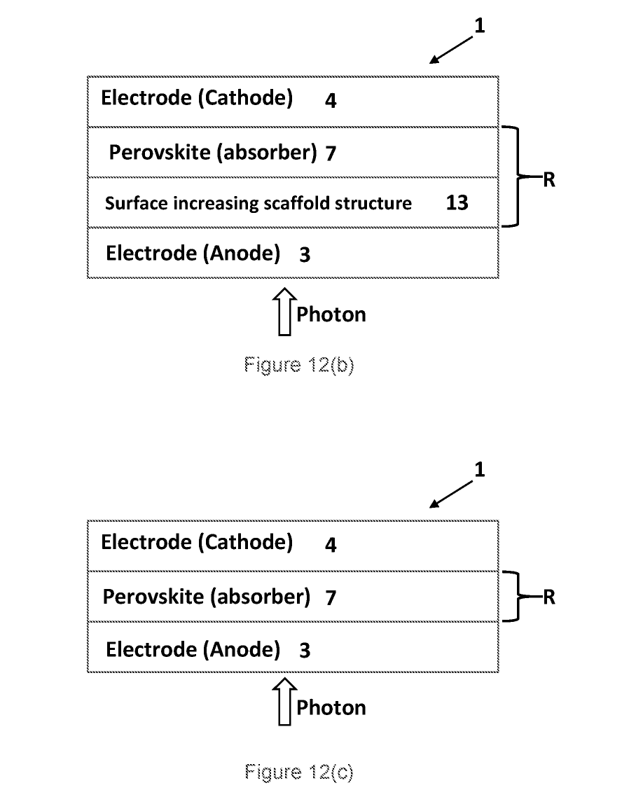

According to a fifth embodiment, the photodetector according to the first embodiment does not include under-layer 5 (see for example, FIG. 12(a)). The photodetector 1 comprises a first electrode 3, a second electrode 4 and an active region R. The active region R includes or consists solely of: a perovskite 7 provided on the anode electrode 3, and a hole-transporting material 11 provided between the cathode electrode 4 and the perovskite 7.

All photodetector embodiments can optionally include a support layer 17 upon which the previously mentioned layers and structures are provided or deposited. The support layer 17 is further detailed below.

According to a sixth embodiment, (see for example, FIG. 10(b)). The photodetector 1 comprises a first electrode 3, a second electrode 4 and an active region R. The active region R includes or consists solely of an under layer 5 provided on the first electrode 3, a surface increasing scaffold structure 13 provided on the under-layer 5 and a perovskite 7 provided on the surface increasing scaffold structure 13 and between the electrode 4 and the surface increasing scaffold structure 13.

According to a seventh embodiment, (see for example, FIG. 10(c)). The photodetector 1 comprises a first electrode 3, a second electrode 4 and an active region R. The active region R includes or consists solely of an under layer 5 provided on the first electrode 3 and a perovskite 7 provided on the under layer 5 and between the electrode 4 and the under layer 5.

According to an eight embodiment, (see for example, FIG. 12(b)). The photodetector 1 comprises a first electrode 3, a second electrode 4 and an active region R. The active region R includes or consists solely of a surface increasing scaffold structure 13 provided on the first electrode 3 and a perovskite 7 provided on or in the surface increasing scaffold structure 13 and between the electrode 4 and the surface increasing scaffold structure 13.

According to a ninth embodiment, (see for example, FIG. 12(c)). The photodetector 1 comprises a first electrode 3, a second electrode 4 and an active region R. The active region R includes or consists solely of a perovskite 7 between the second electrode 4 and the first electrode 3.

For each of the above photodetectors, when in use, a reverse-bias voltage applied to the first and second electrodes produces a high photocurrent amplification or gain at low voltage. The photodetector 1 is a high gain, low voltage photodetector.

The photodetectors produce, for example, a light photocurrent multiplication of at least 2 (gain of 1) for an applied reverse bias voltage at −0.55 V compared to 0.05 V, and a light photocurrent multiplication of at least 6 (gain of 5) for an applied reverse applied voltage at −0.9 V compared to −0.05 V.

The present invention also relates to a device including a photodetector according to any of the previous embodiments and a voltage source connected in reverse bias to the anode electrode and the cathode electrode. The voltage source is applying a reverse bias to the device. The voltage source is applying, for example, a reverse bias between −0.01 V and −0.9 V to produce a light photocurrent multiplication of at least 2 for an applied reverse bias voltage at −0.55 V compared to 0.05 V, and a light photocurrent multiplication of at least 6 for an applied reverse applied voltage at −0.9 V compared to −0.05 V.

The present invention also concerns the use of the device 1 according to any of the previous embodiments to make a high gain, low voltage photodetector.

The present invention also concerns the use of the device 1 according to any of the previous embodiments as a high gain, low voltage photodetector.

The present invention also concerns the use of the device 1 according to any of the previous embodiments to amplify, a light photocurrent at low voltage.

The present invention also concerns a method for producing a photodetector comprising the steps of: providing the device 1 according to any of the previous embodiments, and applying a reverse-bias voltage to said device 1 to produce a high gain factor at low voltage. The reverse-bias voltage applied produces, for example, a light photocurrent multiplication of at least 2 for an applied reverse bias voltage at −0.55 V compared to 0.05 V, and a light photocurrent multiplication of at least 6 for an applied reverse applied voltage at −0.9 V compared to −0.05 V.

The present invention also concerns a method of operation of a photodetector comprising the steps of: providing the device 1 according to any of the previous embodiments, and applying a reverse-bias voltage to said device 1 to produce a high gain at a low voltage. The reverse-bias voltage applied to said photodetector produces, for example, a light photocurrent multiplication of at least 2 for an applied reverse bias voltage at −0.55 V compared to 0.05 V, and a light photocurrent multiplication of at least 6 for an applied reverse applied voltage at −0.9 V compared to −0.05 V.

The present invention also concerns a method of fabricating a photodetector comprising the steps of: providing the device 1 according to any of the previous embodiments, and fixing or attaching reverse-bias voltage terminals to said device 1 for reverse-bias voltage operation.

The present invention also concerns a method for amplifying a photocurrent comprising the steps of: providing the device 1 according to any of the previous embodiments, and applying a reverse-bias voltage to said device 1. The reverse-bias voltage applied to said device produces for example a light photocurrent multiplication of at least 2 for an applied reverse bias voltage at −0.55 V compared to 0.05 V, and a light photocurrent multiplication of at least 6 for an applied reverse applied voltage at −0.9 V compared to −0.05 V.

An exemplary method of fabricating a photodetector according to the first embodiment comprises the steps of: providing an anode or first electrode 3, providing an under-layer 5 on the anode electrode 3, providing a perovskite 7 on the under-layer 5, providing a cathode or second electrode 4, providing a hole-transporting material 11 between the cathode electrode 4 and the perovskite 7, and including, in the under-layer 5, a plurality of hole conducting channels or a network of hole conducting channels inside the under-layer, the plurality of hole conducting channels or the network of hole conducting channels being in electrical communication with the anode electrode 3 and the perovskite to permit hole conduction between the anode electrode 3 and the perovskite 7 via the plurality of hole conducting channels or the network of hole conducting channels.

Exemplary methods for producing the different constituent layers or elements of the device 1 of the different embodiments is now described, in particular, with reference to the device 1 of the first embodiment (FIG. 9). An exemplary method for producing an under-layer 5 according to the present invention and as used in the above mentioned embodiments is now described. In this example, the under-layer 5 is a TiO₂ under-layer provided on a chemically etched FTO glass (first electrode 3). Pre-etched FTO glasses 3 (Nippon Sheet Glass, NSG 10Ω) were cleaned in an ultrasonic bath containing ethanol for 30 min and was then treated in UV/Ozone cleaner for 30 min. TiO₂ under-layer 5 was spin-coated on FTO glasses at 2000 rpm for 20 s using 0.15 M titanium diisopropoxide bis(acetylacetonate) (75 wt. % in isopropanol, Aldrich) in 1-butanol (99.8 %, Aldrich) solution. Afterwards the coated FTO was heated at 125° C. for 5 min.

Concerning, for example, the device 1 according to the second embodiment (FIG. 10(a)), upon the under-layer 5 deposited on a fluorine doped tin oxide (FTO) layer 3, a 350 nm-thick mesoporous TiO₂ layer (surface increasing scaffold structure 13) was made with Dyesol 18-NRT paste (particle size: ˜20 nm; diluted with ethanol, 1:3.5 weight ratio) by spin coating at 5,000 rpm for 30 sec and heating at 500° C. for 30 min to burn organic components. The method for producing a photodetector or device 1 according to the first embodiment (FIG. 9) is identical to the second embodiment but does not include the above step of depositing the surface increasing scaffold structure 13.

To form the perovskite 7, for the deposition of methylammonium lead iodide (perovskite preparation element), 1.0 M of lead iodide solution in N,N-dimethylformamide kept at 70° C. was firstly spin coated at 6,500 rpm for 30 sec on the under-layer 5 or the surface increasing scaffold structure 13 and then dried at 70° C. for 15 min.

After cooling to room temperature, the film was immersed in a solution of methylammonium iodide (perovskite preparation element) in isopropanol (8 mg ml⁻¹) for 20 sec, shortly rinsed with isopropanol and dried again at 70° C. for 15 min.

The device 1 produces low voltage reverse bias photocurrent amplification perovskite deposition methods.

The hole transfer material HTM 11 solution was prepared by dissolving 72.3 mg of spiro-MeOTAD, 28.8 uL of 4-tert-butylpyridine (TBP, Aldrich), 17.5 uL of a stock solution of 520 mg/mL of lithium bis(trifluoromethylsulphonyl)imide in acetonitrile and 29 uL of a stock solution of 300 mg/mL of tris(2-(1H-pyrazol-1-yl)-4-tert-butylpyridine)cobalt(III) bis(trifluoromethylsulphonyl)imide in acetonitrile in 1 mL of chlorobenzene. This solution was spin-coated at 4,000 rpm for 30 sec before deposition of 60 nm-thick gold counter second electrode 4 by evaporation method.

With respect to the photodetector or device 1 according to the second embodiment (FIGS. 5 and 10(a)), an exemplary deposition step of the surface increasing scaffold structure 13 has been set out above and further embodiments of this deposition step and material is set out later below. The surface increasing scaffold structure 13 is deposited on the under-layer 5 with the perovskite 7 deposition and following steps being the same as mentioned above for the first embodiment.

In relation to the third embodiment, a further perovskite layer (not necessarily the same) can be deposited on perovskite 7.

Concerning the fourth embodiment (FIG. 11), the formation of the photodetector or device 1 is also similar to that of the first embodiment but the surface increasing scaffold structure 13 is deposited directly on the electrode (FTO) 3 and the under-layer 5 deposition step is omitted.

In relation to the fifth embodiment (FIG. 12(a)), the perovskite 7 is formed directly on the electrode (FTO) 3 as previously indicated above with respect to embodiment 1 and following process steps are the same as mentioned above for the first embodiment.

In relation to the sixth embodiment (FIG. 10(b)), the device 1 of this embodiment is produced in a similar manner to that of embodiment 2 with the preparation step of the HTM 11 being omitted and the second electrode 4 being deposited directly on the perovskite 7.

Concerning the seventh embodiment (FIG. 10(c)), the device 1 of this embodiment is produced in a similar manner to that of embodiment 1 with the preparation step of the HTM 11 being omitted and the second electrode 4 being deposited directly on the perovskite 7.

In relation to the eight embodiment (FIG. 12(b)), the device 1 of this embodiment is produced in a similar manner to that of embodiment 2 with the preparation step of the under-layer 5 being omitted so that the surface increasing scaffold structure 13 is deposited directly on the first electrode 3. The preparation step of the HTM 11 is also omitted and the second electrode 4 being deposited directly on the perovskite 7.

Concerning the ninth embodiment (FIG. 12(c)), the device 1 of this embodiment is produced by depositing a perovskite layer 7 as set out with respect to embodiment 1 but directly on the first electrode 3 and the second electrode 4 being deposited directly on the perovskite 7.

The present invention also concerns a device 1 or a low voltage photodetector obtainable or obtained by the above mentioned fabrication method.

FIG. 6 shows for example the measured dark current of the above fabricated device (FIG. 10(a)). In reverse bias at 900 mV the current is in the range of 1 mA/cm². For comparison, the measured dark current of a similar device but having a non-porous compact under-layer 5 is presented where the current at 900 mV reverse bias is much smaller and close to 0 mA/cm².

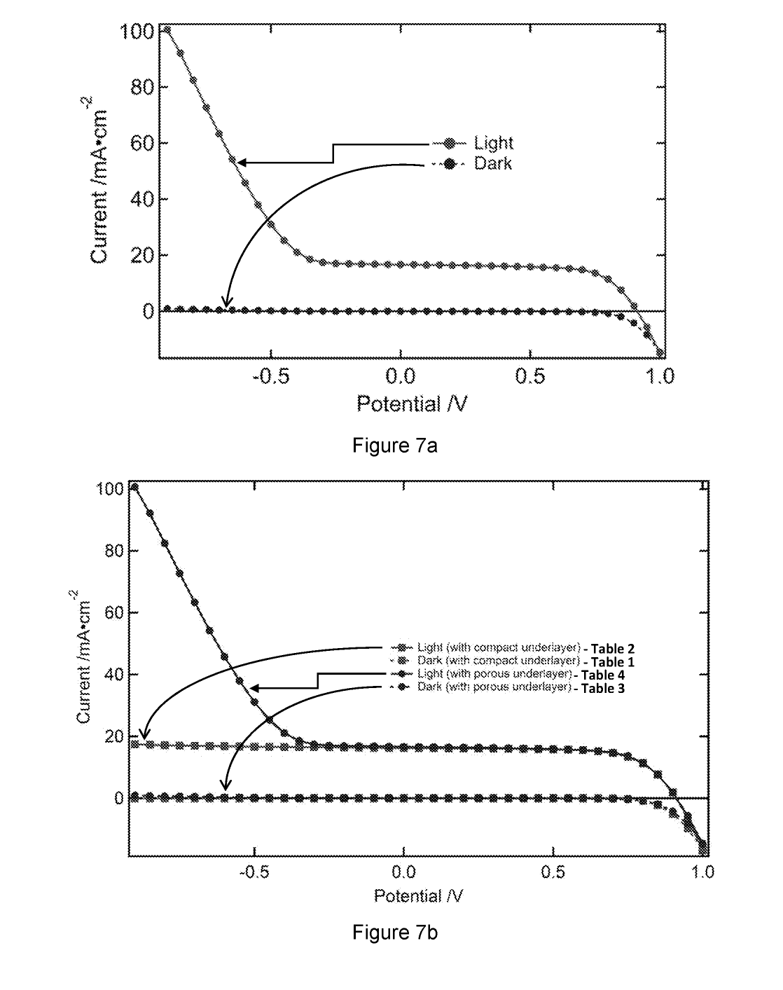

When illuminated with light intensity of 1 sun (100 mW/cm² by a white light LED array) the current in reverse bias increases about 100 times to 100 mA/cm² (FIG. 7a, 7b). The photodetector according to the present invention thus produces high amplification of the actual photocurrent response under low reverse bias.

For comparison, the measured current of a similar device illuminated with light intensity of 1 sun but having a non-porous compact under-layer 5 is additionally presented in FIG. 7b.

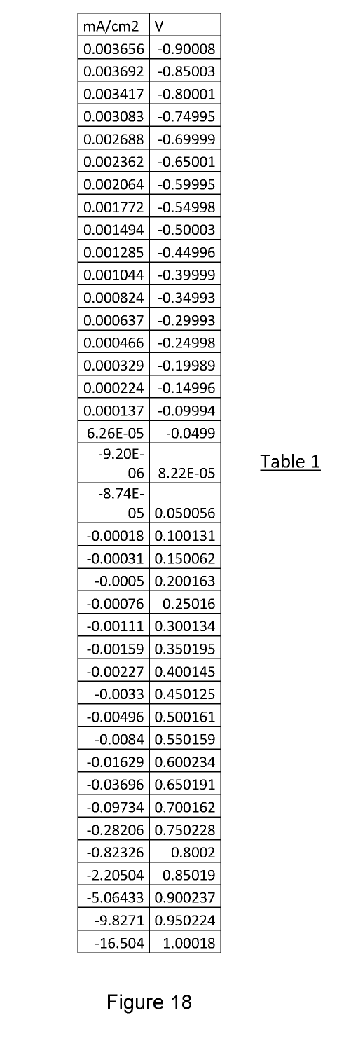

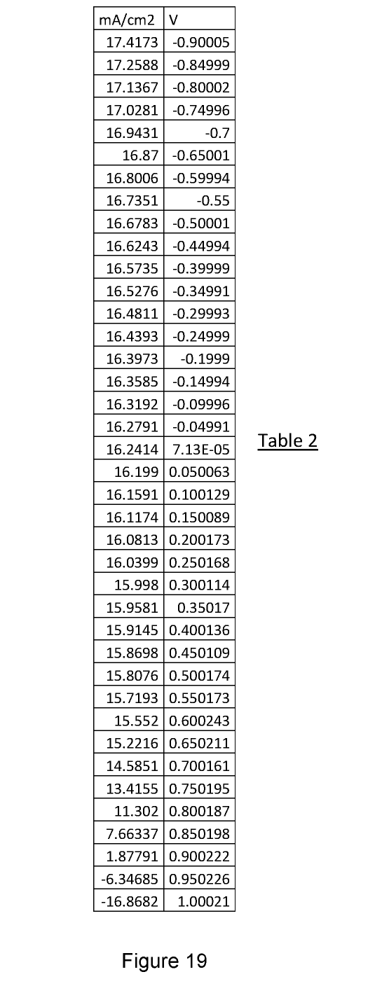

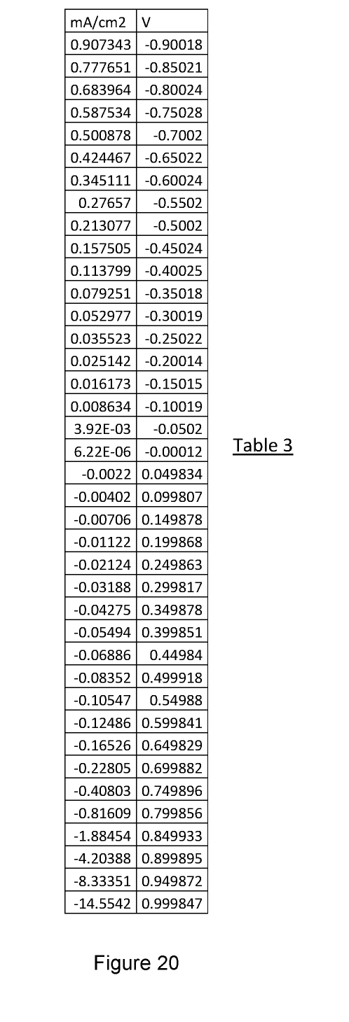

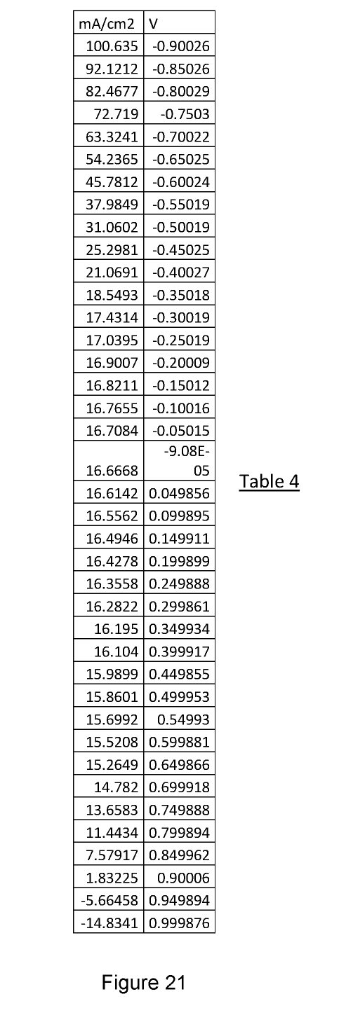

In reverse bias at 900 mV the dark current is in the range of 1 mA/cm². Under illumination in forward bias the Jsc is approximately 16.5 mA/cm². At 900 mV in reverse bias of the diode the current is 100 mA/cm². There is a gain of six times with a very low driving voltage. Tables 1 to 4 (FIGS. 18 to 21) include the data plotted in FIGS. 7a and 7b.

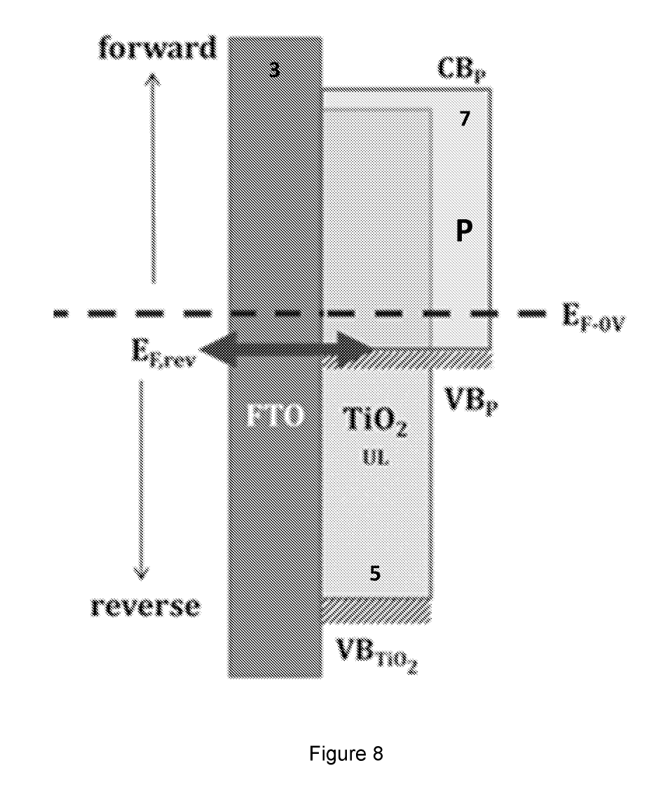

FIG. 8 is a schema showing a porous TiO₂ under-layer (UL) 5 infiltrated by a perovskite 7 (P). In the case of this porous UL 5, there exists a contact between the perovskite 7 (MaPbI3) and the FTO 3. This enables a direct charge transfer, resulting in current flowing under reverse bias (see FIGS. 6 and 7). This may also imply that the perovskite itself may act as a blocking for the HTM 11 to prevent a HTM 11/FTO 3 contact since no shunting has been observed but instead an increase of the current under reverse bias conditions. The porous TiO₂ under-layer (UL) 5 infiltrated by the perovskite 7 (P) enables a charge transfer at this interface in reverse bias.

The HTM 11 does not come into direct contact with the substrate of the photoanode. This is possibly achieved by this blocking absorber layer UL (under-layer 5) preventing direct contact of the FTO 3 with the HTM 11. Layer formation at the contact to the FTO is accomplished by the porous under-layer 5 which facilitates, by its sponge like character, the imbibition of (for example) the PbI₂ precursor solution and the followed formation of a compact MaPbI3 layer inside the porous under-layer 5.

The constituent elements of the device 1 or photodetector according to the above described embodiments and the present invention are now further described.

The electrode 3, or the electrode 3 and supporting layer 17 may be a conducting support layer. The conducting support layer (and electrode 3) is preferably substantially transparent. “Transparent” means transparent to at least a part, preferably a major part of the visible light. Preferably, the conducting support layer is substantially transparent to all wavelengths or types of visible light. Furthermore, the conducting support layer may be transparent to non-visible light, such as UV and IR radiation, for example.

According to an embodiment, the conducting support layer provides the support layer of the invention. Preferably, the photodetector elements are built on said support layer. According to another embodiment, the support is provided on the side of the counter electrode. In this case, the conductive support layer does not necessarily provide the support of the device, but may simply be or comprise a current collector, for example a metal foil.

The conducting support layer preferably functions and/or comprises a current collector, collecting the current.

For example, the conducting support layer may comprise or consist of a material selected from indium doped tin oxide (ITO), fluorine doped tinoxide (FTO), ZnO—Ga₂O₃, ZnO—Al₂O₃, tin-oxide, antimony doped tin oxide (ATO), SrGeO₃ and zinc oxide, for example preferably coated on a transparent substrate, such as plastic or glass. In this case, the plastic or glass provides the support structure of the layer and the cited conducting material provides the conductivity. Such support layers are generally known as conductive glass and conductive plastic, respectively, which are thus preferred conducting support layers in accordance with the invention. According to an embodiment, the conducting support layer comprises a conducting transparent layer, which may be selected from conducting glass and from conducting plastic.

The current collector may also be provided by a conductive metal foil, such as a titanium or zinc foil, for example. Non-transparent conductive materials may be used as current collectors in particular on the side of the device that is not exposed to the light to be captured by the device. Such metal foils have been used, for example, in flexible devices, such as those disclosed by Seigo Ito et al., Chem. Commun. 2006, 4004-4006.

According to an embodiment of the invention, the surface-increasing scaffold structure 13 is nanostructured and/or nanoporous. The scaffold structure is thus preferably structured on a nanoscale. The structures of said scaffold structure increase the effective surface compared to the surface of the preceding layers.

The scaffold material may be made from any one or combinations selected from of a large variety of different materials. According to an embodiment, the surface-increasing scaffold structure consists essentially of or is made from one selected from the group consisting of a semiconductor material, a conducting material, a non-conducting material and combinations of two or more of the aforementioned.

According to an embodiment, said scaffold structure 13 is made from and/or comprises a metal oxide. For example, the material of the scaffold structure is selected from semiconducting materials, such as Si, TiO₂, SnO₂, Fe₂O₃, ZnO, WO₃, Nb₂O₅, CdS, ZnS, PbS, Bi₂S₃, CdSe, CdTe, SrTiO₃, GaP, InP, GaAs, CuInS₂, CuInSe₂, and combinations thereof, for example. Preferred semiconductor materials are Si, TiO₂, SnO₂, ZnO, WO₃, Nb₂O₅ and SrTiO₃, for example.

However, the material of the scaffold structure 13 does not need to be semiconducting or conducting, but could actually be made from a non-conducting and/or insulating material. For example, the scaffold structure could be made from plastics, for example from plastic nanoparticles, which are in any way assembled on the conducting support and are fixed thereon, for example by heating and/or cross-linking. Polystyrene (PS) spheres of sub-micrometer size deposited on a conducting substrate can be cited as an example of a non-conducting scaffold structure.

In case the scaffold structure is made from and/or comprises a non-conducting material, an electric connection between the following layer should be warranted. It is noted that the scaffold structure does not necessarily have to form a layer that covers the adjoining layer surface completely. The scaffold may be formed by nanoparticles that are applied on the adjoining layer and does not need to be covered completely.

One can also envisage a non-conducting scaffold structure, which is coated with a layer of an electrically conducting and/or semiconducting material. The coating is sufficiently thin so as to substantially retain the original nanostructured and/or nanoporous structure of the scaffold structure. For example, the electrically conducting and/or semiconducting coating may be in electric contact with the adjoining layer.

Finally, the scaffold structure can also be made from a conducting material, for example from a metal and/or from conducting polymers, for example.

According to an embodiment, the surface-increasing scaffold structure 13 comprises nanoparticles, which are applied and/or fixed on the adjoining layer. The expression “nanoparticles” encompasses particles, which may have any form, in particular also so-called nanosheets. Nanosheets made from anatase TiO₂ have been reported by Etgar et al., Adv. Mater. 2012, 24, 2202-2206.

The scaffold structure 13 may also be prepared by screen printing or spin coating, for example as is conventional for the preparation of porous semiconductor (e.g. TiO₂) surfaces in dye-sensitized solar cells, see for example, Thin Solid Films 516, 4613-4619 (2008) or Etgar et al., Adv. Mater. 2012, 24, 2202-2206. Nanoporous semiconductor structures and surfaces have been disclosed, for example, in EP 0333641 and EP 0606453.

According to an embodiment of the invention, said scaffold structure 13 comprises and/or is prepared from nanoparticles, in particular nanosheets, which nanoparticleas and/or nanosheets are preferably further annealed. The nanoparticles preferably have dimensions and/or sizes in the range of 2 to 300 nm, preferably 3 to 200 nm, even more preferably 4 to 150 nm, and most preferably 5 to 100 nm. “Dimension” or “size” with respect to the nanoparticles means here maximum extensions in any direction of space, including the diameter in case of substantially spherical or ellipsoid particles, or length and thickness in case of nanosheets. Preferably, the size of the nanoparticles is determined by transmission electron microscopy (TEM) and selected area electron diffraction (SAED) as disclosed by Etgar et al.

According to an embodiment, the surface-increasing scaffold structure 13 is nanostructured and/or nanoporous.

According to an embodiment, the surface area per gram ratio of said scaffold structure is in the range of 20 to 200 m²/g, preferably 30 to 150 m²/g, and most preferably 60 to 120 m²/g. The surface per gram ratio may be determined the BET gas adsorption method.

According to an embodiment, said scaffold structure 13 forms a continuous and/or complete, or, alternatively, a non-continuous and/or non-complete layer on said support layer. According to an embodiment, said scaffold structure 13 can form a layer having a thickness of 10 to 2000 nm, preferably 15 to 1000 nm, more preferably 20 to 500 nm, still more preferably 50 to 400 nm and most preferably 100 to 300 nm.

The photodetector or device 1 according to the present invention comprises for example an organic-inorganic perovskite layer 7. The photodetector or device 1 may comprise one or more layers, which may each be the same or different.

The term “Perovskite”, for the purpose of this specification, refers to the “perovskite structure” and not specifically to the perovskite material, CaTiO₃. For the purpose of this specification, “perovskite” encompasses and preferably relates to any material that has the same type of crystal structure as calcium titanium oxide and of materials in which the bivalent cation is replaced by two separate monovalent cations. The perovskite structure has the general stoichiometry AMX3, where “A” and “M” are cations and “X” is an anion. The “A” and “M” cations can have a variety of charges and in the original Perovskite mineral (CaTiO₃), the A cation is divalent and the M cation is tetravalent. For the purpose of this invention, the perovskite formulae includes structures having three (3) or four (4) anions, which may be the same or different, and/or one or two (2) organic cations, and/or metal atoms carrying two or three positive charges, in accordance with the formulae presented elsewhere in this specification.

Organic-inorganic perovskites are hybrid materials exhibiting combined properties of organic composites and inorganic crystalline. The inorganic component forms a framework bound by covalent and ionic interactions which provide high carrier mobility. The organic component helps in the self-assembly process of those materials, it also enables the hybrid materials to be deposited by low-cost technique as other organic materials. Additional important property of the organic component is to tailor the electronic properties of the organic-inorganic material by reducing its dimensionality and the electronic coupling between the inorganic sheets.

The structure of the organic-inorganic perovskites are analogous to multilayer quantum well structures, with semiconducting inorganic sheets alternating with organic layers having a large energy gap. One possibility when the conduction band of the inorganic layers is substantially below that of the organic layers, and the valence band of the inorganic layers is similarly above that of the organic layers. Therefore, the inorganic sheets act as quantum wells for both electrons and holes.

Another option is when the bandgaps for the organic and inorganic layers can be offset, leading to a type II heterostructure in which the wells for the electrons and holes are in different layers.

Those structures of the organic-inorganic perovskites permit their use as an absorber or sensitizer, which can inject electrons to the scaffold structure 13, under-layer 5 and/or the conductive support 3 and at the same time may function as a hole conductor.

The organic-inorganic perovskite material that is used in the one or more perovskite layer preferably has a molecular structure corresponding to any one of the formulae (I), (II), (III), and/or (IV) below:

A₂MX₄ (I)

AMX₃ (II)

ANX₄ (III)

BMX₄ (IV)

wherein A is an monovalent organic cation and B is a bivalent organic cation. Preferably, A and B are selected from hydrocarbons comprising up to 15 carbons, and from 1 to 20 heteroatoms (for A) and 2 to 20 heteroatoms (for B), in particular one or two positively charged nitrogen atoms, respectively, besides possibly further heteroatoms selected from N, O and S.

M is a metal atom, which may be selected from the group consisting of Cu²⁺, Ni²⁺, Co²⁺, Fe²⁺, Mn²⁺, Cr²⁺, Pd²⁺, Cd²⁺, Ge²⁺, Sn²⁺, Pb²⁺, Eu²⁺, or Yb²⁺. Preferably, M is Sn²⁺ or Pb²⁺. N is a trivalent metal, which is preferably selected from the group of Bi^{3 +} and Sb³⁺.

X is an anionic compound, and is preferably selected independently from Cl⁻, Br⁻, I⁻, NCS⁻, CN⁻, NCO⁻, and combinations thereof. As there may be three X in formulae (II), the perovskite material may comprise combinations of different halogens. For example, “X₃” may be selected from I₂Cl⁻³, IBr³, Cl₂I⁻³, Br₂I⁻³, for example. The four anions in “X₄” may also be a combination of different halogens. Preferably, X is Br⁻ or I⁻.

According to a preferred embodiment, all anions in “X₃” and “X₄” are identical.

According to a preferred embodiment, said organic-inorganic perovskite layer comprises a perovskite-structure of the formula (I), (II), (III) of (IV) below,

A₂MX₄ (I)

AMX₃ (II)

ANX₄ (III)

BMX₄ (IV)

wherein,

A is an organic, monovalent cation selected from primary, secondary, tertiary or quaternary organic ammonium compounds, including N-containing heterorings and ring systems, A having from 1 to 15 carbons and 1-20 heteroatoms;

B is an organic, bialent cation selected from primary, secondary, tertiary or quaternary organic ammonium compounds having from 1 to 15 carbons and 2-20 heteroatoms and having two positively charged nitrogen atoms;

M is a divalent metal cation selected from the group consisting of Cu²⁺, Ni²⁺, Co²⁺, Fe²⁺, Mn²⁺, Cr²⁺, Pd²⁺, Cd²⁺, Ge²⁺, Sn²⁺, Pb²⁺, Eu²⁺, or Yb²⁺;

N is selected from the group of Bi^{3 +} and Sb³⁺; and,

the three or four X are independently selected from I⁻, Br, I⁻, NCS⁻, CN⁻, and NCO⁻.

M and N are preferably metal ions that can preferably adopt an octahedral anion coordination.

Preferably, X are selected from Br⁻ and I⁻, and M is Sn²⁺ or Pb²⁺.

According to a preferred embodiment, the perovskite material has the structure of formula (II).

According to a preferred embodiment, said organic-inorganic perovskite layer (4) comprises a perovskite-structure of any one of the formulae (V), (VI), (VII), (VIII), (IX) and (X);

APbX₃ (V)

ASnX₃ (VI)

A₂PbX₄ (VII)

A₂SnX₄ (VIII)

BPbX₄ (IX)

BSnX₄ (X)

wherein A, B and X are as defined above. Preferably, X is selected from Br⁻ and I⁻, most preferably X is I⁻.

According to a preferred embodiment, said organic-inorganic perovskite layer comprises a perovskite-structure of the formula (V) or (VI) above.

According to an embodiment, A, in particular in any one of formulae (I) to (III), (VI) and (VII), is a monovalent cation selected from any one of the compounds of formulae (1) to (8) below:

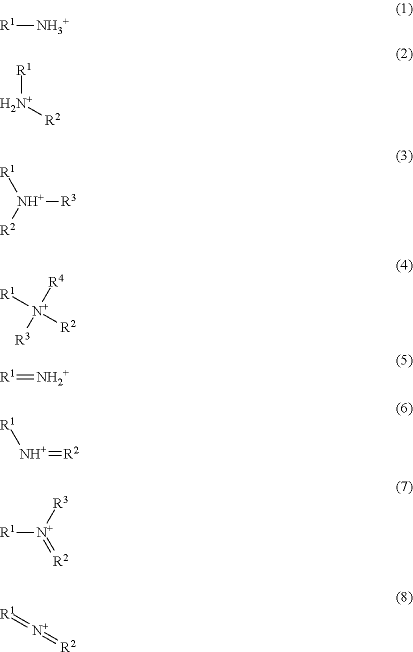

wherein,

any one of R¹, R², R³ and R⁴ is independently selected from C1 to C15 aliphatic and C4 to C15 aromatic substituents, wherein any one, several or all hydrogens in said substituent may be replaced by halogen and wherein, if there are two or more carbons, up to half of said carbons in said substituents may be replaced by a N, S or O heteroatom, and wherein, in any one of the compounds (2) to (8), the two or more of substituents present (R¹, R², R³ and R⁴, as applicable) may be covalently connected to each other to form a substituted or unsubstituted ring or ring system.

According to an embodiment, B is a bivalent cation selected from any one of the compounds of formulae (9) and (10) below:

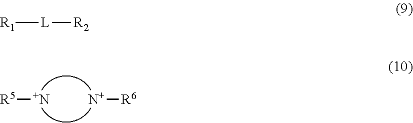

wherein,

in the compound of formula (9), L is absent or an aliphatic or aromatic linker structure having 1 to 10 carbons, wherein any one, several or all hydrogens in said L may be replaced by halogen and wherein up to half of the carbons in said L may be replaced, independently, by a N, S or O heteroatom;

wherein any one of R₁, and R₂ is independently selected from any one of the substituents (20) to (25) below:

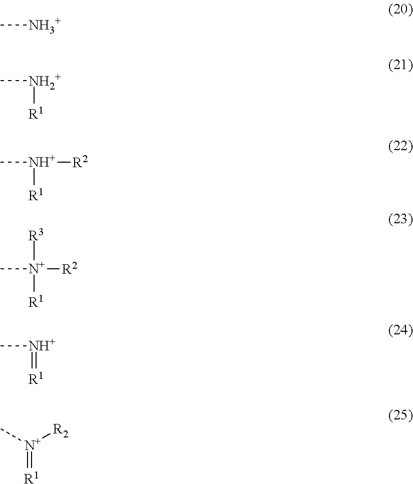

wherein the dotted line in the substituents (20) to (25) represents the bond by which said substituent is connected to the linker structure L;

wherein R¹, R², and R³ are independently as defined above with respect to the compounds of formulae (1) to (8);

wherein R¹ and R², if they are both different from substituent (20), may be covalently connected to each other by way of their substituents R¹, R², and R³, as applicable, and wherein any one of R¹, R², and R³, if present, may be covalently connected to L or the ring structure of compound (10), independently from whether said substituent is present on R₁ or R₂;

and wherein, in the compound of formula (10), the circle containing said two positively charged nitrogen atoms represents an aromatic ring or ring system comprising 4 to 15 carbon atoms and 2 to 7 heteroatoms, wherein said nitrogen atoms are ring heteroatoms of said ring or ring system, and wherein the remaining heteroatoms may be selected independently from N, O and S and wherein R⁵ and R⁶ are independently selected from H and from substituents as R¹ to R⁴.

Preferably, if the number of carbons is in L is impair, the number of heteroatoms is smaller than the number of carbons. Preferably, in the ring structure of formula (10), the number of ring heteroatoms is smaller than the number of carbon atoms.

According to an embodiment, in the compound of formula (9), L is an aliphatic or aromatic linker structure having 1 to 8 carbons, wherein any one, several or all hydrogens in said L may be replaced by halogen and wherein 0 to 4 carbons in said L may be replaced, independently, by a N, S or O heteroatom. Preferably, L is an aliphatic or aromatic linker structure having 1 to 6 carbons, wherein any one, several or all hydrogens in said L may be replaced by halogen and wherein 0 to 3 carbons in said L may be replaced, independently, by a N, S or O heteroatom.

According to an embodiment, in the compound of formula (9), said linker L is free of any O or S heteroatoms. According to an embodiment, L is free of N, O and/or S heteroatoms.

According to an embodiment, in the compound of formula (10), the circle containing said two positively charged nitrogen atoms represents an aromatic ring or ring system comprising 4 to 10 carbon atoms and 2 to 5 heteroatoms (including said two ring N-atoms).

According to an embodiment, said ring or ring system in the compound of formula (10) is free of any O or S heteroatoms. According to an embodiment, said ring or ring system in the compound of formula (10) is free of any further N, O and/or S heteroatoms, besides said two N-ring atoms. This does not preclude the possibility of hydrogens being substituted by halogens.

As the skilled person will understand, if an aromatic linker, compound, substituent or ring comprises 4 carbons, it comprises at least 1 ring heteroatom, so as to provide said aromatic compound.

According to an embodiment, any one of R¹, R², R³ and R⁴ is independently selected from Cl to C8 aliphatic and C4 to C8 aromatic substituents wherein any one, several or all hydrogens in said substituent may be replaced by halogen and wherein, if there are two or more carbons, up to half of said carbons in said substituents may be replaced by a N, S or O heteroatom, and wherein two or more of substituents present on the same cation may be covalently connected to each other to form a substituted or unsubstituted ring or ring system.

According to an embodiment, any one of R¹, R², R³ and R⁴ is independently selected from C1 to C6 aliphatic and C4 to C6 aromatic substituents wherein any one, several or all hydrogens in said substituent may be replaced by halogen and wherein, if there are two or more carbons, up to half of said carbons in said substituents may be replaced by a N, S or O heteroatom and wherein two or more of substituents present on the same cation may be covalently connected to each other to form a substituted or unsubstituted ring or ring system.

According to an embodiment, any one of R¹, R², R³ and R⁴ is independently selected from C1 to C4, preferably C1 to C3 and most preferably C1 to C2 aliphatic substituents wherein any one, several or all hydrogens in said substituent may be replaced by halogen and wherein two or more of substituents present on the same cation may be covalently connected to each other to form a substituted or unsubstituted ring or ring system.

According to an embodiment, any one of R¹, R², R³ and R⁴ is independently selected from C1 to C10 alkyl, C2 to C10 alkenyl and C2 to C10 alkynyl, wherein said alkyl, alkenyl and alkynyl, if they comprise 3 or more carbons, may be linear, branched or cyclic, and wherein several or all hydrogens in said substituent may be replaced by halogen.

According to an embodiment, any one of R¹, R², R³ and R⁴ is independently selected from C1 to C8 alkyl, C2 to C8 alkenyl and C2 to C8 alkynyl, wherein said alkyl, alkenyl and alkynyl, if they comprise 3 or more carbons, may be linear, branched or cyclic, and wherein several or all hydrogens in said substituent may be replaced by halogen.

According to an embodiment, any one of R¹, R², R³ and R⁴ is independently selected from C1 to C6 alkyl, C2 to C6 alkenyl and C2 to C6 alkynyl, wherein said alkyl, alkenyl and alkynyl, if they comprise 3 or more carbons, may be linear, branched or cyclic, and wherein several or all hydrogens in said substituent may be replaced by halogen.

According to an embodiment, any one of R¹, R², R³ and R⁴ is independently selected from Cl to C4 alkyl, C2 to C4 alkenyl and C2 to C4 alkynyl, wherein said alkyl, alkenyl and alkynyl, if they comprise 3 or more carbons, may be linear, branched or cyclic, and wherein several or all hydrogens in said substituent may be replaced by halogen.

According to an embodiment, any one of R¹, R², R³ and R⁴ is independently selected from C1 to C3, preferably C1 to C2 alkyl, C2 to C3, preferably C2 alkenyl and C2 to C3, preferably C 2 alkynyl, wherein said alkyl, alkenyl and alkynyl, if they comprise 3 or more carbons, may be linear, branched or cyclic, and wherein several or all hydrogens in said substituent may be replaced by halogen.

According to an embodiment, any one of R¹, R², R³ and R⁴ is independently selected from C1 to C4, more preferably C1 to C3 and even more preferably C1 to C2 alkyl. Most preferably, any one of R¹, R², R³ and R⁴ are methyl. Again, said alkyl may be completely or partially halogenated.

According to an embodiment, A and B is a monovalent or bivalent cation, respectively, selected from substituted and unsubstituted C5 to C6 rings comprising one, two or more nitrogen heteroatoms, wherein one (for A) or two (for B) of said nitrogen atoms is/are positively charged. Substituents of such rings may be selected from halogen and from C1 to C4 alkyls, C2 to C4 alkenyls and C2 to C4 alkynyls as defined above, preferably from C1 to C3 alkyls, C3 alkenyls and C3 alkynyls as defined above. Said ring may comprise further heteroatoms, which may replace one or more carbons in said ring, in particular, heteroatoms may be selected from O, N and S. Bivalent organic cations B comprising two positively charged ring N-atoms are exemplified, for example, by the compound of formula (10) above. Such rings may be aromatic or aliphatic.

A and B may also comprise a ring system comprising two or more rings, at least one of which being from substituted and unsubstituted C5 to C6 ring as defined as above. The elliptically drawn circle in the compound of formulae (10) may also represent a ring system comprising, for example, two or more rings, but preferably two rings. Also if A comprises two rings, further ring heteroatoms may be present, which are preferably not charged, for example.

According to an embodiment, however, the organic cations A and B comprise one (for A), two (for B) or more nitrogen atom(s) but is free of any O or S or any other heteroatom, with the exception of halogens, which may substitute one or more hydrogen atoms in cation A and/or B.

A preferably comprises one positively charged nitrogen atom. B preferably comprises two positively charged nitrogen atoms.

A and B may be selected from the exemplary rings or ring systems of formulae (30) and (31) (for A) and from (32) to (34) (for B) below:

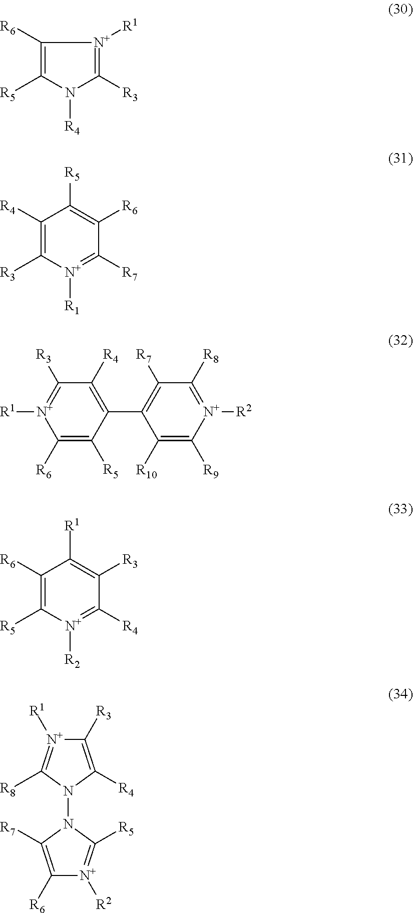

in which R¹ and R² are, independently, as defined above, and R₃, R₄, R₅, R₆, R₇, R₈, R₉ and R₁₀ are independently selected from H, halogen and substituents as defined above for R¹ to R⁴. Preferably, R₃-R₁₀ are selected from H and halogen, most preferably H.

In the organic cations A and B, hydrogens may be substituted by halogens, such as F, Cl, I, and Br, preferably F or Cl. Such a substitution is expected to reduce the hygroscopic properties of the perovskite layer or layers and is thus considered advantageous for the purpose of the present specification.

In the methods of the invention, the perovskite layer may be applied by any one or more selected from drop casting, spin-coating, dip-coating and spray-coating, for example.

According to an embodiment, the photodetector or device 1 of the invention comprises two or more successive organic-inorganic perovskite layers, wherein said successive perovskite layers may be composed identically or wherein two or more of said layers may have a different molecular structure and/or composition. In this way, the different functions of absorbing or sensitizing and/or hole transporting which are preferably achieved by the perovskite layers may be optimized and/or fine-tuned as a function the surrounding adjoining layers.

If there are several, different perovskite layers, the different perovskite structures may be of a different composition. Any one or more of A, B, M, N or X in the structures of formulae (I) to (IX) may be changed in order to provide a different perovskite layer having different properties, as desired. In particular, A, B, M, N or X may be changed in a subsequent layer, in order to adjust the bandgaps of the material. Different layers comprising different perovskite structures, but preferably still within the general formulae (I) to (IX), may in particular be useful to optimize a respective layer to its function (absorber, sensitizer or hole conductor).

The perovskite 7 can have, for example, a film thickness between 20 nm and 10 micrometers, inclusive of 20 nm and 10 micrometers.

The photodetector or device 1 of the invention preferably comprises the counter electrode 4. The counter electrode generally comprises a catalytically active material, suitable to provide electrons and/or fill holes towards the inside of the device. The counter electrode may thus comprise one or more materials selected from (the group consisting of) Pt, Au, Ni, Cu, Ag, In, Ru, Pd, Rh, Ir, Os, C, conductive polymer and a combination of two or more of the aforementioned, for example. Conductive polymers may be selected from polymers comprising polyaniline, polypyrrole, polythiophene, polybenzene, polyethylenedioxythiophene, polypropylenedioxy-thiophene, polyacetylene, and combinations of two or more of the aforementioned, for example.

The counter electrode 4 may be applied as is conventional, for example by thermal evaporation of the counter electrode material onto the exposed adjoining layer.

The hole transporting material 11 can be a hole-transporting material of organic, inorganic, organometallic, hybrid inorganic and organic, oligomers, and polymers with HOMO level between −4.5 to −5.5 eV. The Hole transporting material 11 can be an organic hole transporting material that is 2,2′7,7′-tetrakis(N,N-di-methoxyphenyamine)-9,9′-spirobifluorene (Spiro-MeOTAD).

By “hole transport material”, “hole transporting material”, “organic hole transport material” or “inorganic hole transport material”, and the like, is meant any material or composition wherein charges are transported by electron or hole movement (electronic motion) across said material or composition. The “hole transport material” is thus an electrically conductive material. Such hole transport materials, etc., are different from electrolytes. In this latter, charges are transported by diffusion of molecules.

A hole transport material 11 can be one selected from organic and inorganic hole transport materials. Preferred organic hole transport materials for the purpose of the present invention are Spiro-OMeTAD (2,2′, 7,7′-tetrakis-N,N-di-p-methoxyphenylamine-9,9′-spirobifluorene) and derivatives of PTAA (poly(triarlyamine)) such as (Poly[bis(4-phenyl)(2,4,6 trimethylphenyl)amine]) or (Poly[bis(4-phenyl)(4-butylphenyl)amine]). US2012/0017995, disclosing further hole transport materials, is entirely incorporated herein by reference.

The hole transporting material 11 can be deposited, for example, by spin-coating.

It is noted that the term “organic” in expressions “organic hole transport material”, “organic hole transport layer” does not exclude the presence of further components. Further components may be selected from (a) one or more dopants, (b) one or more solvents, (c) one or more other additives such as ionic compounds, and (c) combinations of the aforementioned components, for example. In the organic charge transport material, such further components may be present in amounts of 0-30 wt. %, 0-20 wt. %, 0-10 wt. %, most preferably 0-5 wt. %.

Examples of ionic compounds that may be present in organic hole transport materials are TBAPF₆, Na CF₃SO₃, Li CF₃SO₃, LiClO₄ and Li[(CF₃SO₂)₂N.

Examples of other compounds that may be present in organic hole transport materials are amines, 4-tertbutylpyridine, 4-nonyl-pyridine, imidazole and N-methyl benzimidazole.

According to another embodiment, the intermediate HTM layer 11 comprises and/or consists essentially of an inorganic hole transport material. A wide variety of inorganic hole transport materials is commercially available. Non-limiting examples of inorganic hole transport materials are CuNCS, CuI, MoO₃, and WoO₃. The inorganic hole transport material may or may not be doped.

The organic or inorganic hole transport material 11 can remove holes from the perovskite material and/or provides new electrons from the counter electrode 4 to perovskite layer 7. In other terms, the hole transport material transports electrons from the counter electrode to the perovskite material layer.

The above description of the present invention does not exclude the possibility that there is one or more intermediate HTM layers between the different layers of the photodetector 1 in the above described embodiments. Such intermediate HTM layers, if present, would preferably be conducting and/or semiconducting.

The invention also concerns new low voltage photodetectors with an inverted architecture, namely having a transparent front on the side of the hole collector.

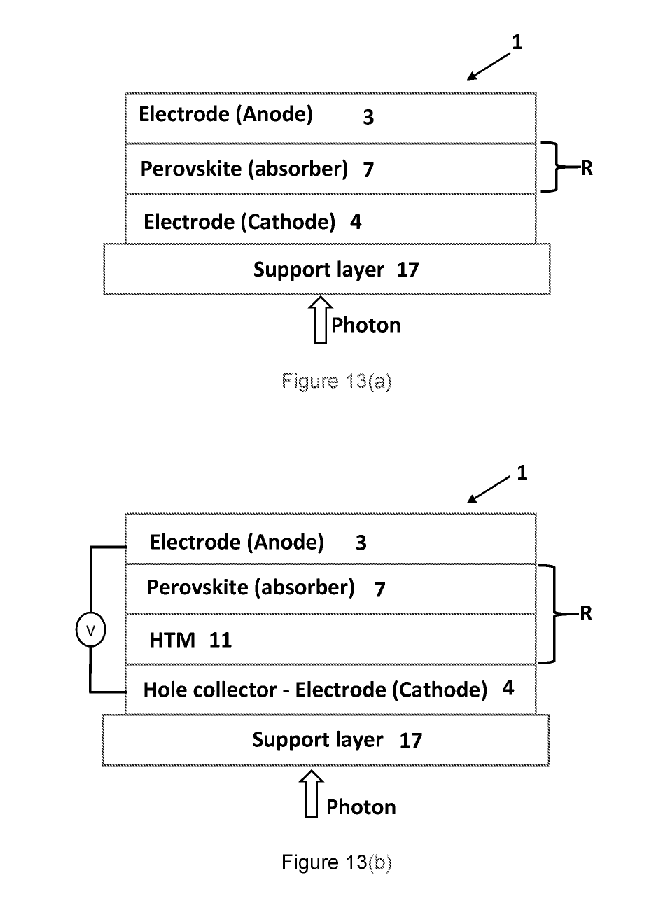

Exemplary photodetectors are illustrated in FIGS. 13(a), 13(b), 14, 15 and 16(a), 16(b) and 16(c).

FIG. 13(b) illustrates a first embodiment of the photodetector or device 1 according to the present invention having the above mentioned inverted architecture. The device 1 includes a first electrode 3 and a second electrode 4 sandwiching an active or intermediate region R.

The active region R of the photodetector 1 comprises or consists solely of a hole-transporting material 11 provided on the first electrode (cathode) 4, a perovskite 7 provided on the hole-transporting material 11. The second electrode (anode) 3 provided on the perovskite 7.

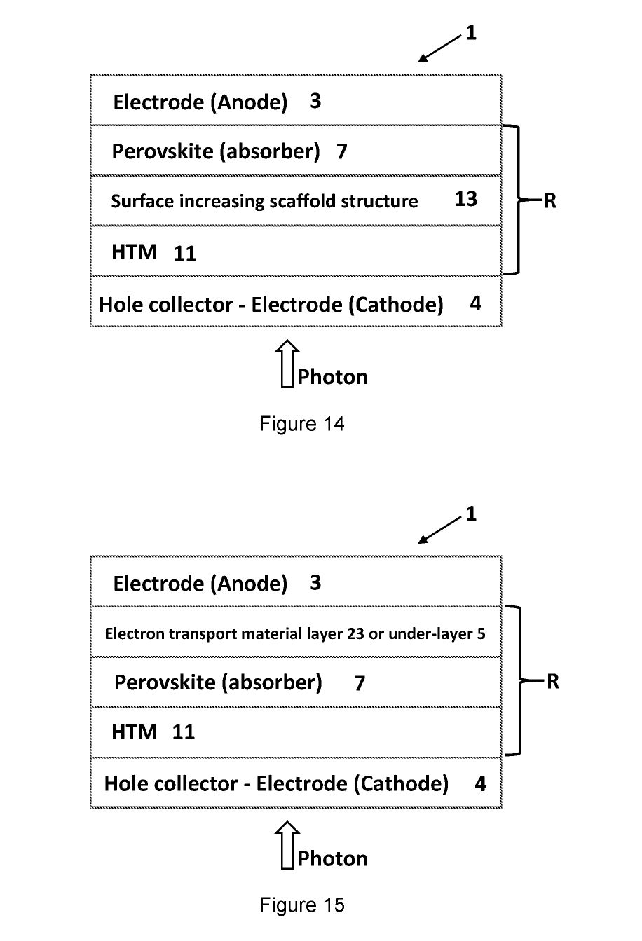

FIG. 14 illustrates a second embodiment of the photodetector or device 1 according to the present invention having an inverted architecture. The photodetector or device 1 is identical to the first embodiment (FIG. 13(b)) except that the active region R in addition to the elements of the active region R of FIG. 13(b) consists ofor further comprises a surface increasing scaffold structure 13 deposited on the hole-transporting material 11 and the perovskite 7 is infiltrated into surface increasing scaffold structure 13 and contacts the hole-transporting material 11.

FIG. 15 illustrates a third embodiment of the photodetector or device 1 according to the present invention having an inverted architecture. The photodetector 1 is identical to the first embodiment (FIG. 13(b)) except that the active region R in addition to the elements of the active region R of FIG. 13(b) consists of or further comprises an electron transport material layer 23 on the perovskite 7 and onto which the second electrode 3 is deposited. Preferably, the electron transport material layer 23 is porous and is infiltrated by a perovskite 7 from the perovskite 7 layer side to the electrode 3 side such that the perovskite 7 layer is in contact (or makes a plurality of direct contacts) with the electrode (anode) 3 through the pores of the electron transport material layer 23.

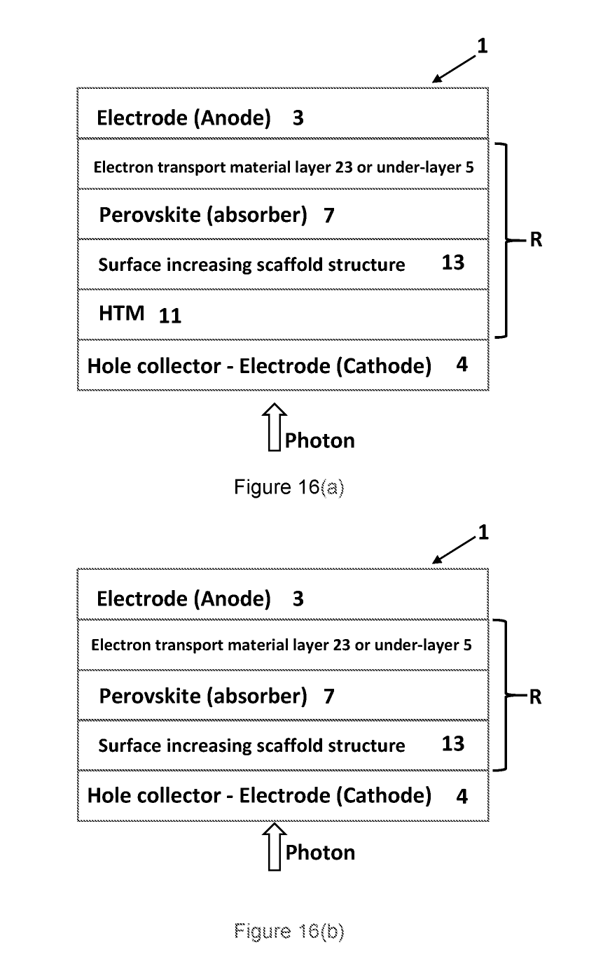

FIG. 16(a) illustrates a fourth embodiment of the photodetector or device 1 according to the present invention having an inverted architecture. The photodetector 1 is identical to the second embodiment (FIG. 14) except that the active region R in addition to the elements of the active region R of FIG. 14 consists ofor further comprises an electron transport material layer 23 on the perovskite 7 and onto which the second electrode 3 is deposited. Preferably, the electron transport material layer 23 is porous and is infiltrated by a perovskite 7 from the perovskite 7 layer side to the electrode 3 side such that the perovskite 7 layer is in contact (or makes a plurality of direct contacts) with the electrode (anode) 3 through the pores of the electron transport material layer 23. Preferably, the surface increasing scaffold structure 13 consists of a non-conducting material.

FIG. 16(b) illustrates a fifth embodiment of the photodetector or device 1 according to the present invention having an inverted architecture. The photodetector 1 is identical to the embodiment of FIG. 16(a) except that the active region R does not contain a HTM 11.

FIG. 16(c) illustrates a sixth embodiment of the photodetector or device 1 according to the present invention having an inverted architecture. The photodetector 1 is identical to the embodiment of FIG. 15 except that the active region R does not contain a HTM 11.

According to a seventh inverted architecture embodiment (see for example, FIG. 13(a)), the active region R includes or consists solely of a perovskite 7 provided directly on the electrode 4 and directly on the electrode 3.

In further embodiments of the present invention, the electron transport material layer 23 of FIGS. 15, 16(a), 16(b) and 16(c) is replaced with an under-layer 5 such as that described above with respect to the ‘normal’ or non-inverted structures (FIGS. 9 and 10).

A second perovskite layer 7 that infiltrates the electron transport material layer 23 or under-layer 5 can be deposited on the electron transport material layer 23 or under-layer 5. The active region R can additionally include or additionally consists of this second perovskite layer 7.

It is to be noted that the above photodetector embodiments can optionally include a support layer 17 like that mentioned above with respect to the non-inverted structure (see for example FIG. 13) upon which the previously mentioned layers of the inverted structure are provided or deposited.

For each of the above devices 1, when in use, a reverse-bias voltage applied to the anode and cathode electrodes produces a high photocurrent amplification or gain at low voltage. The device is a high gain, low voltage photodetector.

The present invention also concerns a device or photodetector 1 according to according to any one of the previous inverted architecture embodiments further including a voltage source connected in reverse bias to the electrodes. The voltage source is applying a reverse bias voltage.

The device or photodetector 1 is a high gain, low voltage photodetector.

The present invention also concerns the use of the device 1 according to any one of the previous inverted architecture embodiments to make a high gain, low voltage photodetector.

The present invention further concerns the use of the device 1 according to any one of previous inverted architecture embodiments as a high gain, low voltage photodetector.

The present invention further concerns the use of a photodetector according to any one of previous inverted architecture embodiments to amplify a light photocurrent at low voltage.

The reverse-bias voltage applied to the device or photodetector 1 produces for example a light photocurrent multiplication of at least 2 (gain=1) for an applied reverse bias voltage at −0.55 V compared to 0.05 V.

The present invention further relates to a method for producing a photodetector comprising the steps of: providing the device 1 according to any one of previous inverted architecture embodiments, and applying a reverse-bias voltage to the photodetector to produce a high gain factor at low voltage.

The reverse-bias voltage applied produces for example a light photocurrent multiplication of at least 2 for an applied reverse bias voltage at −0.55 V compared to 0.05 V.

The present invention further relates to a method of operation of a photodetector comprising the steps of: providing the device 1 according to any one of previous inverted architecture embodiments, and applying a reverse-bias voltage to produce a high gain at a low voltage. The reverse-bias voltage applied to the photodetector produces for example a light photocurrent multiplication of at least 2 for an applied reverse bias voltage at −0.55 V compared to 0.05 V.

The present invention further relates to a method of fabricating a photodetector comprising the steps of: providing the device 1 according to any one of previous inverted architecture embodiment, and fixing or attaching reverse-bias voltage terminals to the photodetector for reverse-bias voltage operation.

The present invention further concerns a method for amplifying a photocurrent comprising the steps of: providing the device 1 according to any one of the previous inverted architecture embodiments, and applying a reverse-bias voltage to the photodetector. The reverse-bias voltage applied produces for example a light photocurrent multiplication of at least 2 for an applied reverse bias voltage at −0.55 V compared to 0.05 V.

A method for producing a low voltage photodetector (inverted architecture) according to the first embodiment (FIG. 13(a)) comprises the steps of providing a hole collector layer or cathode electrode 9; applying a hole transporting material 11 onto the hole collector layer or cathode electrode 9; applying an absorber layer or perovskite 7 onto the hole transporting material 11; and providing a current collector or anode electrode on the perovskite layer 7. This latter layer is in electric contact with the perovskite 7.

For the purpose of the present specification, the expression “in electric contact with” means that electrons or holes can get from one layer to the other layer with which it is in electric contact, at least in one direction. In particular, considering the electron flow in the operating device exposed to electromagnetic radiation, layers through which electrons and/or holes are flowing are considered to be in electric contact. The expression “in electric contact with” does not necessarily mean, and preferably does not mean, that electrons and/or holes can freely move in any direction between the layers.

A method for producing a low voltage photodetector (inverted architecture) according to the second embodiment (FIG. 14) comprises the same steps to that of the previous method further comprising the step of depositing a surface increasing scaffold structure 13 on the hole-transporting material 11 and then depositing the perovskite 7 on the surface increasing scaffold structure 13 to infiltrate the surface increasing scaffold structure 13 and contact the hole-transporting material 11.

A method for producing a low voltage photodetector (inverted architecture) according to the third embodiment (FIG. 15) comprises the same steps to that of the previous method relating to the first embodiment (FIG. 13(a)) further comprising the step of depositing an electron transport material layer 23 on the perovskite 7 and depositing the second electrode 3 onto the electron transport material layer 23. A further perovskite layer 7 can be deposited on transport material layer 23 to obtain a perovskite infiltrated transport material layer 23.

A method for producing a low voltage photodetector (inverted architecture) according to the fourth embodiment (FIG. 16(a)) comprises the same steps to that of the previous method relating to the second embodiment (FIG. 14) further comprising the step of depositing an electron transport material layer 23 on the perovskite 7 and depositing the second electrode 3 onto the electron transport material layer 23. A further perovskite 7 can be deposited on transport material layer 23 to obtain a perovskite infiltrated transport material layer 23.

In the fifth embodiment (FIG. 16(b)) of the photodetector or device 1 according to the present invention having an inverted architecture, the step of depositing the HTM 11 in the production method of fourth embodiment (FIG. 16(a)) is not carried out and the surface increasing scaffold structure 13 is deposited directly on the electrode 4.

In the sixth embodiment (FIG. 16(c)) of the photodetector or device 1 according to the present invention having an inverted architecture, the step of depositing the HTM 11 in the production method of third embodiment (FIG. 15) is not carried out and the perovskite 7 is deposited directly on the electrode 4.

Concerning the seventh inverted architecture embodiment (FIG. 13(a)), the perovskite 7 is deposited directly on the electrode 4 and the electrode 3 is deposited on the perovskite 7.

In further embodiments of the present invention, the electron transport material layer 23 of FIGS. 15, 16(a), 16(b) and 16(c) is replaced with an under-layer 5 such as that described above with respect to the ‘normal’ or non-inverted structures (FIGS. 9 and 10). The deposition of the under-layer 5 can also be carried out as set out above with respect to the non-inverted structures.

Furthermore, the constituent layers and elements of the inverted devices 1 can be deposited, for example, as set out above with respect to the non-inverted device 1 embodiments.

The thickness tR of the active region R of the device is preferably less than 2 μm. The thickness t_{R} of the active region R is preferably between 0.5 μm and 1.5 μm, the values of 0.5 μm and 1.5 μm included.

The device 1 of the present invention (inverted or non-inverted structures) provides current amplification or gain when a reverse-bias negative voltage as low as −0.2 V is applied to the electrodes to produce an electric field across the thickness tR of the active region R. The device 1 of the present invention thus provides current amplification or gain when an electric field between 400000 kVm⁻¹ (0.2 V/0.5 μm) and 133333.33 Vm⁻¹ (0.2 V/1.5 μm) is applied across the active region R of the device 1.

The device 1 of the present invention (inverted or non-inverted structures) provides current amplification or gain when a reverse-bias negative voltage of −0.1 V or less than −0.1 V (negative number of greater magnitude) or of −0.2 V or less than −0.2 V (negative number of greater magnitude) is applied to the electrodes to produce an electric field across the thickness tR of the active region R. (For example, up until a negative voltage before which the device ultimately breaks down).

The device 1 of the present invention thus provides current amplification or gain when an electric field of 200000kVm⁻¹ (0.1 V/0.5 μm) or greater; or 400000 kVm⁻¹ (0.2 V/0.5 μm) or greater is applied across the active region R of the device 1.

The device 1 of the present invention thus provides current amplification or gain when an electric field of 200000 kVm⁻¹ (0.1 V/0.5 μm) or greater; or 400000 kVm⁻¹ (0.2 V/0.5 μm) or greater is applied across the active region R of the device 1.

The device 1 of the present invention thus provides current amplification or gain when an electric field of 66666.666 kVm⁻¹ (0.1 V/1.5 μum) or greater; or 133333.33 Vm⁻¹ (0.2 V/1.5 μm) or greater is applied across the active region R of the device 1.

The device 1 of the present invention (inverted or non-inverted structures) provides current amplification or gain when a reverse-bias negative voltage between −0.1 V or −0.2 V and −0.6 V as well as between −0.1 V or −0.2 V and −1 V is applied to the electrodes to produce an electric field across the thickness tR of the active region R.

The features or characteristics of the absorber layer or perovskite 7 previously described above and that are additionally described herein concern both with the inverted and non-inverted embodiments.

According to an embodiment, the absorber layer or perovskite 7 of any one of the above mentioned devices 1 (inverted or non-inverted) may comprises at least one pigment being selecting from organic, inorganic, organometallic and organic-inorganic pigments or a combination thereof. The absorber layer 7 is preferably a light absorbing compound or material. Preferably, the absorber layer 7 is a pigment, and most preferably the absorber layer 7 is an organic-inorganic pigment.

The absorber layer 7 may comprise one or more pigments of the group consisting of organometallic sensitizing compounds (telocyanine derived compounds, porphyrine derived compounds), metal free organic sensitizing compounds (diketopyrrolopyrrole (DPP) based sensitizer), inorganic sensitizing compounds such as quantum dots, Sb₂S₃ (Antimonysulfide, for example in the form of thin films), aggregates of organic pigments, nanocomposites, in particular organic-inorganic perovskites, and combinations of the aforementioned. For the purpose of the invention, it is in principle possible to use any type of dyes or sensitizer, including combinations of different types of dyes or different dyes of the same type.

According to an embodiment, an absorber layer or perovskite 7 may comprise, consist of or is made of an organic-inorganic perovskite. Said organic-inorganic perovskite is provided under a film of one perovskite pigment or mixed perovskite pigments or perovskite pigments mixed with further dyes or sensitizers as described herein.

According to a further embodiment, the absorber layer 7 comprises a further pigment in addition to the organic-inorganic perovskite pigment, said further pigment selected from organic pigment, organometallic pigment or inorganic pigment.

Organometallic sensitizers or absorber layers are disclosed, for example, in EP0613466, EP0758337, EP0983282, EP1622178, WO2006/038823, WO2009/107100, WO2010/055471 and WO2011/039715. Exemplary organic dyes are those disclosed in WO2009/098643, EP1990373, WO2007/100033 for example. An organic dye was also used in European patent application No. EP11161954.0 and in PCT/IB2011/054628. Metal free organic sensitizers or absorber layers such as DPP based compounds are disclosed, for example, in PCT/IB32013/056648 and in European patent application No. EP12182817.2.

As previously mentioned, the perovskite structure has the general stoichiometry AMX₃, where “A” and “M” are cations and “X” is an anion. The “A” and “M” cations can have a variety of charges and in the original Perovskite mineral (CaTiO₃), the A cation is divalent and the M cation is tetravalent. For the purpose of this invention, the perovskite formulae includes structures having three (3) or four (4) anions, which may be the same or different, and/or one or two (2) organic cations, and/or metal atoms carrying two or three positive charges, in accordance with the formulae presented elsewhere in this specification.

Organic-inorganic perovskites are hybrid materials exhibiting combined properties of organic composites and inorganic crystalline. The inorganic component forms a framework bound by covalent and ionic interactions, which provide high carrier mobility. The organic component helps in the self-assembly process of these materials, it also enables the hybrid materials to be deposited by low-cost technique as other organic materials. Additional important property of the organic component is to tailor the electronic properties of the organic-inorganic material by reducing its dimensionality and the electronic coupling between the inorganic sheets.

The perovskite 7 can have a film thickness between 20 nm and 10 micrometers, inclusive of 20 nm and 10 micrometers. According to an embodiment, the method of the invention provides an absorber layer or perovskite 7 having a thickness from 10 nm to 800 nm, 15 nm to 400 nm or 100 nm to 300 nm. The absorber layer or perovskite 7 has a thickness from 20 nm to 350 nm or 60 nm to 350 nm, preferably from 250 nm to 350 nm. Preferably the absorber layer or perovskite 7 comprises or consists of organic-inorganic perovskite has a thickness as defined above, namely from 10 nm to 800 nm, 15 nm to 400 nm, 100 nm to 300 nm, from 20 nm to 350 nm or from 60 nm to 350 nm, preferably from 250 nm to 350 nm.

According to a further embodiment, the method of the invention provides the step of applying the absorber layer or perovskite 7 being performed at a vacuum from 10⁻² to 10⁻¹⁰ mbar, 10⁻² to 10⁻⁷ mbar, preferably at 10⁻⁶ mbar.

According to another embodiment of the method of the invention, the step of applying the absorber layer or perovskite 7 comprising or consisting of the organic-inorganic perovskite is performed by deposition by sublimation process, wherein the absorber layer or perovskite 7 comprising an organic-inorganic perovskite is obtained by co-deposition of one or more sublimated divalent metal salts or sublimated trivalent metal salts and of one or more sublimated organic ammonium salts. Said deposition may be defined as co-deposition or deposition by sublimation process.

For the purpose of the present specification, the expression “sublimation” means that this is the transition from the solid phase of a material (crystal for example) to the gas phase of said material (or vapor phase) without passing through an intermediate liquid phase at very low pressure, such as high vacuum. The relative expressions “sublimation temperature” corresponds to the term “heat of sublimation” being the temperature at which the phase transition from solid to gas without passing through the liquid phase is performed at a defined pressure. Said temperature depends on the type of the material, substance as well as the pressure in which this phase transition is performed. The relative expression “sublimated” or “sublimed” qualifies or defines the material (e.g. crystal of chemical compounds, of salts, of halide salts, of metallic salts, of organic salts), which has undergone a phase transition from the solid phase to the gas phase without passing through an intermediate liquid phase.

In an embodiment, the step of applying the absorber layer or perovskite 7 comprises heating the one or more divalent or trivalent salts and the ammonium salts up to their respective sublimation temperature to obtain a vapor of each salt, depositing said vapors onto the preceding layer (for example HTM 11 or surface increasing scaffold structure 13) and forming the inorganic-organic perovskite. This step or the process of fabrication the device may be performed without heating said device. Actually, the preceding layer can be the electron blocking layer and/or the hole transporting layer 11 or the surface increasing scaffold structure 13 of the partially assembled photo detector 1. Said step of depositing may be performed in a one step process as described above or in a multiple-steps process, wherein each salt forming the organic-inorganic perovskite is sublimated separately and deposited separately in several steps onto the preceding layer for forming the organic-inorganic perovskite layer.

According to an embodiment, said one or more divalent metal salts or said one or more trivalent metal salts, which are heated to their respective sublimation temperature, are selected from salts of formula MX₂ or of formula NX₃, respectively, wherein: M is a divalent metal cation selected from the group consisting of Cu²⁺, Ni²⁺, Co²⁺, Fe²⁺, Mn²⁺, Cr²⁺, Pd²⁺, Cd²⁺, Ge²⁺, Sm²⁺, Pb²⁺, Eu²⁺, or Yb^{2 +}; N is selected from the group of Bi3+ and Sb3+; any X is independently selected from Cl⁻, Br⁻, I⁻, NCS⁻, CN⁻, and NCO⁻. Preferably, said metal salt is MX₂.

According to a preferred embodiment, said metal salt is a metal halide. Preferably, in case two or more different metal salts are used, these are different metal halides.

According to an embodiment, said organic ammonium is selected from AX and BX₂, A being an organic, monovalent cation selected from primary, secondary, tertiary or quaternary organic ammonium compounds, including N-containing heterorings and ring systems, A having from 1 to 60 carbons and 1 to 20 heteroatoms; and B being an organic, bivalent cation selected from primary, secondary, tertiary or quaternary organic ammonium compounds having from 1 to 60 carbons and 2 to 20 heteroatoms and having two positively charged nitrogen atoms. Preferably, said organic ammonium is selected from AX.

Preferred embodiments for A, B, M, N and X are disclosed elsewhere in this specification, for example with respect to preferred perovskites of the invention.

In a preferred embodiment, the divalent metal salts are of formula MX₂ and the trivalent metal salts are of formula NX₃, M being a divalent metal cation selected from the group consisting of Cu²⁺, Ni²⁺, Co²⁺, Fe²⁺, Mn²⁺, Cr²⁺, Pd²⁺, Cd²⁺, Ge²⁺, Sm²⁺, Pb²⁺, Eu²⁺, or Yb^{2 +}, N being selected from the group of Bi³⁺ and Sb³⁺, and, X being independently selected from Cl⁻, Br⁻, I⁻, NCS⁻, CN⁻, and NCO⁻; and the organic ammonium salts being selected from AX, AA′ X₂, and BX₂, A and A′ being independently selected from organic, monovalent cations selected from primary, secondary, tertiary or quaternary organic ammonium compounds, including N-containing heterorings and ring systems, A and A′ having from 1 to 60 carbons and 1 to 20 heteroatoms;

and B being an organic, bivalent cation selected from primary, secondary, tertiary or quaternary organic ammonium compounds having from 1 to 60 carbons and 2 to 20 heteroatoms and having two positively charged nitrogen atoms, and, X being independently selected from Cl⁻, Br⁻, I⁻, NCS⁻, CN⁻, and NCO⁻.

When more than one divalent metal salt are applied and/or deposited, the two different salts are sublimated and applied by co-deposition at the same time or in two-steps. For example, in case of deposition from a crystal, the crystal may contain different metal salts, which have been recrystallized together or the deposition may be performed from different crystals from different divalent salts, being sublimated at different temperature according to their respective sublimation temperature. Said different metals salts preferably differ with respect to the anion.

According to an embodiment, the method of the invention comprises the steps of applying the absorber layer or perovskite 7 by co-deposition of two or more sublimated divalent salts selected from MXⁱ₂ MXⁱⁱ₂ and MXⁱⁱⁱ₂, wherein Xⁱ, Xⁱⁱ and Xⁱⁱᵢ (charge not shown) are each different anions selected from I⁻, Cl⁻, Br⁻, I⁻, NCS⁻, CN⁻, and NCO⁻preferably from I⁻, Cl⁻, and Br⁻.

A mixed perovskite is obtained if the sublimated metal salt, in the state of vapor, comprising MXⁱ₂ MXⁱⁱ₂, or MXⁱ₂, MXⁱᵢ₂ and MXⁱⁱⁱ₂, for example, may be co-deposited and/or combined with a sublimated organic ammonium salt, namely in the state of vapor, in accordance with the invention, which may be selected, independently from any one of AXⁱ, AXⁱⁱ and AXⁱⁱⁱ, under high vacuum, namely from 10⁻² to 10⁻¹⁰ mbar, 10⁻² to 10⁻⁷ mbar, preferably at or at least at 10⁻⁶mbar.

Preferably, if the sublimated metal salt comprises MXⁱ₂ and MXⁱⁱ₂, the organic ammonium salt is selected from salts comprising one of the anions contained in the sublimated metal salt, for example from AXⁱ or AXⁱⁱ.

According to an embodiment, the method of the invention comprises the step of applying the absorber layer or perovskite 7, wherein said step is performed by co-deposition of two sublimated divalent metal salts, one said salt being MI₂ and the further being selected from MCl₂ and MBr₂ and of the sublimated ammonium organic salt AX, X being I⁻ and A defined as above or below. Preferably, M is Pb and/or A is CH₃NH₃⁺.

According to an embodiment, the method of the invention comprises the step of applying the absorber layer or perovskite 7, wherein said step is performed by co-deposition of two sublimated divalent metal salts, one said salt being MCl₂ and the further being selected from MI₂ and MBᵣ₂ and of the sublimated ammonium organic salt AX, X being I⁻ and A defined as above or below. Preferably, M is Pb and/or A is CH 3 NH₃⁺.

According to a preferred embodiment, the co-deposition of the one or more sublimated organic ammonium salts with the one or more sublimated divalent or trivalent metal salts concerns the co-deposition of one single and/or one structurally defined organic ammonium salt. Preferably, not a mixture of different sublimated organic salts is co-deposited. This is preferably valid irrespective from whether a mixture of different sublimated metal salts or if a single type of sublimated metal salts was co-deposited in the method of the invention.

In a further embodiment, the method of the invention comprises the step of applying the absorber layer or perovskite 7, wherein said step is performed by co-deposition of sublimated MⁱX₂ with sublimated MⁱⁱX or sublimated MⁱⁱⁱX₃, and of one or more sublimated ammonium organic salts as defined herein. In this case Mii and Miii represent monovalent or trivalent cations, which would constitute a doping with a monovalent or trivalent metal salt, respectively. In the result, n-type or p-type doped metal salts and eventually perovskites can be obtained.

In accordance with the above said two different metal salts may be applied, differing with respect to the metal, but having, for example, identical anions. In this case, metals carrying different charges are preferably applied, resulting in doped perovskite or doped perovskite pigments.

In a preferred embodiment, the step of applying the absorber layer or perovskite 7 is performed by one or more methods selected from physical vapor deposition methods group and/or from chemical vapor deposition. The physical vapor deposition methods group consists of deposition by sublimation process, cathodic arc deposition, electron beam physical vapor deposition, thermal evaporation, evaporative deposition, pulse laser deposition, sputter deposition.

According to another embodiment, the absorber layer or perovskite 7 comprising an organic-inorganic perovskite may be applied in a first step: under the form of a film of the one or more divalent or trivalent metal salt is applied and/or deposited by a deposition method selected from deposition from a solution, a dispersion, a colloid or a crystal or a salt, thermal evaporation, deposition by sputtering, electrodeposition, atomic-layer-deposition (ALD), and, and in a second step, under the application or deposition by anyone of the method as described above of the organic ammonium salt, thereby forming in situ the organic-inorganic perovskite layer. The method of deposition from solution encompasses drop casting, spin-coating, dip-coating, curtain coating, spray-coating, and ink-jet printing methods. The perovskite 7 being an organic-inorganic perovskite may be also applied in one-step process from any one of the methods of deposition from a solution, a dispersion, a colloid, a crystal or a salt, if solution, dispersion, colloid, crystal or salt comprises said organic-inorganic perovskite. Further application methods of organic-inorganic perovskite are described, for example, in EP13166720.6.

In another embodiment, the step of providing the current collector or anode electrode 3 (or the cathode electrode 4 of the non-inverted structures) is performed by a method selected from the physical vapor deposition methods group as defined above, preferably by thermal evaporation onto the absorber or perovskite layer 7 or onto the absorber layer comprising a perovskite layer or any other layer of the active region R. Said step may be performed under vacuum, at a pressure from 10⁻² to 10⁻¹⁰ mbar, 10⁻² to 10⁻⁷ mbar, preferably of 2×10⁻⁶ mbar.

In a further embodiment, the current collector or the anode electrode 3, 4 comprises or is a metal layer deposited by thermal evaporation.

In a further embodiment, the step of providing the current collector or anode electrode 3, 4 is performed by a deposition method from a solution as defined above, namely being selected from drop casting, spin-coating, dip-coating, curtain coating, spray-coating, and ink-jet printing, meniscus coating.

According to another embodiment, the current collector or anode electrode 3, 4 has a thickness being ≦30 nm, ≦50 nm, ≦70 nm, ≦90 nm, or ≦110 nm, preferably ≦70 nm. Accordingly, the step of providing the current collector or anode electrode 3, 4 lasts up to that said current collector 3, 4 has reached the desired thickness defined above.

In an embodiment of the method of the invention, the application or deposition of the electron transport material layer 23 is performed by a deposition method from solution selected from drop casting, spin-coating, dip-coating, curtain coating, spray-coating, and ink-jet printing, meniscus, preferably by meniscus coating. The solution may comprise one or more materials or two or more solutions may mixed and applied in a one-step process to form a film or applied in a process comprising two or more sequential steps.

In another embodiment, the application or deposition may be performed by a physical vapor deposition method, a chemical vapor deposition method or a deposition by sublimation, namely sublimation.

According to another embodiment, the electron transport material layer 23 has a thickness being ≦5, ≦10 nm, ≦20 nm, ≦50 nm, preferably from 4 to 50 nm, from 5 to 20 nm.

The electron transporting material 23 is or includes one of the following: TiO₂, with 0.1 to 5 Y or Ga doped TiO₂, [6,6]-phenyl-C61-butyric acid methyl ester (PCBM), 1,4,5,8,9,11-hexazatriphenylene-hexacarbonitrile (HAT-CN), (C60-In)^{[5,6]} fullerene (C60), (C70-D5 h)^{[5,6]} fullerene (C70), [6,6]-Phenyl C₇₁ butyric acid methyl ester (PC70BM), 2,9-dimethyl-4,7-diphenyl-1,10-phenanthroline (BCP), 1,3,5-tri(phenyl-2-benzimi-dazolyl)-benzene (TPBI), preferably PCBM, HAT-CN, C60, C70, PC70BM, and metal oxide. The electron transporting material 23 can be deposited at room temperature from a solution using, for example, a meniscus-coating process (see for example, Malinkiewicz et al, Nature photonics, Vol. 8, February 2014, page 131).

In an embodiment, the step of providing a carrier (hole) collector layer or cathode electrode 4 of the inverted embodiments comprises a step of providing a conducting layer being transparent and a step of applying a conducting material onto the conducting layer. Namely the hole collector layer or electrode 4 may comprise a conducting layer being transparent and a conducting material. Said conducting layer is selected from conducting glass or conducting plastic. The conducting material is selected from indium doped thin oxide (ITO), fluorine doped tin oxide (FTO), ZnO—Ga₂O₃, ZnO-Al₂O₃, tin-oxide, antimony doped tin oxide (ATO), SrGeO₃ and zinc oxide. Accordingly, the hole collector or electrode 4 may comprise or may consist of a conducting layer and a conductive material.

In another embodiment, the step of providing a hole collector layer or electrode 4 comprises a further step of providing a surface-increasing scaffold structure between the conducting layer and the conducting material layer. Accordingly, the hole collector layer or electrode 4 may comprise a conducting layer, a surface-increasing scaffold structure and a conducting material layer.

According to another embodiment, the method of invention comprises a further step of providing a support layer 17 on the external side of the hole collector or electrode 4 (see for example FIG. 13(b)). Said support layer 17 may be the hole collector or the conducting layer of the hole collector or electrode 4, or comprises the hole collector or is provided before the conducting layer of the hole collector, namely to the external side of the hole collector.

In a further embodiment, the method of invention comprises a further step of providing a support layer 19 on the side of the current collector and/or metal layer or conductor layer, preferably on the top of the current collector or anode electrode 3.

The surface increasing scaffold structure 13 can be prepared and deposited in the same way and using the same materials as described above in relation to the non-inverting architecture described in relation to, for example, FIGS. 10 and 11.

Similarly, the hole transporting layer HTM 11 can be prepared and deposited in the same way and using the same materials as described above in relation to the non-inverting architecture described in relation to, for example, FIGS. 9 to 12.

The invention also provides a low voltage photodetector obtainable or obtained by the production method of the present invention.

In the inverted architecture embodiment, the hole collector layer or electrode 4 of the photodetector is preferably on the side exposed to or for receiving the light to be measured or detected.

The hole collector or electrode 4 is preferably arranged to collect and conduct the holes generated in the absorber layer or perovskite 7.

According to an embodiment, the device or photodetector 1 according to any previous embodiment of the invention preferably comprises one or more support layers 17. The support layer preferably provides physical support of the device. Furthermore, the support layer 17 preferably provides a protection with respect to physical damage and thus delimits the photodetector 1 with respect to the outside, for example on at least one of the two sides of the photodetector 1, that is located on the one exposed to the incident light to be detected (support layer 17) or on the opposite side that remains in the dark (current support layer). According to an embodiment, the photodetector 1 may be constructed by applying the different layers photodetector in a sequence of steps, one after the other, onto the support layer. The support layer may thus also serve as a starting support for the fabrication of the photodetector. Support layers may be provided on only one or on both opposing sides of the photodetector.

The support layer, if present, is preferably transparent, so as to let light pass through the photodetector. Of course, if the support layer is provided on the side of the photodetector that is not directly exposed to light to be converted to electrical charge, the support does not necessarily have to be transparent. However, any support layer provided on the side that is designed and/or adapted to be exposed to light for the purpose of energy conversion is preferably transparent. “Transparent” means transparent to at least a part, preferably a major part of the visible light. Preferably, the support layer is substantially transparent to all wavelengths or types of visible light. Furthermore, the support layer may be transparent to non-visible light, such as UV and IR radiation, for example.

In a preferred embodiment of the invention, a support layer 17 is provided, said support layer serving as support as described above as well as the conducting layer of the hole collector or electrode. The support layer thus replaces or contains the conducting layer. The support layer is preferably transparent. Examples of support layers are conducting glass or conducting plastic, which are commercially available. For example, the support layer comprises a material selected from indium doped tin oxide (ITO), fluorine doped tin oxide (FTO), ZnO—Ga₂O₃, ZnO—Al₂O₃, tin oxide, antimony doped tin oxide (ATO), SrGeO₃ and zinc oxide, coated on a transparent substrate, such as plastic or glass.

In accordance with an embodiment of the method of the invention, when a surface-increasing scaffold structure is provided between the conducting layer and the conducting material of the hole conductor, the surface-increasing scaffold structure is nanostructured and/or nanoporous. The scaffold structure is thus preferably structured on a nanoscale. The structures of said scaffold structure increase the effective surface compared to the surface of the conducting layer.

According to an embodiment, the surface-increasing scaffold structure of the photo detector of the invention comprises, consists essentially of or is made from one selected from the group consisting of a semiconductor material, a conducting material, a non-conducting material and combinations of two or more of the aforementioned.

According to an embodiment, said scaffold structure is made from and/or comprises a metal oxide. For example, the material of the scaffold structure is selected from semiconducting materials, such as Si, TiO₂, SnO₂, Fe₂O₃, ZnO, WO₃, Nb₂O₅, CdS, ZnS, PbS, Bi₂S₃, CdSe, CdTe, SrTiO₃, GaP, InP, GaAs, CuInS₂, CuInSe₂, and combinations thereof, for example. Preferred semiconductor materials are Si, TiO₂, SnO₂, ZnO, WO₃, Nb₂O₅ and SrTiO₃.

However, the material of the scaffold structure does not need to be semiconducting or conducting, but could actually be made from a non-conducting and/or insulating material. As described in PCT/IB2013/056080, for example, the scaffold structure could be made from plastics, for example from plastic nanoparticles, which are in any way assembled on the support and are fixed thereon, for example by heating and/or cross-linking. Polystyrene (PS) spheres of sub-25 micrometer size deposited on a conducting substrate can be cited as an example of a non-conducting scaffold structure.

The invention encompasses the device or photodetector 1 comprising the absorber or perovskite layer 7 and the step of applying an absorber layer 7. The absorber or perovskite layer 7 is preferably a light-absorbing compound or material. Preferably, the absorber layer 7 is a pigment.

According to a preferred embodiment, the absorber layer 7 comprises, consists essentially of or consists of a nanocomposite material or an organic-inorganic pigments. According to a preferred embodiment, the absorber layer 7 comprises, consists essentially of or consists of an organic-inorganic perovskite.

According to an embodiment, the organic-inorganic perovskite material that is used and/or obtained in the one or more perovskite layer preferably comprises a perovskite-structure of any one of formulae (I), (II) , (III), (IV), (V) and/or (VI) below:

AA′MX₄ (I)

AMX₃ (II)

AA′N_{2/3}X₄ (III)

AN_{2/3}X₃ (IV)

BN_{2/3}X₄ (V)

BMX₄ (VI)

wherein,

A and A′ are organic, monovalent cations that are independently selected from primary, secondary, tertiary or quaternary organic ammonium compounds, including N-containing heterorings and ring systems, A and A′ having independently from 1 to 60 carbons and 1 to 20 heteroatoms;

B is an organic, bivalent cation selected from primary, secondary, tertiary or quaternary organic ammonium compounds having from 1 to 60 carbons and 2-20 heteroatoms and having two positively charged nitrogen atoms;

M is a divalent metal cation selected from the group consisting of Cu²⁺, Ni²⁺, Co²⁺, Fe²⁺, Mn²⁺, Cr²⁺, Pd²⁺, Cd²⁺, Ge²⁺, Sm²⁺, Pb²⁺, Eu²⁺, or Yb^{2 +};

N is selected from the group of Bi3+ and Sb3+; and,

the three or four X are independently selected from Cl⁻, Br⁻, I⁻, NCS⁻, CN⁻, and NCO⁻.

In particular, the three or four X may be the same or different. For example, in AMX₃ (formula II) may be expressed as formula (II′) below:

AMXⁱXⁱⁱXⁱⁱⁱ (II′)

wherein Xⁱ, Xⁱⁱ, Xⁱⁱⁱ are independently selected from Cl⁻, Br⁻, I⁻, NCS⁻, CN⁻, and NCO⁻, preferably from halides (Cl⁻, Br⁻, I⁻), and A and M are as defined elsewhere in this specification. Xⁱ, Xⁱⁱ, Xⁱⁱⁱ may thus be the same or different in this case. The same principle applies to the perovskites of formulae (I) and (III)-(VI) and the more specific embodiments of formulae (VIII) to (XIV) below. In case of AA′MX₄ (formula I), for example, formula (I′) applies:

AA′M XⁱXⁱⁱXⁱⁱⁱX^{iv} (I′)

wherein Xⁱ, Xⁱⁱ, Xⁱⁱⁱ are independently selected from Cl⁻, Br⁻, I⁻, NCS⁻, CN⁻, and NCO⁻, preferably from halides (Cl⁻, Br⁻, I⁻).

Preferably, if Xⁱ, Xⁱⁱ, Xⁱⁱⁱ in formulae (II) and (IV) or Xⁱ, Xⁱⁱ, Xⁱⁱⁱ, X^{iv} in formulae (I), (III), (V) or (VI) comprise different anions X, there are not more than two different anions. For example, Xⁱ and Xⁱⁱ being the same with Xⁱⁱⁱ being an anion that is different from Xⁱ and Xⁱⁱ.

According to a preferred embodiment, the perovskite material has the structure selected from one or more of formulae (I) to (III), preferably (II) or (II′).

According to a preferred embodiment, said organic-inorganic perovskite layer comprises a perovskite-structure of any one of the formulae (VIII) to (XIV):

APb X₃ (VIII)

ASnX₃ (IX)

ABiX₄ (X)

AA′Pb X₄ (XI)

AA′SnX₄ (XII)

BPbX₄ (XIII)

B SnX₄ (XIV)

wherein A, A′, B and X are as defined elsewhere in this specification. Preferably, X is preferably selected from Cl⁻, Br⁻ and I⁻, most preferably X is I⁻.

According to a preferred embodiment, said organic-inorganic perovskite layer comprises a perovskite-structure of the formulae (VIII) to (XII), more preferably (VIII) and/or (IX) above.

According to an embodiment, A and A′, for example in AX and/or in any one of formulae (I) to (IV), and (VIII) to (XII), are monovalent cations selected independently from any one of the compounds of formulae (1) to (8) below:

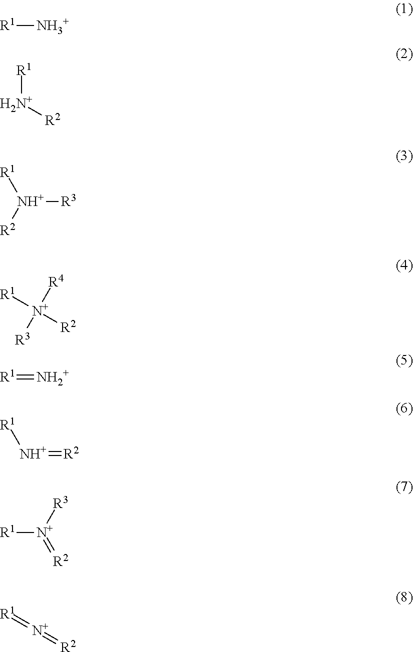

wherein,

any one of R¹, R², R³ and R⁴ is independently selected from C1-C15 organic substituents comprising from 0 to 15 heteroatoms.

According to an embodiment of said C1-C15 organic substituent any one, several or all hydrogens in said substituent may be replaced by halogen and said organic substituent may comprise up to fifteen (15) N, S or O heteroatoms, and wherein, in any one of the compounds (2) to (8), the two or more of substituents present (R¹, R², R³ and R⁴, as applicable) may be covalently connected to each other to form a substituted or unsubstituted ring or ring system. Preferably, in a chain of atoms of said C1-C15 organic substituent, any heteroatom is connected to at least one carbon atom. Preferably, neighboring heteroatoms are absent and/or heteroatom-heteroatom bonds are absent in said C1-C15 organic substituent comprising from 0 to 15 heteroatoms.

According to an embodiment any one of R¹, R², R³ and R⁴ is independently selected from C1 to C15 aliphatic and C4 to C15 aromatic or heteroaromatic substituents, wherein any one, several or all hydrogens in said substituent may be replaced by halogen and wherein, in any one of the compounds (2) to (8), the two or more of the substituents present may be covalently connected to each other to form a substituted or unsubstituted ring or ring system.

According to an embodiment, B is a bivalent cation selected from any one of the compounds of formulae (9) and (10) below:

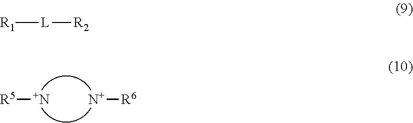

wherein,

in the compound of formula (9), L is an organic linker structure having 1 to 10 carbons and 0 to 5 heteroatoms selected from N, S, and/or O, wherein any one, several or all hydrogens in said L may be replaced by halogen;

wherein any one of R₁ and R₂, is independently selected from any one of the sub stituents ( 20 ) to (25) below:

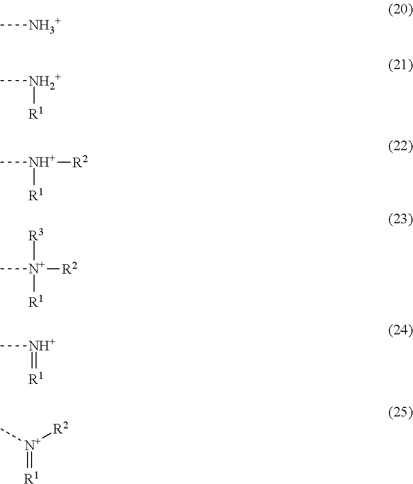

wherein the dotted line in the substituents (20) to (25) represents the bond by which said substituent is connected to the linker structure L;

wherein R¹, R², and R³ are independently as defined above with respect to the compounds of formulae (1) to (8); wherein R₁ and R₂, if they are both different from substituent (20), may be covalently connected to each other by way of their substituents R¹, R², and/or R³, as applicable, and wherein any one of R¹, R², and R³, if present, may be covalently connected to L or the ring structure of compound (10), independently from whether said substituent is present on R₁ or R₂; and wherein, in the compound of formula (10), the circle containing said two positively charged nitrogen atoms represents a substituted or unsubstituted aromatic ring or ring system comprising 4 to 15 carbon atoms and 2 to 7 heteroatoms, wherein said nitrogen atoms are ring heteroatoms of said ring or ring system, and wherein the remaining of said heteroatoms may be selected independently from N, O and S and wherein R⁵ and R⁶ are independently selected from H and from substituents as R¹ to R⁴. Halogens substituting hydrogens totally or partially may also be present in addition to and/or independently of said 2 to 7 heteroatoms.

Preferably, if the number of carbons is in L is impair, the number of heteroatoms is smaller than the number of carbons. Preferably, in the ring structure of formula (10), the number of ring heteroatoms is smaller than the number of carbon atoms.

According to an embodiment, L is an aliphatic, aromatic or heteroaromatic linker structure having from 1 to 10 carbons.

Preferably, the dotted line in substituents (20) to (25) represents a carbon-nitrogen bond, connecting the nitrogen atom shown in the sub stituent to a carbon atom of the linker.

According to an embodiment, in the compound of formula (9), L is an organic linker structure having 1 to 8 carbons and from 0 to 4 N, S and/or O heteroatoms, wherein any one, several or all hydrogens in said L may be replaced by halogen. Preferably, L is an aliphatic, aromatic or heteroaromatic linker structure having 1 to 8 carbons, wherein any one, several or all hydrogens in said L may be replaced by halogen.

According to an embodiment, in the compound of formula (9), L is an organic linker structure having 1 to 6 carbons and from 0 to 3 N, S and/or O heteroatoms, wherein any one, several or all hydrogens in said L may be replaced by halogen. Preferably, L is an aliphatic, aromatic or heteroaromatic linker structure having 1 to 6 carbons, wherein any one, several or all hydrogens in said L may be replaced by halogen.

According to an embodiment, in the compound of formula (9), said linker L is free of any O or S heteroatoms. According to an embodiment, L is free of N, O and/or S heteroatoms.

According to an embodiment, in the compound of formula (10), the circle containing said two positively charged nitrogen atoms represents a substituted or unsubstituted aromatic ring or ring system comprising 4 to 10 carbon atoms and 2 to 5 heteroatoms (including said two ring N-atoms).

According to an embodiment, said ring or ring system in the compound of formula (10) is free of any O or S heteroatoms. According to an embodiment, said ring or ring system in the compound of formula (10) is free of any further N, O and/or S heteroatoms, besides said two N-ring atoms. This does not preclude the possibility of hydrogens being substituted by halogens.

As the skilled person will understand, if an aromatic linker, compound, substituent or ring comprises 4 carbons, it comprises at least 1 ring heteroatom, so as to provide an aromatic moiety.

According to an embodiment, any one of R¹, R², R³ and R⁴ is independently selected from C1 to C8 organic substituents comprising, from 0 to 4 N, S and/or O heteroatom, wherein, independently of said N, S or O heteroatoms, any one, several or all hydrogens in said substituent may be replaced by halogen, and wherein two or more of substituents present on the same cation may be covalently connected to each other to form a substituted or unsubstituted ring or ring system. Preferably, any one of R¹, R², R³ and R⁴ is independently selected from C1 to C8 aliphatic, C4 to C8 heteroaromatic and C6 to C8 aromatic substituents, wherein said heteroaromatic and aromatic substituents may be further substituted.

According to an embodiment, any one of R¹, R², R³ and R⁴ is independently selected from C1 to C6 organic substituents comprising, from 0 to 3 N, S and/or O heteroatom, wherein, independently of said N, S or O heteroatoms, any one, several or all hydrogens in said substituent may be replaced by halogen, and wherein two or more of substituents present on the same cation may be covalently connected to each other to form a substituted or unsubstituted ring or ring system. Preferably, any one of R¹, R², R³ and R⁴ is independently selected from C1 to C6 aliphatic, C4 to C6 heteroaromatic and C6 to C6 aromatic substituents, wherein said heteroaromatic and aromatic substituents may be further substituted.

According to an embodiment, any one of R¹, R², R³ and R⁴ is independently selected from C1 to C4, preferably C1 to C3 and most preferably C1 to C2 aliphatic substituents wherein any one, several or all hydrogens in said substituent may be replaced by halogen and wherein two or more of substituents present on the same cation may be covalently connected to each other to form a substituted or unsubstituted ring or ring system.

According to an embodiment, any one of R¹, R², R³ and R⁴ is independently selected from C1 to C10 alkyl, C2 to C10 alkenyl, C2 to C10 alkynyl, C4 to C10 heteroaryl and C6 to C10 aryl, wherein said alkyl, alkenyl, and alkynyl, if they comprise 3 or more carbons, may be linear, branched or cyclic, wherein said heteroaryl and aryl may be substituted or unsubstituted, and wherein several or all hydrogens in R¹-R⁴ may be replaced by halogen.

According to an embodiment, any one of R¹, R², R³ and R⁴ is independently selected from C1 to C8 alkyl, C2 to C8 alkenyl, C2 to C8 alkynyl, C4 to C8 heteroaryl and C6 to C8 aryl, wherein said alkyl, alkenyl, and alkynyl, if they comprise 3 or more carbons, may be linear, branched or cyclic, wherein said heteroaryl and aryl may be substituted or unsubstituted, and wherein several or all hydrogens in R¹-R⁴ may be replaced by halogen.

According to an embodiment, any one of R¹, R², R³ and R⁴ is independently selected from C1 to C6 alkyl, C2 to C6 alkenyl, C2 to C6 alkynyl, C4 to C6 heteroaryl and C6 aryl, wherein said alkyl, alkenyl, and alkynyl, if they comprise 3 or more carbons, may be linear, branched or cyclic, wherein said heteroaryl and aryl may be substituted or unsubstituted, and wherein several or all hydrogens in R¹-R⁴ may be replaced by halogen.

According to an embodiment, any one of R¹, R², R³ and R⁴ is independently selected from Cl to C4 alkyl, C2 to C4 alkenyl and C2 to C4 alkynyl, wherein said alkyl, alkenyl and alkynyl, if they comprise 3 or more carbons, may be linear, branched or cyclic, and wherein several or all hydrogens in in R¹-R⁴ may be replaced by halogen.

According to an embodiment, any one of R¹, R², R³ and R⁴ is independently selected from Cl to C3, preferably C1 to C2 alkyl, C2 to C3, preferably C2 alkenyl and C2 to C3, preferably C2 alkynyl, wherein said alkyl, alkenyl and alkynyl, if they comprise 3 or more carbons, may be linear, branched or cyclic, and wherein several or all hydrogens in R¹-R⁴ may be replaced by halogen.

According to an embodiment, any one of R¹, R², R³ and R⁴ is independently selected from Cl to C4, more preferably C1 to C3 and even more preferably C1 to C2 alkyl. Most preferably, any one of R¹, R², R³ and R⁴ are methyl. Again, said alkyl may be completely or partially halogenated.

According to an embodiment, A, A′ and B are monovalent (A, A′) and bivalent (B) cations, respectively, selected from substituted and unsubstituted C5 to C6 rings comprising one, two or more nitrogen heteroatoms, wherein one (for A and A′) or two (for B) of said nitrogen atoms is/are positively charged. Substituents of such rings may be selected from halogen and from C1 to C4 alkyls, C2 to C4 alkenyls and C2 to C4 alkynyls as defined above, preferably from C1 to C3 alkyls, C3 alkenyls and C3 alkynyls as defined above. Said ring may comprise further heteroatoms, which may be selected from O, N and S. Bivalent organic cations B comprising two positively charged ring N-atoms are exemplified, for example, by the compound of formula (10) above. Such rings may be aromatic or aliphatic, for example.

A, A′ and B may also comprise a ring system comprising two or more rings, at least one of which being from substituted and unsubstituted C5 to C6 ring as defined as above. The elliptically drawn circle in the compound of formulae (10) may also represent a ring system comprising, for example, two or more rings, but preferably two rings. Also if A and/or A′ comprises two rings, further ring heteroatoms may be present, which are preferably not charged, for example.

According to an embodiment, however, the organic cations A, A′ and B comprise one (for A, A′), two (for B) or more nitrogen atom(s) but are free of any O or S or any other heteroatom, with the exception of halogens, which may substitute one or more hydrogen atoms in cation A and/or B.

A and A′ preferably comprise one positively charged nitrogen atom. B preferably comprises two positively charged nitrogen atoms.

A, A′ and B may be selected from the exemplary rings or ring systems of formulae (30) and (31) (for A) and from (32) to (34) (for B) below:

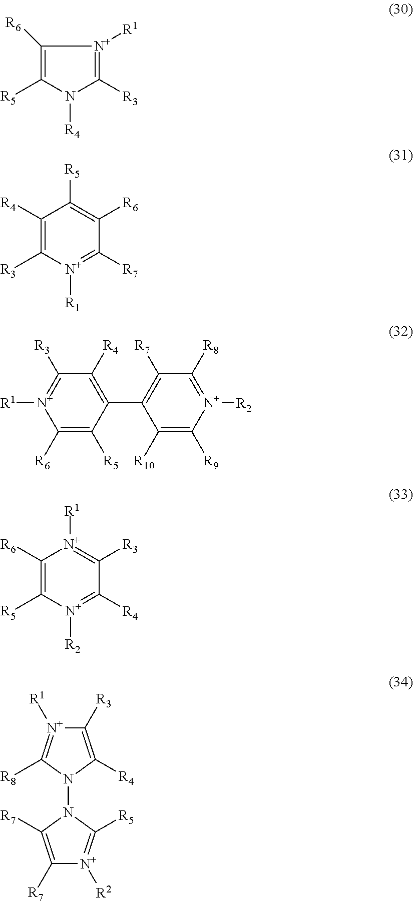

in which R¹ and R² are, independently, as defined above, and R₃, R₄, R₅, R₆, R₇, R₈, R₉ and R¹⁰ are independently selected from H, halogen and substituents as defined above for R¹ to R⁴. Preferably, R₃-R₁₀ are selected from H and halogen, most preferably H.

In the organic cations A, A′ and B, hydrogens may be substituted by halogens, such as F, Cl, I, and Br, preferably F or Cl. Such a substitution is expected to reduce the hygroscopic properties of the perovskite layer or layers and may thus provide a useful option for the purpose of the present specification.

According to a preferred embodiment, A and A′ are independently selected from organic cations of formula (1). Preferably, R¹ in the cation of formula (1) is selected from C1 to C8 organic substituents comprising, from 0 to 4 N, S and/or O heteroatom. More preferably, R¹ is selected from C1 to C4, preferably C1 to C3 and most preferably C1 to C2 aliphatic substituents.

According to a preferred embodiment, the metal M is selected from Sn²⁺ and Pb²⁺, preferably Pb²⁺. According to a preferred embodiment, N is Sb³⁺.

According to a preferred embodiment, the three or four X are independently selected from Cl⁻, Br⁻, and I⁻.

According to a preferred embodiment, the organic-inorganic perovskite material has the formula of formulae (XV) to (XIX) below:

AMI₃ (XV)

AMI₂Br (XVI)

AMI₂Cl (XVII)

AMBr₃ (XVII)

AMCl₃ (XIX)

wherein A and M are as defined elsewhere in this specification, including the preferred embodiments of A and M, such as those defined below. Preferably, M is selected from Sn²⁺ and Pb²⁺. Preferably, A is selected from organic cations of formula (1). Preferably, R¹ in the cation of formula (1) is selected from C1 to C8 organic substituents comprising, from 0 to 4 N, S and/or O heteroatom. More preferably, R¹ is selected from C1 to C4, preferably C1 to C3 and most preferably C1 to C2 aliphatic substituents.

According to a preferred embodiment, the organic-inorganic perovskite is a compound of formula (VII) (AMXⁱXⁱⁱXⁱⁱⁱ), wherein A is a monovalent cation of formula (1) as defined above, M is as defined elsewhere in this specification, and Xⁱ, Xⁱⁱ, Xⁱⁱⁱ are independently selected from Cl⁻, Br⁻, I⁻. Preferably, R¹ in the cation of formula (1) is selected from C1 to C4, preferably C1 to C3 and most preferably C1 to C2 aliphatic substituents.

According to a preferred embodiment, the organic-inorganic perovskite is a compound of formula (VII) (AMXⁱXⁱⁱXⁱⁱⁱ), wherein A is a monovalent cation of formula (1) as defined above, M is Sn²⁺ or Pb²⁺, and Xⁱ, Xⁱⁱ, Xⁱⁱⁱ are independently selected from Cl⁻, Br⁻, I⁻. Preferably, R^{I-} in the cation of formula (1) is selected from C1 to C4, preferably C1 to C3 and most preferably C1 to C2 aliphatic substituents. Preferably, Xⁱ-Xⁱⁱⁱ are identical.

In the methods of the invention, if the absorber layer 7 comprises an organic-inorganic perovskite layer or consist of a perovskite layer or contains organic-inorganic perovskite pigments, the perovskite layer or pigments may be applied in direct contact with and/or on the electron blocking layer. The hole transporting/electron blocking layer consists or aromatic amine derivatives consisting of the group of triphenylamine, carbazole, (N,N,(diphenyl)-N′,N′di-(alkylphenyl)-4,4′-biphenyldiamine), (pTPDs), diphenylhydrazone, etc., i.e. molecules able to transport holes, as described for example in the book: “Organic Photoreceptors for Imaging Systems”, appendix 3, by Paul M. Borsenberger and David S. Weiss, Marcel Dekker, Inc, NY 1998. poly [N,N′-bis(4-butylphenyl)-N,N′-bis(phenyl)benzidine] (polyTPD), poly(9,9-dioctylfluorene-alt-N-(4-butylphenyl)-diphenylamine (TFB), 2,2′,7,740 -tetrakis-N,N-di-p-methoxyphenylamine-9,9′-spirobifluorene) (spiro-OMeTAD), N,N,N′,N′-tetraphenylbenzidine (TPD), preferably form polyTPD, polyTPD's substituted with electron donor groups and acceptor groups.

SEM: Film morphology was investigated by using a high-resolution scanning electron microscope (Merlin, Zeiss) equipped with a GEMINI II column and a Schottky Field Emission gun. Images were acquired with an In-Lens Secondary Electron Detector.

Cyclic voltammetry: CV measurements were carried out in a three electrode setup with an Autolab PGSTAT30 (EcoChemie B.V) under oxygen free atmosphere due to Argon bubbling. The aqueous supporting electrolyte contained 0.5 M KCl and the one electron redox couple K₄[Fe(II)(CN)₆]/K₃[Fe(III)(CN)₆] with a concentration of 0.5 mM yielding a yellowish coloured solution. The reference electrode used was an Ag/AgCl (sat.), the counter electrode was a Pt wire and the scan velocity of the measurements was 50 mV/s.

JV characterisation: The photo detectors were measured using a 450 W xenon light source (Oriel) with an irradiance of 100 mW/cm². A Schott K113 Tempax filter (Prazisions Glas & Optik GmbH) was used to reduce the spectral mismatch between AM 1.5 G and the simulated illumination to ˜4 % between 350-750 nm. Current-Voltage characteristics of the devices were obtained by applying an external voltage bias (from forward to reverse) while measuring the current response with a source meter (Keithley 2400). The voltage step and equilibration times were 10 mV and 500 ms, respectively. The cells were covered with a thin mask (0.16 mm²) to reduce scattered light.

The current voltage measurements were recorded with a Bio-Lobic SP300 potentiostat in 50 mV steps with a retention time of 60 s at each bias potential before the actual current measurement started. For the measurements under light a white light LED array with a light intensity of about 1 sun was used and the mask used had an area similar to the whole active area of the PA to maintain a similar area for the dark and photocurrent measurements.

Herein, we demonstrate further details of the high-gain, low-voltage CH₃NH₃PbI₃ photodetectors 1 of the present invention in various architectures. We observe photomultiplication in all structures with direct contact of FTO and perovskite with the highest responsivity 208 A W⁻¹ corresponding to an IPCE of 47,000%. Studying the dynamics and temperature dependence, we find a slow process with an activation energy of 420±90 meV in the time scale of seconds, which is essential to photocurrent multiplication. We develop a model based on ion migration to explain the observed transients and the photomultiplication. The accumulation of negative ionic charge at the FTO(electrode)/perovskite interface under reverse bias lowers the FTO work function allowing for direct hole injection into the perovskite valence band. Under illumination, the conductivity of perovskite is increased and the device behaves similar to a photoconductor.

Solution-processable organic-inorganic lead halide perovskites with the formula CH₃NH₃PbX₃ (where X is Cl, Br or I) have attracted significant attention as new optoelectronic materials for photovoltaics,^{[18]} photodetectors,^{[9-19]} phototransistors,^{[13, 20]} light emitting diodes,^{[21]} and lasers. ^{[22, 23]}

The perovskite materials were shown to possess favorable properties for photovoltaic applications,^{[24]} and electrical power conversion efficiencies of 20.1% have been achieved within only five years of development.^{[25]} Recently, it has been demonstrated that organic-inorganic lead halide perovskites are also suitable candidates for high-performance photodetectors.^{[11, 26]}

Photodetectors, which convert incident optical signals to electrical signals, are key components for optical communication, photography, environmental sensing, medical analysis, astronomy, and safety equipment.^{[27]}

An important class of photodetectors are those exhibiting intrinsic photocurrent amplification (gain) meaning that an incident photon triggers an electrical current flow provided by numerous electrons. Gain increases the sensitivity of the detector making it suitable for applications such as receivers in optical fiber communication, high-resolution imaging, single photon counting, and laser microscopy. ^{[28]}

We present here an exemplary vertical stack geometry CH₃NH₃PbI₃—based photodetector 1 operated at a very low voltage (−0.6 V), which is characterized by a very high average gain of 1300 and a peak IPCE of 50,000%. We demonstrate that the only prerequisite to obtain high gain in this type of devices is a direct contact between CH₃NH₃PbI₃ and fluorine-doped tin oxide (FTO), which shows the versatility of perovskite as a material for high-performance photodetectors.

We investigate steady state and dynamic behavior of the photodetector with respect to illumination and operating voltage. We find that both, a reduction of the hole injection barrier at the FTO(electrode)/perovskite interface under reverse bias and an enhancement of conductivity of the perovskite film under illumination (photoconductivity) are essential for the working mechanism. By investigating the temperature dependent dynamics, we find a characteristic activation energy of 420±90 meV for the process dominating the dynamics of the current response. Our findings are consistent with the movement of ionic species alongside electronic charge carriers within perovskite. By assuming that these ions modify the electronic properties of the FTO/perovskite interface, we provide a model for the operation principles of the photodetector.

### Investigated Architectures

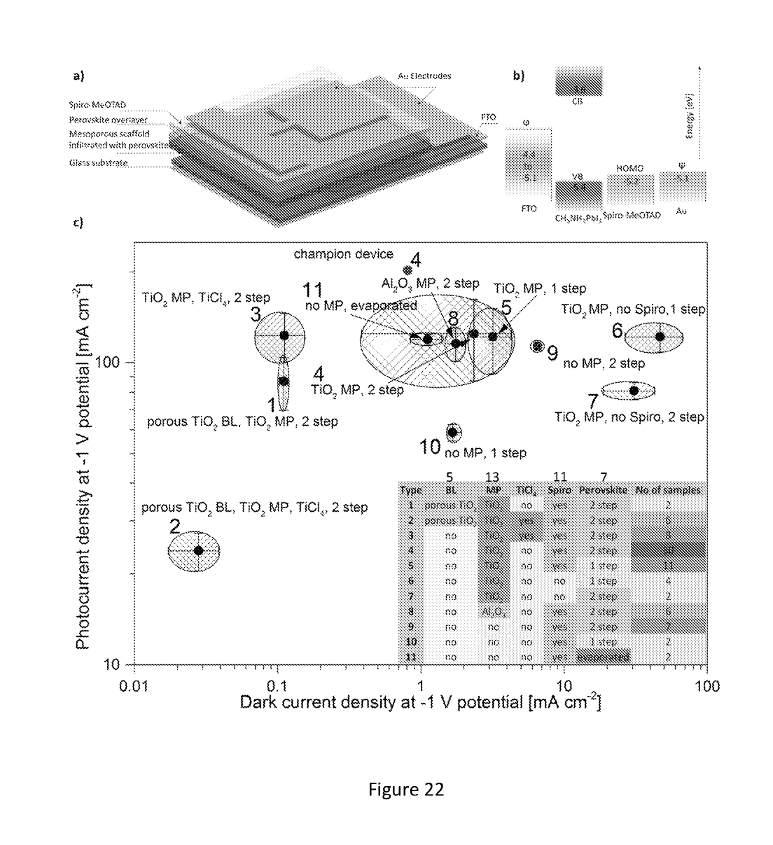

We investigated devices 1 with an architecture similar to that illustrated in FIG. 22(a).^{[26]} On top of FTO—patterned glass 3, a TiO₂ blocking layer (BL) was deposited by spin-coating, spray-pyrolysis or atomic layer deposition (ALD). This was followed by deposition of a mesoporous (MP) metal oxide scaffold 13 (conductive TiO₂ or insulating—Al₂O₃). Optionally, TiCl₄ treatment was employed at this stage of device fabrication. The CH₃NH₃PbI₃ film 7 was deposited using several different methods: interdiffusion of two perovskite precursors (PbI₂ and CH₃NH₃I),^{[4]} orthogonal solvent quenching,^{[2]} or perovskite precursor co-evaporation.^{[29]} Finally, the hole transporting material (HTM 11) Spiro-MeOTAD was spin-coated and Au contacts 9 were thermally evaporated. Employment of a BL, MP scaffold or an HTM was optional and devices in various configurations were studied.

We note that the work function of FTO 3 is not fixed (FIG. 22(b)) and we show later that it can be shifted as a result of ions accumulated at FTO 3/ perovskite 7 interface.

We compared the devices 1 by analyzing their current density-voltage (J-V) characteristics. A standard procedure involved measuring dark J-V characteristics of the devices from 0 V to −1 V (reverse), to +1 V (forward), back to 0 V with 200 mV s⁻¹ scan rate. This was followed by an analogous measurement under white, 100 mW cm⁻² LED illumination. A desirable combination of parameters for the photodetectors 1 was low dark and high photocurrent under reverse bias conditions. We used dark and photocurrent density values at −1 V potential as benchmark parameters to compare fabricated devices and to select the best-performers for an in-depth analysis. The summary of the findings is presented in FIG. 22(c).

The J-V studies showed that devices 1 with pin hole-free compact, spray-pyrolyzed or ALD-deposited TiO₂ BL do not show photocurrent amplification under reverse bias and hence they do not work as photodetectors with gain. We note that already 2 nm-thick compact BL deposited TiO₂ MP completely suppressed photocurrent amplification under reverse bias conditions. Thus creating an interface between the electrode FTO 3 and perovskite 7 proves critical for the photodetector to exhibit gain. We found that replacing a compact BL with a porous one (porous under-layer 5) with the same thickness (deposited via spin-coating) introduced photocurrent amplification (gain) under reverse bias conditions. The gain was further increased when the BL was removed completely (no BL or porous under-layer 5), which is consistent with an increased FTO/ perovskite contact area.

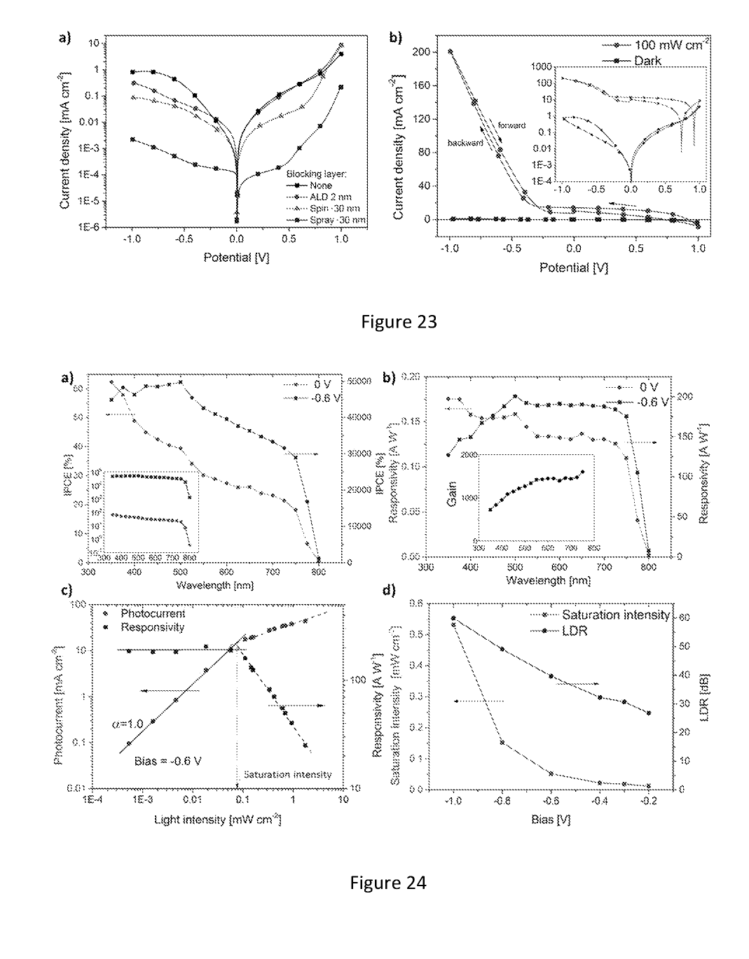

On the other hand, the dark currents also increased when the compact BL was replaced with a porous one and they further increased when the BL was removed completely (FIG. 23(a)). Interestingly, dark currents of devices with 2 nm-thick ALD-deposited BL were very similar to dark currents of devices employing no BL despite the fact that the former did not show photocurrent amplification. This indicates that the BL is sufficiently thin for electrons to tunnel through while at the same time a direct contact between FTO 3 and perovskite 7 is prohibited (due to the pin-hole free, conformal BL obtained from ALD even for very thin films). This underlines once again the importance of the FTO 3/perovskite 7 interface for photocurrent amplification.

Correspondingly, the shunt resistance (calculated from the slope of the dark current at 0 V) decreased from ˜1 MΩ cm² for devices with a compact BL to ˜50 kΩ cm² for devices with a porous BL, to ˜10 kΩ cm² for devices with ALD or without BL.

The TiCl₄ treatment, which creates a 1-3 nm thick porous layer of TiO₂, was found to considerably reduce both dark and photocurrent under reverse bias when applied on samples with a porous TiO₂ BL. However, when applied on devices without a BL and with MP (mesoporous) TiO₂, it reduced dark currents while not affecting the photocurrent significantly, which again is in line with the FTO-perovskite interface being responsible for a functioning photodetector.

Furthermore, we compared devices with TiO₂ or Al₂O₃ MP scaffolds 13. Devices with Al₂O₃ and TiO₂ scaffolds showed very similar J-V characteristics. However, devices without MP scaffold 13 suffered from much increased dark currents (˜8 times increase at −1 V bias) while still showing only slightly lower photocurrents.

In order to exclude that the photocurrent amplification phenomena originates from the perovskite 7/HTM 11 interface, devices 1 without Spiro-MeOTAD layer 11 (and without BL) were fabricated. Such devices still functioned as photodetectors with gain (albeit the gain was much lower than that for devices employing an HTM 11). However, they suffered from ˜13 times increased dark currents as compared to the devices with an HTM 11, which can be explained by increased shunting due to a direct contact of MP TiO₂ 13 with gold 9.

Thus we conclude that as soon as an intimate contact between FTO (electrode 3) and perovskite 7 is present, the device 1 can be operated as a photodetector with gain, regardless of the device architecture or the perovskite deposition method.

We found large variation in photodetector performance of the devices 1 with the same architecture not only between different batches of devices but also within each batch (the standard error on the photocurrent density at −1 V of 30 model devices was 30%). However, we have not observed any instances of devices without a compact BL, which would not function as photodetectors with gain. Devices 1 employing CH₃NH₃PbI₃ can suffer from low reproducibility, which has been a subject of an intense discussion within the photovoltaic community.^{[32]} In general, we observed the highest reproducibility with devices employing no blocking layer and no MP 13, although their photodetector performance was limited due to high dark currents due to shunting.

Following these findings, we fixed our device architecture for further study to a stack of FTO 3/TiO₂ MP scaffold 13/CH₃NH₃PbI₃ 7/Spiro-MeOTAD HTM 11/Au 9 (see FIG. 22(a)). The CH₃NH₃PbI₃ film 7 was deposited via two-step interdiffusion method. We note that the devices with this particular architecture yield the highest-performing devices, however the average performance is not the highest.

### Device Characterization

### Basic Steady-state Characterization

Measured in the dark, the perovskite photodetector exhibits rectifying behavior. A solar to power conversion efficiency of 6.2 % is achieved under 100 mW cm⁻² simulated solar radiation (FIG. 23(b)). However, when the device is biased in reverse direction under illumination, a strong increase in photocurrent is observed, which allows the device to work as both a photovoltaic cell and a high-gain photodetector depending on the direction of the applied bias.

The spectral response of the detector was characterized under 0 V and −0.6 V, reverse bias. As shown in FIG. 24(a) and (b), the detector 1 exhibits high performance across the broad spectrum covering near UV and stretching the entire visible range, while being IR-blind.

The incident photon to current efficiency (IPCE) of the device at short circuit conditions falls from ˜60 % under 350 nm to ˜30 % under 550 nm and ˜20 % under 750 nm illumination. This trend follows the absorbance of the perovskite film 7 (FIG. 30).

Another important parameter for photodetectors is responsivity, which describes the ability of a device to respond to optical signals and it is defined as the ratio of the photogenerated current and the incident light power (Pₕᵥ):

$$R = \frac{{I}_{photo}}{{P}_{hv}} = \frac{{I}_{illuminated} - {I}_{dark}}{{P}_{hv}} \qquad ( 1 )$$

Under short circuit conditions the detector is characterized by low responsivity of 0.18-0.11 A W⁻¹ in 350-750 nm region. When the detector is operated under −0.6 V reverse bias, a peak IPCE of 50,000% is observed under 500 nm illumination. This translates to very high responsivities of 175-200 A W⁻¹ in the 450-750 nm region.

The gain spectrum of the detector can be calculated as the ratio of responsivity at −0.6 V bias and at 0 V (short-circuit condition) bias:

$$Gain = \frac{{R}_{- 0.6 V} - {R}_{SC}}{{R}_{SC}}$$

Gain of 1 indicates that for every pair of photogenerated carriers, there is one additional carrier injected to the perovskite and the overall current flowing through the external circuit is doubled. The gain of the photodetector is found to increase steadily from ˜720 to ˜1600 between 350 nm and 750 nm. This can be attributed to the more homogenous carrier generation within the perovskite layer 7 at longer illumination wavelengths due to a larger penetration depth of the light, which decreases the resistivity of the perovskite more homogeneously.

Linear dynamic range (LDR) describes an illumination intensity range within which the current response of the detector scales linearly with light intensity. It can be obtained as

$$LDR = 20 log \frac{{I}_{upper} - {I}_{dark}}{{I}_{lower} - {I}_{dark}} \qquad ( 2 )$$

where Iᵤₚₚₑᵣ is the current value at which the response of the detector deviates from linearity and I_{lower} is the lower resolution limit. For practical applications, it is desirable for a photodetector to have high LDR. However, the device can be also operated outside LDR if its behavior is well-characterized.

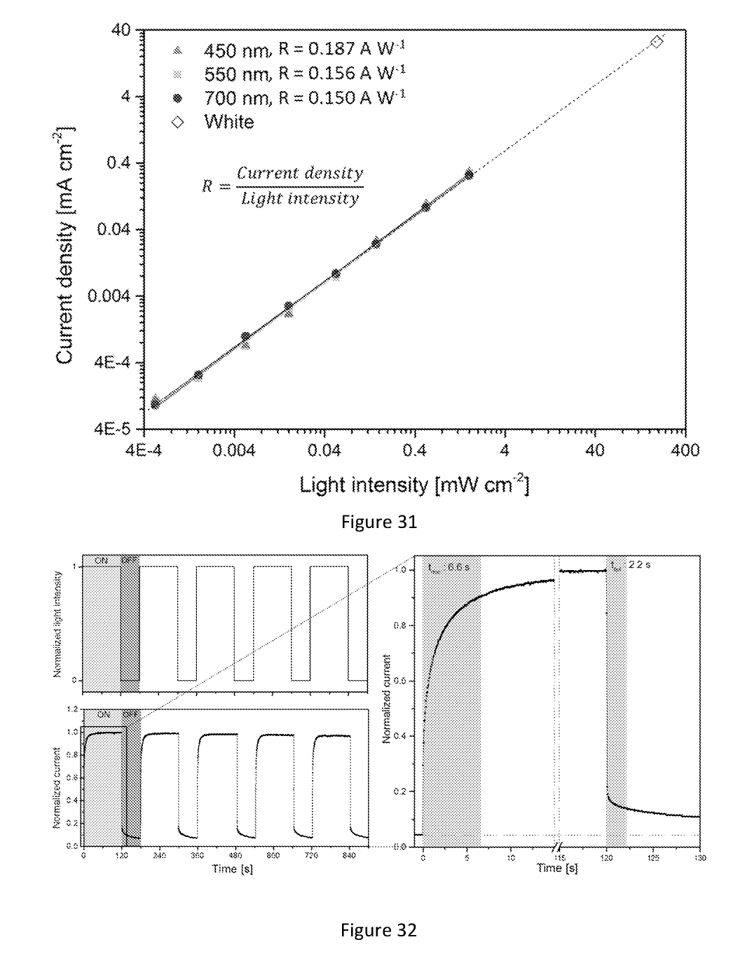

Below the onset for the photocurrent amplification around −0.2 V (including −0.2 V), the response of the detector is linear from 0.5 μW cm⁻² (noise limited) up to at least 100 mW cm⁻², which results in LDR of at least 106 dB (FIG. 31). However, when the device is operated under photocurrent amplification conditions, the signal starts to saturate already below the mW cm⁻² regime (FIG. 24(c)). Photocurrent saturation in photoconductors is known to be related to filling of sensitizing centers.^{[33]} Sensitizing centers are localized states that are empty in the dark and that can capture one type of photogenerated charges, which at low light intensities, increases the overall conductivity of the semiconductor. Under saturation (at higher light intensities), all sensitizing centers are effectively filled. However, the saturation may not be complete either due to the finite lifetime of charges generated above the saturation, or because recombination centers are able to additionally capture some of the photogenerated charges.^{[33]}

The saturation intensity was found to increase substantially under higher operating bias (red line in FIG. 24(d)). Consequently, since the noise limit on the lower end of the linear region (˜0.5 μW cm⁻²) does not considerably vary with operating voltage, LDR increases when the device is operated under higher reverse bias showing an approximately linear scaling with reverse bias (blue line).

Under −0.6 V reverse bias, we have measured a responsivity of 208 A W⁻¹ (IPCE of 47,000 %), which is among the highest values reported for perovskite photodetectors.^{[11, 13, 19, 20]} The current response of the device was found to be linear with irradiance up to 80 μW cm⁻² resulting in a LDR of 44 dB.

We note a broad variability for the saturation intensity from 20 to 110 μW cm⁻² with an average value of 58 μW cm⁻² measured for six identically fabricated devices under −0.6 reverse bias. The average responsivity of those devices was found as 135±55 A W⁻¹.

The high variation in the performance of the detectors is not unusual for optoelectronic devices employing CH₃ NH₃PbI₃ and it shows that a robust method to fabricate perovskite photodetectors is still subject to ongoing research.

### Transient, Light Intensity and Scan Rate Dependent Response

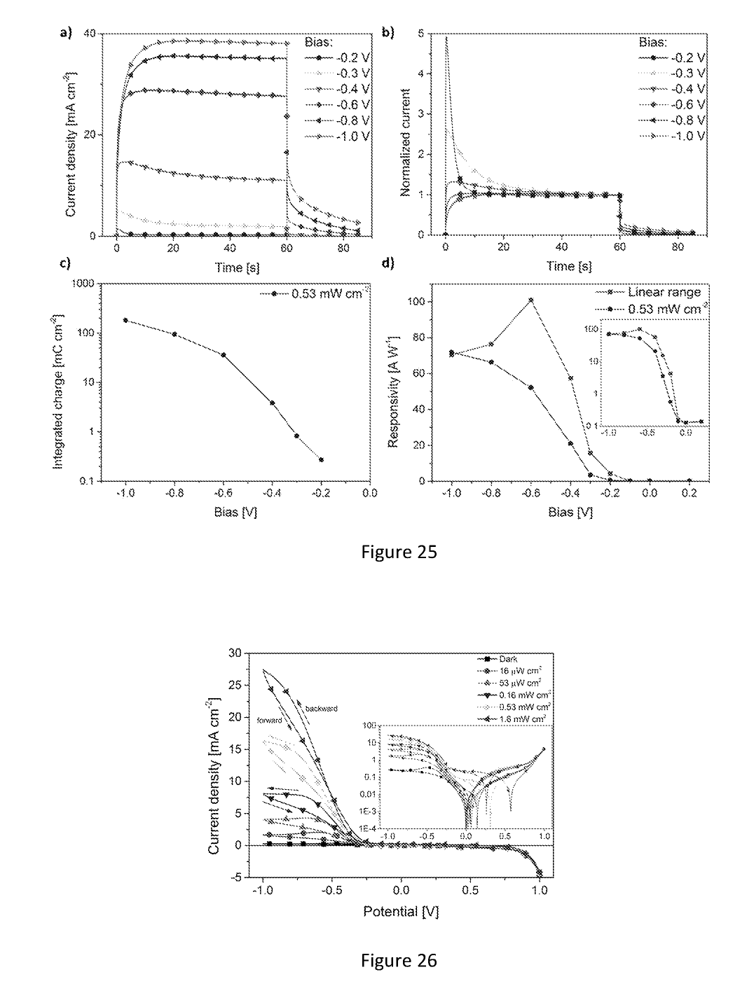

The transient photocurrent response of the device was investigated by biasing the device in reverse direction and exposing it to 60 s-long pulses of 550 nm monochromatic light. Below the onset for photocurrent amplification (also at J_{sc} and under forward bias), the transient response of the detector is relatively fast (<10 ms) and thus not resolved in the investigated timescale of seconds. When the device is biased beyond the photocurrent amplification onset, i.e. when the device is operated under photocurrent amplification conditions, the dynamics become considerably slower and an initial overshoot in current is observed when the light is switched-on (FIG. 25(a) and (b)). This overshoot becomes less pronounced and it peaks later when the voltage is further increased in reverse direction. Although we have observed this overshoot under any bias past the amplification onset, at higher reverse bias the overshoot may not be distinct enough to be identified easily. Subsequently, when light is switched-off, the current decay is composed of two components—a very fast one (cannot be resolved on the investigated timescale of 10 ms) and a very slow one (on the order of seconds). The nature of these two components is likely to be fundamentally different and we hypothesize that the slow component arises due to the movement of ionic species in the perovskite.^{[34, 35]} This transient behavior is fully reproducible (FIG. 32) and the bandwidth of the detector is determined to be in the sub-Hz region due to the very slow dynamics.

The current decay is slower when the light is switched-off and the devices are operated under higher reverse voltage. The amount of charge flowing through the device after light is switched-off can be calculated by fitting the decay curves and integrating the area under them. We determine the charge to be in range of ˜mC cm⁻² (FIG. 25(c)). This is significantly higher than can be expected from the extraction of trapped photogenerated electronic carriers (the trapped charge carrier density would exceed the atomic density of the material) and it implies a photoinduced long-lived rise in injection current from the contacts, which decays on the timescale of seconds after the light is switched-off. These slow transient phenomena are due to a slow change either of the conductivity of the perovskite 7 or of the charge carrier injection rates at the contacts 3, 4 (or a combination of both), which can be interpreted as a signature of movement of ionic species within the perovskite layer 7 and will be analyzed later in this work.

The photodetector exhibits gain and can be operated under any reverse bias greater than the photocurrent amplification onset. However, the responsivity of the device is highly dependent on the operating voltage. FIG. 25(d) shows that below the photocurrent amplification onset at −0.2 V, the responsivity of the device remains very low, which translates to IPCEs below unity. Under higher reverse bias, the responsivity measured within the LDR peaks at −0.6 V before decreasing slightly. The decrease is due to the larger relative contribution of the dark current under higher reverse bias. Under higher illumination intensities (≳0.1 mW cm⁻²) the decrease is not observed since the relative contribution of the dark current is lower.

Interestingly, the responsivity of the device and the total charge flowing through it after light is switched-off follow a very similar trend as a function of operating bias. This may suggest that a photoinduced long-lived rise in injection current is the common origin of both photocurrent amplification and the large amount of post-illumination charge flowing through the device.

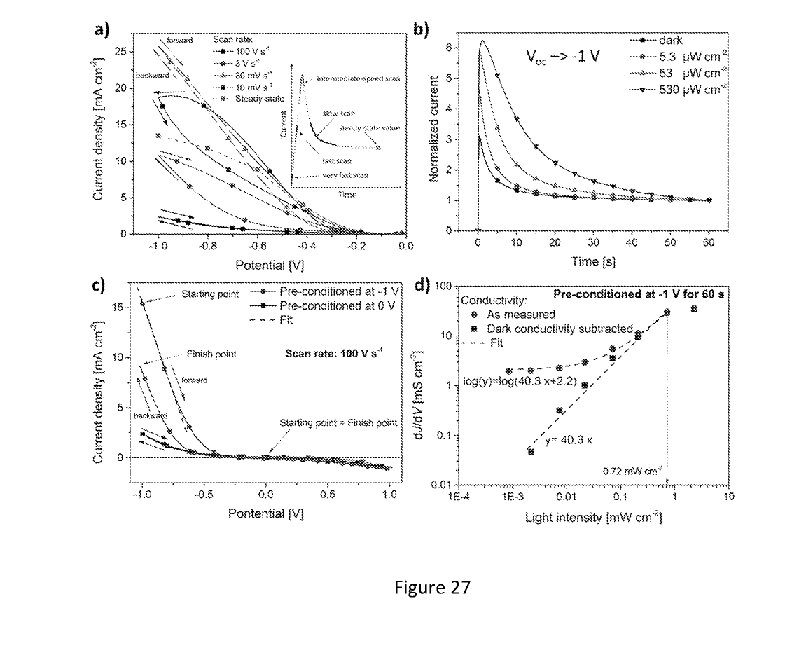

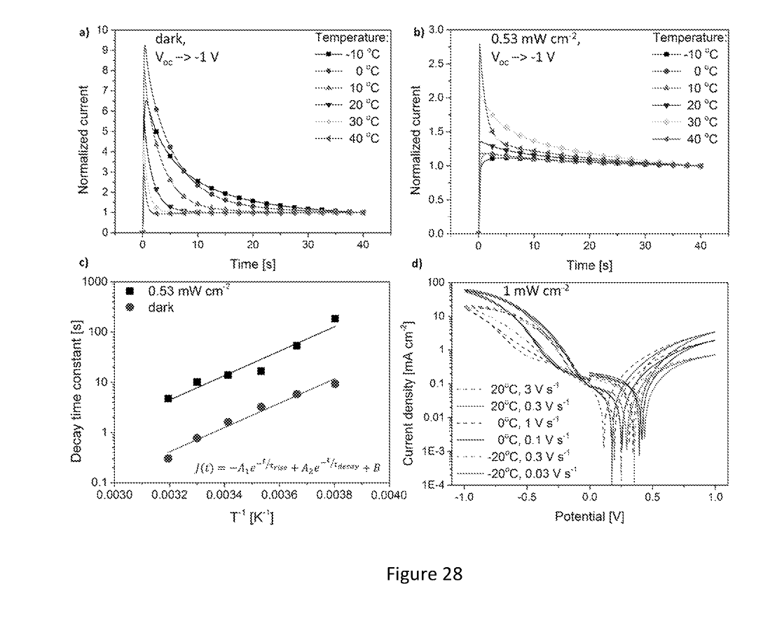

The onset of photocurrent amplification at around −0.2 V is found to be independent of light intensity, light spectrum, scan rate, or temperature. However, under reverse bias, past the onset for photocurrent amplification, the slope and the shape of the J-V curves is heavily dependent on the illumination intensity (FIG. 26), scan rate (FIG. 27) and temperature (FIG. 28), as will become clear further down.

When scanning in backward direction, past the amplification onset, the photocurrent increases sharply with voltage. As the voltage is increased further, the photocurrent saturates and starts to decrease. Scanning beyond this point results in a large J-V hysteresis when the scan is then continued in forward direction (cf. curves for intermediate light intensities in FIG. 26). In general, the further past the current peak the scan is performed, the larger the hysteresis becomes. The trend was found to hold for all of the devices tested and it is also observed in the dark scans suggesting the independence of the phenomena from light. On the other hand, the point at which the photocurrent starts to saturate is dependent on the illumination intensity. In general, the higher the light intensity, the further the saturation voltage shifts towards reverse bias direction (FIG. 26).

The slow photocurrent transients and the hysteresis in the J-V curves of FIG. 26 anticipate a strong dependence on voltage sweep rate. Thus, we measure the J-V curves at different scan rates and following a defined pre-conditioning point (0 V). FIG. 27(a) shows J-V curves measured from 0 V to −1 V and back. When the scan rate is varied, large differences in J-V characteristics of the devices are observed. Again, the most pronounced differences are observed when the device is operated under reverse bias. When very high scan rates are employed (order of 10 s to 100 s V s⁻¹) the photocurrent amplification under reverse bias is almost completely suppressed. Correspondingly, the observed hysteresis is very low. We observe a substantial increase in photocurrent amplification and even higher increase in hysteresis for slightly lower scan rates (several V s⁻¹). The highest photocurrent amplification as well as the lowest hysteresis are obtained when intermediate scan rates are used (30-100 mV s⁻¹). Decreasing the scan rate further to 10 mV s⁻¹ results in both lower photocurrent amplification and higher hysteresis. Overlaying these results with steady-state current values (dashed) reveals that even lower scan rates would be required to achieve hysteresis-free curves.

These seemingly anomalous results of the light intensity and scan rate influence on the J-V characteristics can be explained by investigating the transient behavior of the detector. FIG. 27(b) shows the response of the device when it is subjected to a potential step change from V_{oc} under corresponding light intensity to −1 V (V_{oc} of the devices was found between 90 mV for 530 μW cm⁻² and 0 mV in the dark). Interestingly, immediately after the bias is changed to - 1 V, almost no current flows through the device neither in the dark nor under light. A relatively slow process is responsible for enabling the current to flow and for photocurrent amplification. However, the same process seems to be responsible for the subsequent overshoot in current, which is followed by a slow decay to a saturation value. The dynamics of this behavior are light intensity-dependent and at higher light intensities the process becomes slower.

It is possible to model the response of the device to a potential step with two exponential terms, a positive and a negative one:

J(t)=A₁e⁻^{^{t}}^{/τ}^{ᵣᵢₛₑ})+A₂e⁻^{^{t}}^{/τ}^{_{decay}}+B (3)

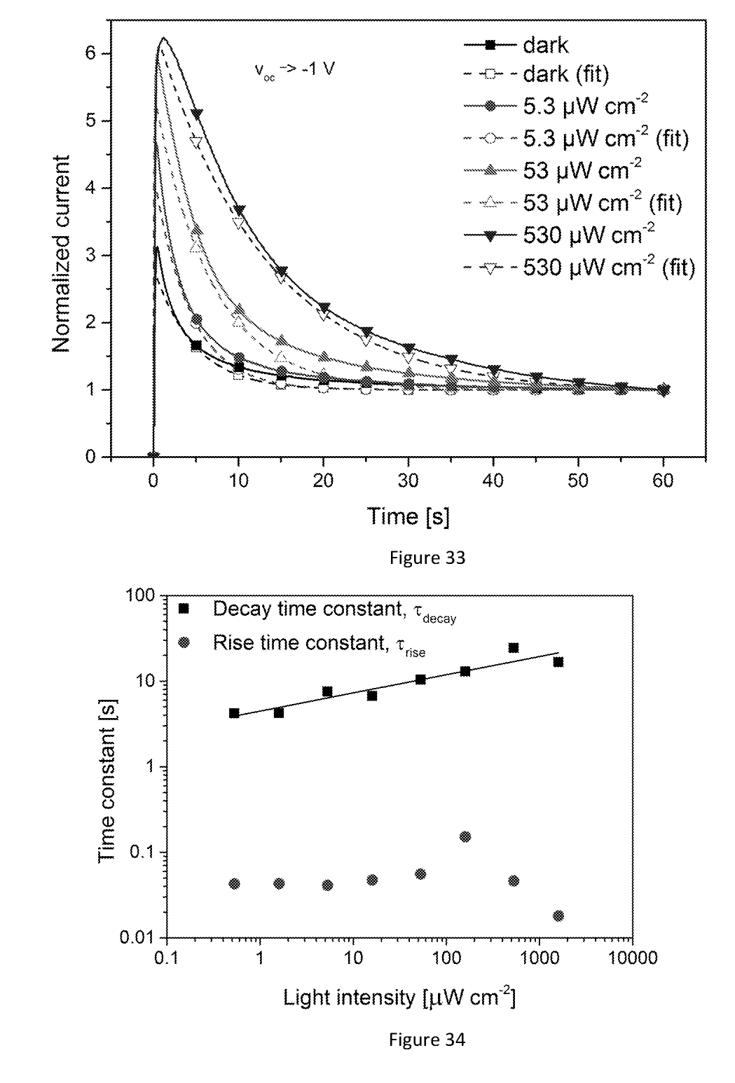

The negative term gives rise to the overshoot in current while the positive term is responsible for the subsequent decay. By fitting the data to this model (FIG. 33) and by analyzing the time constants of the two processes, we have found that light intensity has no apparent influence on the current rise time, which remains below 0.01 s. At the same time the time constant for current decay decreases from ˜20 s at 1.6 mW cm⁻² to ˜4 s at 0.53 μW cm⁻² approximately following a power law relationship (FIG. 34). The observed time scale for current decay is similar to what has been reported for CH₃NH₃PbI₃-based solar cells in the studies of hysteresis.^{[36, 37]}

The inset in FIG. 27(a) explains how photocurrent amplification and hysteresis are related to the transient behavior presented in FIG. 27(b). We note that the device does not have enough time to establish photocurrent amplification when performing a very fast J-V scan. The hysteresis is low since the time interval between forward and reverse scans is very short, which does not permit for significant changes of device's electronic properties; higher current is measured during forward scan (from −1 V to 0 V). At slower scan rates there is more time to establish photocurrent amplification but consequently the hysteresis increases since the time between backward and forward scans is larger. We “probe the tip” of the transient overshoot by choosing the right scan rate. This way it is possible to achieve nearly hysteresis-free J-V curves. When J-V scans are performed at a lower rate, the device has sufficient time to reach the “post-overshoot” region. Hence the hysteresis becomes higher and now it is the backward scan, which yields the higher current value (contrary to the faster measurements).

Following this reasoning, we can explain the shape of the light-intensity dependent J-V curves presented in FIG. 26 under reverse bias and slow scan rates. We have shown that the response of the device to the varying voltage becomes slower when the intensity of the incident illumination is higher. Thus, the hysteresis is lower for larger intensities analogously to the lower hysteresis for intermediate scan rates. This behavior is a consequence of the effect of photogenerated charges on the slow process in the device.

Finally, we measured J-V characteristics of the device following 60 s of pre-conditioning at different potentials (FIG. 27(c)). Following the demonstration in FIG. 27(a) that the device does not have enough time to establish photocurrent amplification during a very fast scan, we employed 100 V s⁻¹ scan rate (40 ms for the complete scan) in order to not allow the slow process to dominate the response of the device.

When the scan is preceded with conditioning at −1 V for 60 s (red curve), we observe high photocurrent amplification under reverse bias conditions. Since the contribution of the slow process on the 40 ms timescale is still not negligible, the forward and backward scans do not overlap. Scanning in forward direction, the J-V curve is linear between −1 V and −0.6 V, which is an indication of photoconductivity as the mechanism responsible for photocurrent amplification. FIG. 27(d) shows how the dJ/dV slope in this linear regime depends on light intensity. The conductivity of the sample is found to be directly proportional to light intensity which is another indication of photoconductivity. However, when plotted in logarithmic scale the relationship is evidently linear only when constant, dark conductivity is subtracted. We note that the response of the detector saturates beyond 0.72 mW cm⁻² illumination intensity. This value is consistent with that shown in FIG. 24 (0.53 mW cm⁻²) for corresponding operating conditions.

### Temperature Dependence

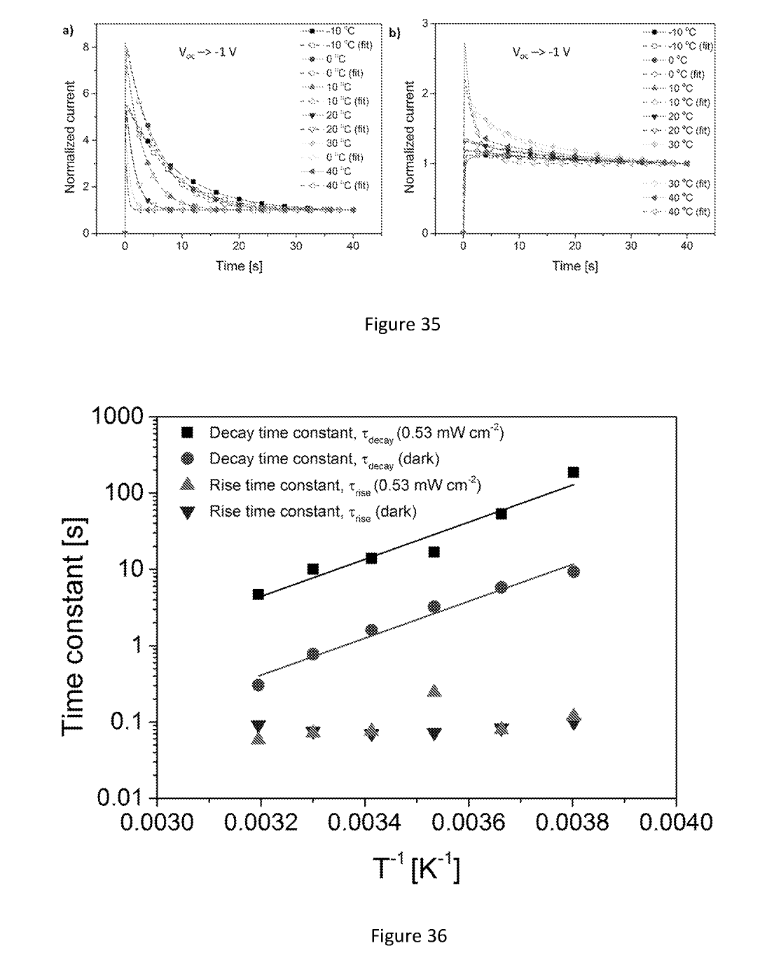

To further analyze the origin of the slow response times, we perform J-V and transient measurements as a function of temperature. FIG. 28(a) and (b) show how the response of the device to a potential step from V_{oc} to −1 V varies at temperatures between −10° C. and 40° C. (V_{oc} under 0.53 mW cm⁻² illumination varied with temperature from 150 mV at −10° C. to 50 mV at 40° C.). We investigated the effect of temperature on the dynamics of the device by again fitting the data with the two exponentials model as presented in equation (3) (FIG. 35 and FIG. 36). While the influence of temperature on the current rise time constant was not fully conclusive, we have found that the current decay becomes considerably slower at lower temperatures both in the dark and under illumination (FIG. 28(c)).

Combined analysis of three independent datasets has revealed an Arrhenius-type relationship. Independently of illumination, we derived an activation energy of 420±90 meV for the slow process responsible for the current decay. This value is consistent with the recently reported activation energy for the movement of iodine defects in CH₃NH₃PbI₃.^{[34, 35, 38]}

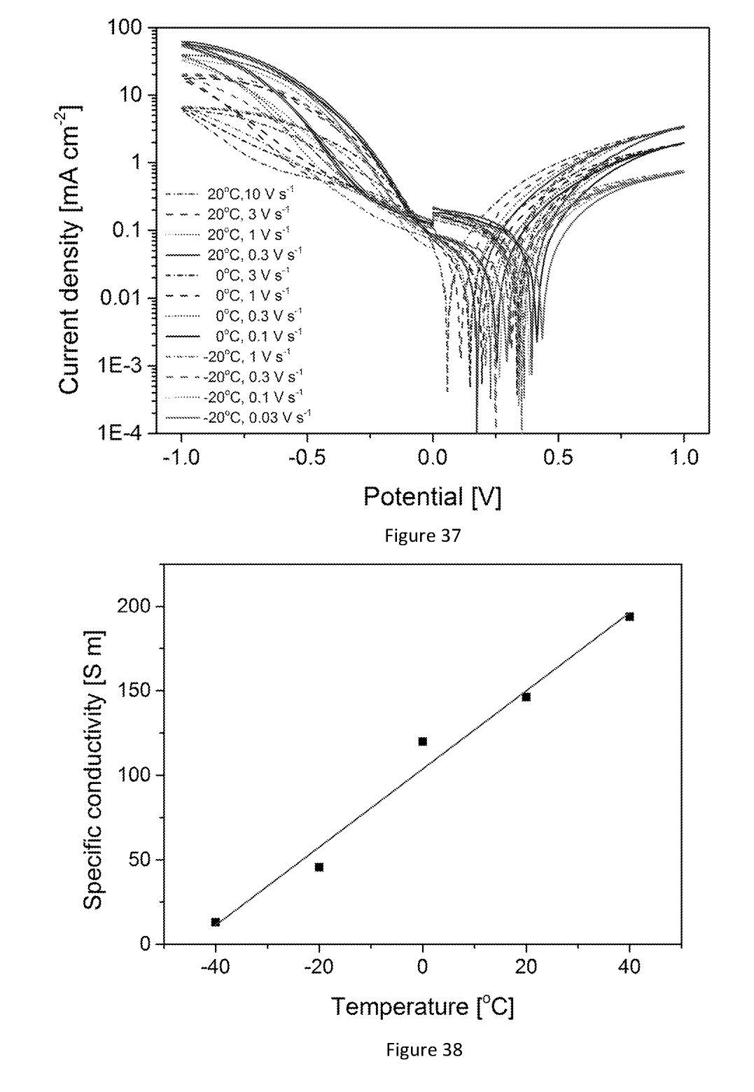

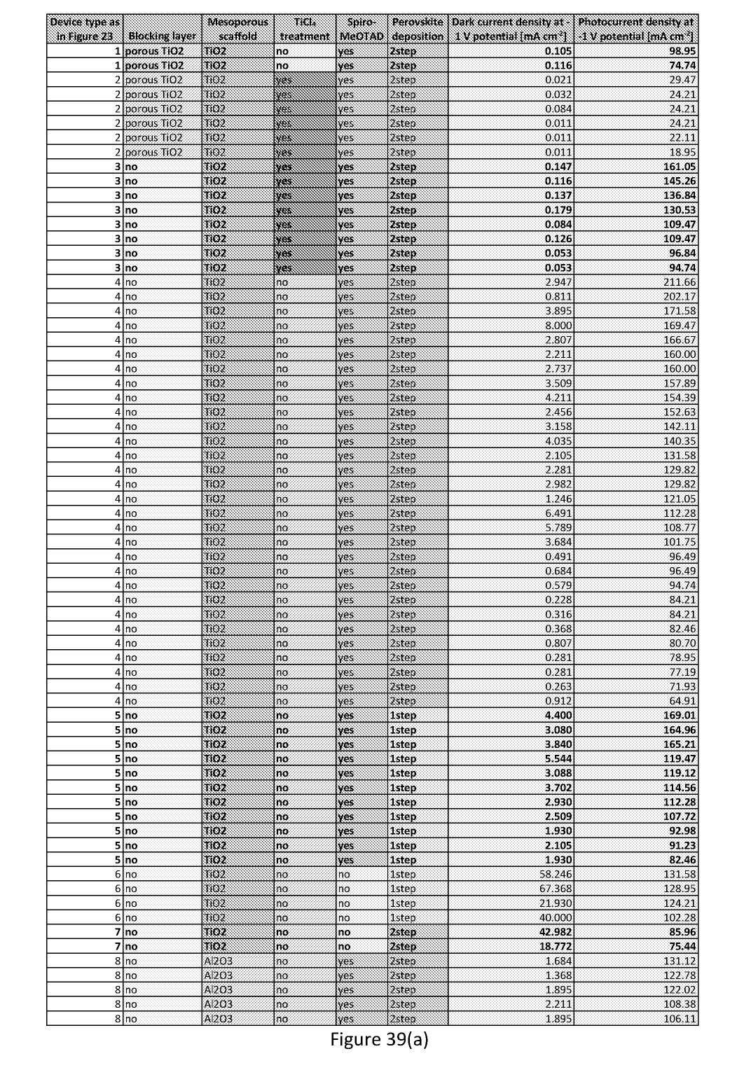

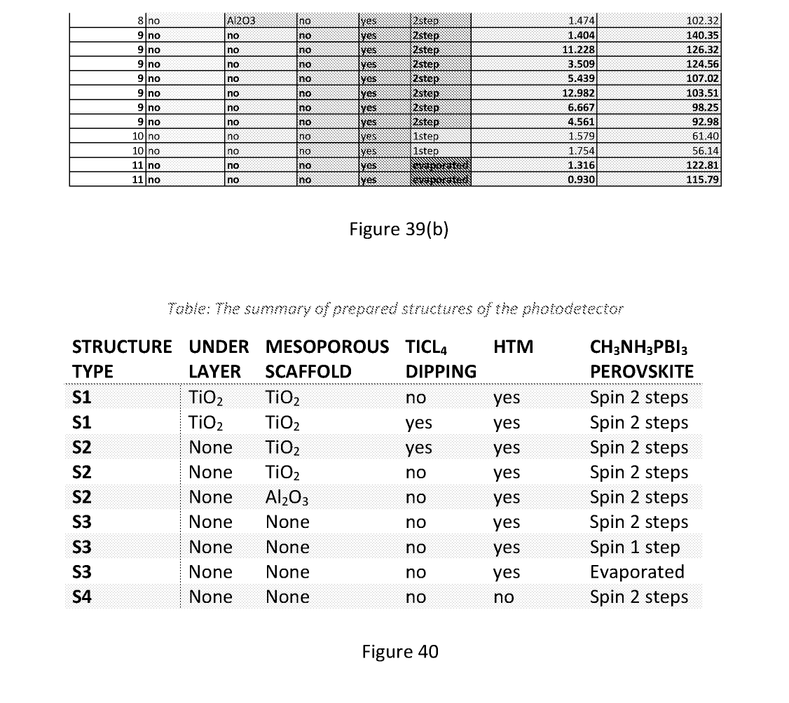

Subsequently, we observed a strong temperature effect on the J-V characteristics of the perovskite photodetector (FIG. 37). In reverse bias direction, photocurrent amplification is found to be heavily dependent both on scan rate and on temperature. On the other hand, while the J-V characteristics in forward direction are less influenced by the scan rate, the influence of temperature is even more pronounced. The latter is likely due to the reduced conductivity of Spiro-MeOTAD 11 at lower temperatures (FIG. 38).

Interestingly, in reverse direction almost identical (rate-dependent) J-V curves can be obtained when simultaneously changing the scan rate and the temperature (FIG. 28(d)). We have found that decreasing the temperature by 20 K is equivalent to performing the J-V scans approximately 3 times faster (see FIG. 37 for more examples). This proves once again that the shape of the reverse J-V curve describing photocurrent amplification is mainly governed by a temperature-activated slow process. This observation is consistent with the effect of temperature on the transient behavior. Using a first order approximation rate ∝ exp(−Eₐ/kT), we determine the activation energy to be between 300 and 400 meV, which is close to the value found above.

In summary, we have found that:

Direct contact between FTO (electrode) 3/perovskite 7 is essential for the device to exhibit photomultiplication.

Photomultiplication is a consequence of photoconductivity of the perovskite 7 CH₃NH₃PbI₃

Photocurrent amplification is enabled by a slow processes with time constants on the order of seconds and it is established by biasing the device in reverse direction

The conductivity of the device is directly proportional to illumination intensity and the response of the device becomes slower under illumination

The device reacts slower at lower temperatures and similar J-V curves can be obtained by simultaneously changing scan rate and temperature in a controlled way.

### Discussion of Operation Mechanism

The characteristics of the photodetector are dominated by processes that occur on the time scale of seconds and that are strongly temperature-activated. These observations coincide with results from studies on the J-V hysteresis in perovskite solar cells. Recently, clear evidence has been presented that links the hysteresis and the slow dynamics to the movement of ionic species within the material.^{[34, 35, 37, 39]} Iodine defects (interstitials and vacancies) were shown to have the lowest formation and activation energies for ionic point defects that are suggested to be the mobile species in CH₃NH₃PbI₃.^{[40]}

Guided by these results, we propose a model that can describe the photomultiplication effect in the photodetector 1 of the present invention.

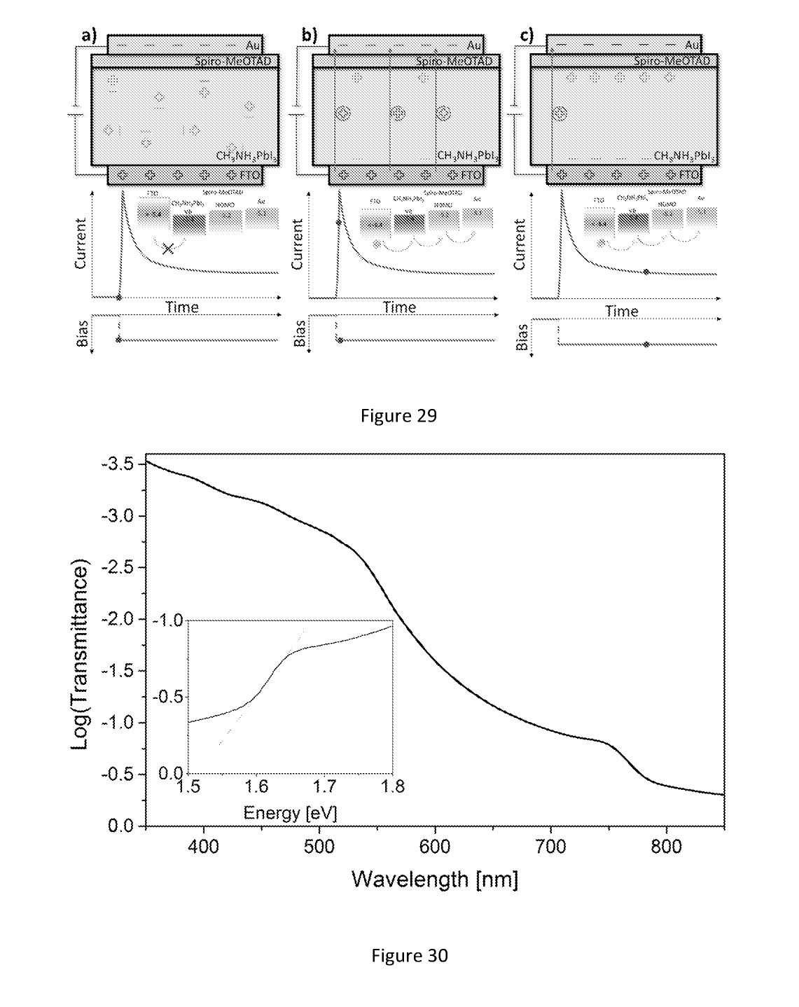

FIG. 29 visualizes how the transient current response to a step-change in potential (from 0 V in negative direction) arises due to the movement of mobile ionic species. When the device is kept in the dark, immediately after reverse bias is applied, an (additional) electric field is established across the device but current does not flow due to the unfavorable alignment of FTO (electrode 3) work function and CH₃NH₃PbI₃valence band (FIG. 29(a)). Mobile ionic species in CH₃NH₃PbI₃respond to the established electric field and travel towards the respective interfaces where they start to “pile up”. The accumulation of negative ions at CH₃NH₃PbI₃/ FTO interface causes a downshift of the FTO work function, which enables hole injection into CH₃NH₃PbI₃and results in a flow of dark current across the device (FIG. 29(b)). However, as large amount of ions accumulate at the interfaces, they screen the electric field in the perovskite, which results in the decrease of dark current down to an equilibrium value (FIG. 29(c)).

The effect of temperature on the transient behavior of the detector expresses itself as a modulation in dynamics. We have shown that the time constant of the current decay increases with temperature following an Arrhenius-type relationship (FIG. 36). This is caused by faster diffusion of ionic species at higher temperatures.

Under illumination additional screening effects and interactions of ionic defects with photogenerated charges have to be taken into account. The presence of this additional photoinduced charge can effectively reduce the electric field in the perovskite layer and hence the driving force for ionic species to move; therefore resulting in slower response times with increased light intensity (FIG. 27(b)). Alternatively, photogenerated charges can compensate the ionic charge accumulated at the interfaces.

When the device is kept under constant, reverse bias (past the photocurrent amplification onset) and the light is switched-on, photogenerated charges are attracted to the respective electrodes by the electric field, which is largely screened by the accumulated ions. The transit time of electrons is assumed to be longer than that of holes,^{[41]} which results in fast hole collection and multiple re-injection before the electrons are collected. This way photomultiplication is obtained and thus the device behaves similar to a photoconductor. Additionally, photogenerated charges establish an electric field, which is opposite to the field applied across the device. This induces the diffusion of ions away from the interface, which reduces the screening and results in a slow current increase. Under low reverse operating voltage, a large amount of ions is able to diffuse away from the interface, which in turn results in unfavorable conditions for hole inj ecti on.

When the light is switched-off, the relatively low density of ions at the interfaces leads to lower screening and a long-lived rise in injection current from the contacts as compared to the pre-illumination state (FIG. 25(c)). The device needs some time to return to pre-illumination state. Essentially, the mechanism responsible for the remnant large injection injection current after light is switched-off is the same as the one shown in FIG. 29. The effect is more pronounced when the device is operated under higher reverse bias, since the electric field remains largely unscreened and hole injection is more efficient.

### Experimental Section

### Blocking Layer

FTO-patterned glass 3 (Nippon sheet glass, NSG 10Ω) was cleaned in an ultrasonic bath containing Hellmanex solution for 20 min, and subsequently in isopropanol. This was followed by a UV ozone treatment for 10 min. For devices employing a spin-coated BL, a 0.15 M titanium diisopropoxide bis(acetylacetonate) solution (in ethanol) was spin-coated on the FTO at 1,000 r.p.m. for 10 s and 2,000 r.p.m. for 30 s. This was followed by drying at 125° C. for 5 min and then annealing at 500° C. for 15 min to produce a layer of about 30 nm in thickness.

The 30 nm-thick TiO₂ compact BL was deposited by spray-pyrolysis of diluted titanium diisopropoxide bis(acetylacetonate) (TAA) solution (Sigma-Aldrich) at an FTO substrate at 450° C. The solution for spray-pyrolysis was prepared by mixing 1 ml of TAA (30% in 2-propanol) and 25 ml of ethanol.

1 to 3 nm-thick TiO₂ compact BL was deposited by atomic layer deposition (ALD) on top of MP TiO₂ Scaffolds.

Mesoporous Scaffold 13

The TiO₂ and Al₂O₃ solutions were prepared by dispersing 1 g and 2 g of paste (Dyesol) respectively in 10 ml ethanol and stirring them overnight before use. The solutions were sonicated for 5 min and then spin-coated on the substrates at 2,000 r.p.m. for 10 s. The films were dried at 125° C. for 10 s and then annealed at 550° C. for 30 min. This resulted in scaffold thickness of around 100 nm.

TiCl₄ Treatment

An optional TiCl₄ treatment was performed by immersing the as-prepared scaffolds in a 0.15 M aqueous TiCl₄ solution at 70-80° C. for 30 minutes and then washing them with deionized water and drying. The films were then annealed at 500° C. for 20 min.

CH₃NH₃PbI₃Layer 7

CH₃NH₃PbI₃films were deposited via several different methods.

2-step spin-coating: The films were prepared under ambient air atmosphere. 1 M PbI₂ solution was prepared by dissolving 462 mg of PbI₂ (Sigma-Aldrich) in 1 ml N,N-dimethhylformamide (DMF) under stirring at 70° C. The hot solution (30 μL) was loaded onto the substrate (10 s loading time) and then spin-coated at 3,000 r.p.m. for 5 s and 6,000 r.p.m. for 5 s. Subsequently, the films were transferred to a hotplate at 100° C. for 10 min. After cooling down to room temperature, 200 μL of 0.044 M CH₃NH₃I solution (in isopropanol) was loaded onto the substrate (30 s loading time) and spun at 3,000 r.p.m. for 20 s and dried at 100° C. for 5 min.

1-step orthogonal spin-coating: The films were deposited in a nitrogen-filled glove box. A 1.1 M precursor solution of CH₃NH₃PbI₃was prepared by dissolving stoichiometric amounts of PbI₂ and CH₃NH₃PbI₃ in dimethylsulfoxide (DMSO). The precursor solution was spin-coated on MP TiO₂ scaffold at 1,000 r.p.m. for 10 s, immediately followed by 6,000 r.p.m. for 30 s. 10 s before the end of the spin-coating program, chlorobenzene was dropped on the spinning substrate. The substrate was then heated at 90° C. for 1 h.

Evaporation: The evaporation was performed in a vacuum chamber. The perovskite film was co-evaporated from PbI₂ and CH₃NH₃I₃ sources through a shadow mask. Both precursors were heating simultaneously to their corresponding sublimation temperatures and the perovskite film was deposited at a substrate placed above the sources.

Hole Transporting Layer 11 and Backside Electrode 4

A 70 mM spiro-MeOTAD solution was prepared by dissolving 72.3 mg of spiro-MeOTAD in 1 ml of chlorobenzene to which 28.8 μl of 4 -tent-butyl piridine and 17.5 μl of 1.8 M lithium(trifluoromethanesulfonyl)imide solution in acetonitrile (Li-TSFI) were added. The hole transporting layer 11 was prepared by spin-coating the as prepared spiro-MeOTAD solution at 4,000 r.p.m. for 30 s. Finally, 80 nm of gold 4 was thermally evaporated through a shadow mask to complete the device 1.

Device Characterization

The absorption spectrum of the devices was measured using a Hewlett Packard HP 8453 spectrometer. Current-voltage characteristics of the devices were recorded using BioLogic SP200 potentiostat. The source of monochromatic light was a monochromator-filtered xenon lamp. Neutral density filters were used to attenuate the light and a mechanical chopper was used to control the sample illumination. The 100 mW cm⁻² white light was generated by an array of white LEDs. A heating/cooling sample holder employing a Peltier element was built in order to control the temperature of devices. A thermocouple was used for temperature feedback. The geometry was arranged so that the thermocouple was placed between the Peltier element and the backside of the device. A 0.5 mm-thick thermal pad separated the device and the thermocouple.

We have fabricated high-gain, low-voltage CH₃NH₃PbI₃ photodetectors 1 in various architectures. We observed photomultiplication in all structures having direct contact of FTO and perovskite, i.e. devices with either a porous 5 or without any TiO 2 hole blocking layer.

Devices based on FTO/TiO₂ MP scaffold/CH₃NH₃PbI₃/Spiro-MeOTAD HTM/Au showed the highest responsivity of 208 A W⁻¹ under 550 nm illumination, which corresponds to an IPCE of 47,000%. These high values of photomultiplication were reached for light intensities in the range of 0.5-80 μW cm⁻² when the device was biased in reverse (−0.6 V).

During J-V scans in the potential range of −1 V and 1 V a strong dependence of the current response on scan rate and pre-conditioning was observed, showing the highest current values with least hysteresis at moderate scan rate (30 mV s⁻¹). This observation is explained by a slow process in the time scale of seconds found when studying the transient current response upon changing illumination intensity or applied voltage. Having performed temperature dependent studies, we observed a strong dependence of the response time on temperature, yielding an activation energy of 420±90 meV for the slow process. As the values for activation energy and response time are characteristic for ionic motion in these perovskite materials, we develop a model based on ion migration that can explain the observed transients and the photomultiplication. Essential is the pile-up of negative ionic charge at the FTO/perovskite interface under reverse bias. This charge lowers the FTO work function allowing for direct hole injection into the perovskite valence band. Due to an overall increase in conductivity, the hole current is enhanced upon illumination, and the device behaves similar to a photoconductor.

These results on the performance of our photodetector advantageously encourage the application of CH₃NH₃PbI₃ for low-cost, and highly sensitive photodetectors with high gain.

### Supporting Information

Absorption spectrum of CH₃NH₃PbI₃, response of the device at short-circuit conditions to illumination of different wavelength and intensity, transient on-off response of the detector, fitted transient response to a potential step and associated time constants, simultaneous temperature and scan rate influence on J-V characteristics of the device, conductivity of Spiro-MeOTAD as a function of temperature and a table showing all experimental conditions and performance of devices presented in FIG. 22(c).

CH₃NH₃PbI₃ is shown to possess a broadband absorption spectrum stretching the entire visible range with the absorption edge around 780 nm (1.59 eV; FIG. 30). The contribution below the absorption edge is caused by strong scattering by the rough perovskite film.

The response of the detector at short circuit conditions was found to be linear with respect to illumination intensity within the range of interest (FIG. 31). The variation in photoresponse caused by using light of different wavelengths is reflected in respective responsivity values obtained under illumination with different wavelengths.

The on-off behavior of the photodetector was examined by shining 120 s-long pulses of 0.53 mW cm⁻², 550 nm monochromatic light (FIG. 32). The time between the pulses was 60 s. The time that it takes the device to switch between 10% and 90% of the saturation current (with dark current subtracted) after light is switched-on is termed rise time, tnse. Consequently, fall time, tfan describes the transition from 90% to 10% of the response after the light is switched-off.

The photodetector is characterized by rise and fall times on the order of several seconds, which result in sub-Hz bandwidth. The pattern consists of a fast response, which is followed by a slow saturation or decay. The unusually slow response of the device is ascribed to slow processes within the perovskite, which is consistent with the idea of the movement of ionic species.

The current response of the device when it is subjected to a potential step change from V_{oc} to −1 V was modelled with two exponential terms:

J(t)=A₁e⁻^{^{t}}^{/τ}^{ᵣᵢₛₑ}+A₂e⁻^{^{t}}^{/τ}^{_{decay}}+B (S1)

The negative term is responsible for the initial rise in current, while the positive term is responsible for its subsequent decay. FIG. 33 shows how the model fits the experimental data and FIG. 34 shows how the current decay and rise time constants depend on the illumination intensity. One can see that at higher illumination intensities, the current decay becomes slower. The decay time constant is related to the illumination intensity through a power law, while no apparent influence of illumination intensity on the current rise time constant was found.

FIG. 35 shows the transient current response of the device when it is subjected to a potential step change from V_{oc} to −1 V. The recorded data is fitted to the model presented in equation (S1).

FIG. 36 shows how the current decay and rise time constants depend on temperature. One can see that at lower temperatures the current decay becomes slower. The decay time constant is related to the temperature through an Arrhenius-type relationship. No apparent influence of temperature on the current rise time constant was found.

FIG. 37 present the simultaneous temperature and scan rate dependence on J-V characteristics of photodetector. With respect to the behavior under reverse bias conditions, it is found that decreasing the temperature by 20 K is equivalent to increasing the scan rate by approximately 3 times.

FIG. 38 presents the specific conductivity of Spiro-MeOTAD film sandwiched between FTO and gold electrodes.

Additionally, results will now be illustrated that show that devices fabricated with a porous under layer 5 (or even without any) and a mesoporous metal oxide scaffold 13, where perovskite 7 is in direct contact with fluorine-doped tin-dioxide (FTO) coated glass (electrode 3), can be operated as high-performance photodetectors as well as solar cells with still a decent power conversion efficiency.

The interface between the perovskite 7 and the FTO 3 shows rectifying behavior. Reverse biasing of such solar cell allows to derive information on the valence-band position of perovskite.

Under reverse bias strong photocurrent amplification is observed, permitting the cell to work as a high-gain, low-voltage photodetector. At already 0.6 V reverse bias the photodetector is characterized by a high amplification response across the visible spectrum (350-750 nm). External quantum efficiency of the detector exceeds 30,000% with responsivity of more than 150 A/W (at low light intensities <50 μW/cm²). This translates to a gain of over 500 and it is achieved at relatively high active area of the device −0.25 cm². This performance is considerably higher than that of organic, hybrid or even many inorganic devices reported so far. For comparison, a conventional high-gain avalanche photodiode operated at several hundreds of volts may have a responsivity of about 60 A/W. The performance of the photodetector is heavily dependent on incident light intensity favoring lower irradiation. These results indicate that perovskite materials are promising candidates for low-cost, low-voltage and high-gain photodetectors operating across a broad visible spectrum. Due to their tuning ability of the bandgap by exchanging the A, B or X side of the ABX₃ crystal this material opens the possibility to adjust the absorption edge further into the red or blue.

FIG. 40 present a table that summarizes the prepared structures S1, S2, S3 and S4 of the photodetector. Structure S1 corresponds to the structure illustrated in FIG. 10(a), structure S2 corresponds to the structure illustrated in FIG. 12(a), structure S3 corresponds to the structure illustrated in FIG. 11 and structure S4 corresponds to the structure illustrated in FIG. 12(c).

The above photodetector type is fabricated on a transparent conductive oxide-coated substrate 3. The porous (if any) under-layer 5 is made by spin-coating TiO₂ precursor followed by a high-temperature temperature sintering. Optionally, the under-layer 5 is dipped in a solution of TiCl₄ followed by another sintering process.

The surface-increasing scaffold 13 (if any) is fabricated by spin-coating a solution of inorganic nanoparticles (conductive or non-conductive) followed by high-temperature sintering. Optionally, the scaffold is dipped in a solution of TiCl₄ followed by another sintering process.

The perovskite absorber layer 7 can be prepared by several ways: thermal evaporation of perovskite precursors or spin coating of the perovskite precursors. The precursors can be mixed together or deposited sequentially. The spin coating is followed by a sintering process.

Hole transporting material, HTM 11, (if any) is spin coated from a solution of dissolved organic semiconductor.

The Au electrode 4 is thermally evaporated through a shadow mask.

All of the current-voltage measurements were performed with a 100 mV/s scanning velocity. The light intensity for the measurements under light was 100 mW/cm².

### Reference Fabrication Procedure

FTO-patterned glass was cleaned in first an ultrasonic bath containing Hellamex solution for 20 min and subsequently in one containing isopropanol. This was followed by a UV light treatment for 10 min.

Under-layer Deposition 5

The porous under-layer was fabricated by spin coating a 0.15 M titanium dispropoxide solution (in ethanol) on the FTO 3 at 1000 r.p.m. for 10 s and 2000 r.p.m. for 30 s. This was followed by drying at 125° C. for 5 min and then annealing at 500° C. for 15 min on a hotplate.

Surface-increasing Mesoporous Scaffold Deposition 13

The TiO₂ solution for fabricating the mesoporous surface-increasing scaffold was prepared by dispersing 1 g of Dyesol 30 NRT paste in 10 ml ethanol and stirring them overnight before use. The solutions were sonicated for 5 min and then spin-coated on the substrates at 2000 r.p.m. for 10 s. The films were dried at 125° C. for 10 s and then annealed at 550° C. for 30 min on a hotplate. This resulted in scaffold thickness of around 100 nm.

TiCl₄ Dipping

The TiCl₄ treatment was performed by dipping the as-prepared substrates in a 0.15 M aqueous TiCl₄ solution at 70-80° C. for 30 minutes and then washing them with deionized water and drying. The films were then annealed at 500° C. for 20 min on a hotplate.

CH₃NH₃PbI₃ Perovskite Deposition 7

The CH₃NH₃PbI₃ films were prepared under ambient air or argon atmosphere. 1 M PbI₂ solution was prepared by dissolving 462 mg of PbI₂ in 1 ml N,N-dimethhylformamide (DMF) under stirring at 70° C. The hot solution (30 μL) was loaded onto the substrate (10 s loading time) and then spin coated at 3000 r.p.m. at 5 s and 6000 r.p.m. for 5 s. Subsequently the films were transferred to a hotplate at 100° C. and sintered for 10 min. After cooling down to room temperature, 200 μL of 0.044 M CH₃NH₃I solution (in isopropanol) was loaded onto the substrate (30 s loading time) and spin coated at 3000 r.p.m. for 20 s and dried at 100° C. for 5 min on a hotplate.

Hole Transporting Material (HTM) Deposition 11

The 70 mM spiro-MeOTAD solution was prepared by dissolving 72.3 mg of spiro-MeOTAD in 1 ml of chlorobenzene to which 28.8 μL of 4-tent-butyl piridine and 17.5 of 1.8 M lithium(trifluoromethanesulfonyl)imide solution in acetonitrile (Li-TSFI) were added. The hole transporting layer was prepared by spin coating the as prepared spiro-MeOTAD solution at 4000 r.p.m. for 30 s.

Metal Electrode Evaporation 4

80 nm of gold was thermally evaporated with a thermal evaporator through a shadow mask to form the cathode. The evaporation was done at a rate of 0.01 nm s⁻¹ for the first 10 nm of gold and then at 0.1 nm s⁻¹ for the rest.

The structure of the device S1 is: FTO electrode 3, porous under-layer 5, surface increasing scaffold 13, perovskite absorber 7, hole transporting material (HTM) 11 and gold 4.

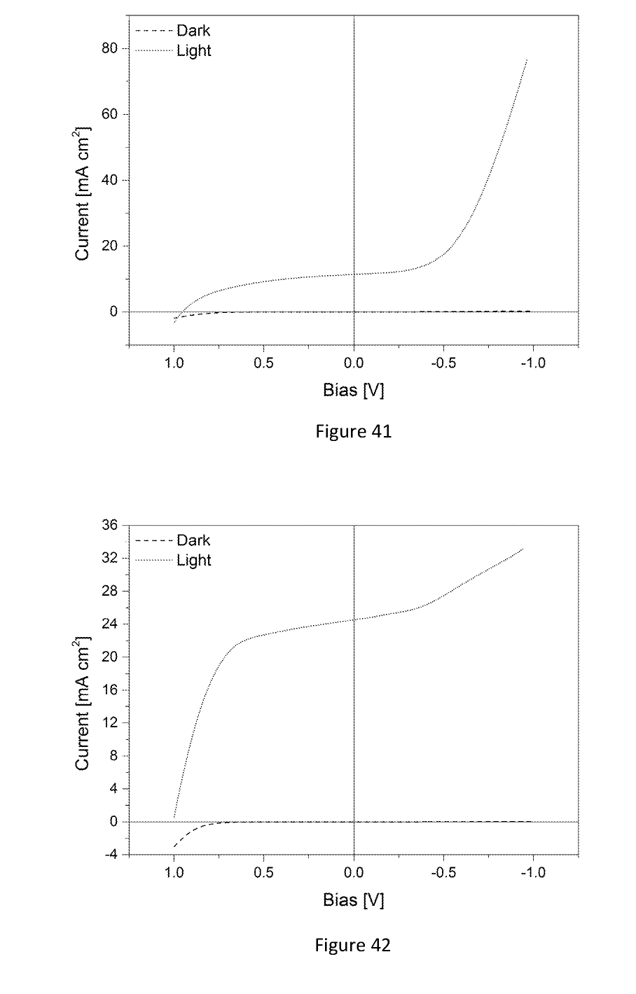

Devices with two different under-layers were fabricated: porous TiO₂ 5 and porous TiO₂ 5 dipped in a solution of TiCl₄. Low voltage reverse bias photocurrent amplification is produced by both S1 structures as can be seen in FIGS. 41 and 42.

The structure of the device S2 is: FTO electrode 3, surface increasing scaffold 13, perovskite absorber 7, hole transporting material (HTM) 11 and gold 4.

Devices with three different scaffolds 13 were fabricated: TiO₂, Al₂O₃ and TiO₂ dipped in a solution of TiCl₄. The deposition step relating to the under-layer 5 is omitted during the production of this device S2.

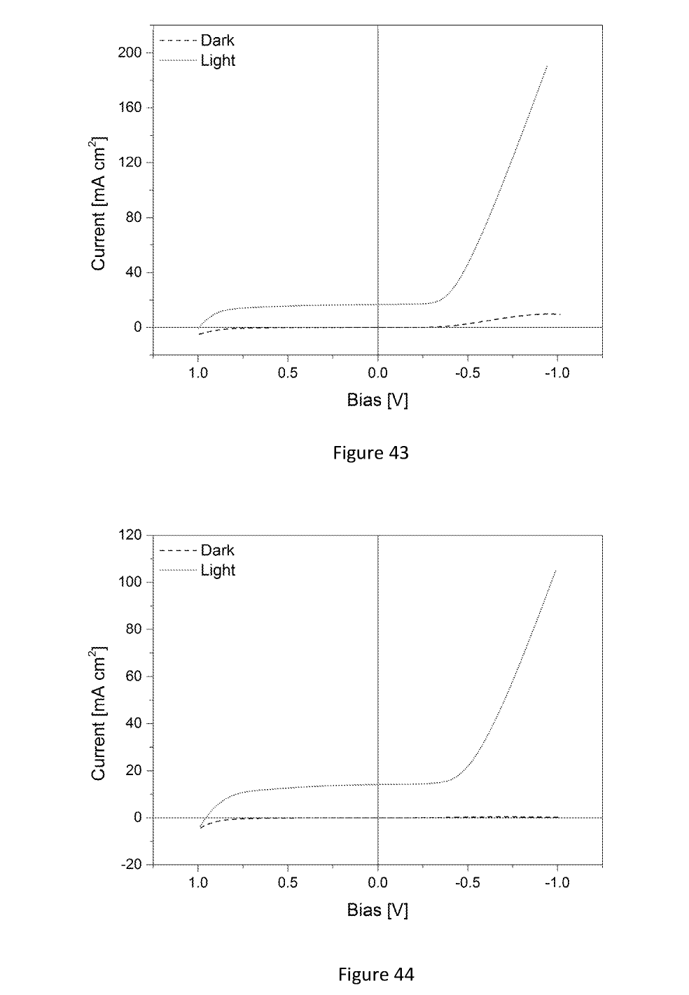

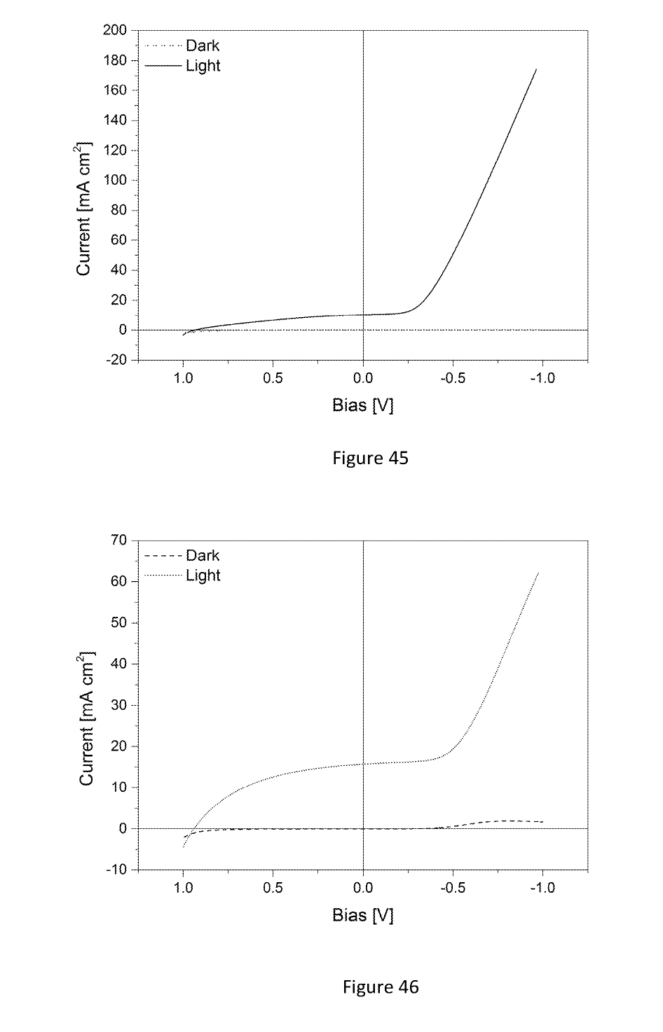

Low voltage reverse bias photocurrent amplification is produced by the S2 structures as can be seen in FIGS. 43 to 45.

The structure of the device S3 is: FTO electrode 3, perovskite absorber 7, hole transporting material (HTM) 11 and gold 4.

Perovskite layer 7 was prepared in several different ways: spin coating of mixture of perovskite precursors, sequential spin coating of perovskite precursors and evaporation of perovskite precursors. The deposition steps relating to the under-layer 5 and the scaffold structure 13 are omitted during the production of this device S3.

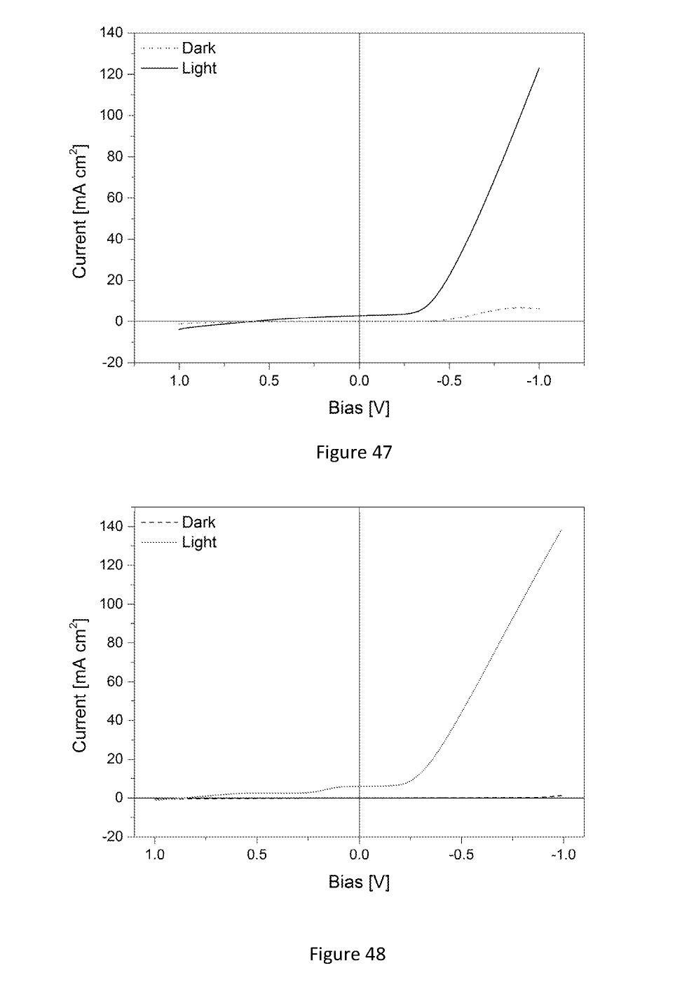

Low voltage reverse bias photocurrent amplification is produced by the S4 structures as can be seen in FIGS. 46 to 48.

The structure of the device S4 is: FTO electrode 3, perovskite absorber 7 and gold 4.

Fabrication was as in the reference procedure but:

The under-layer 5 deposition step is omitted

TiCl₄ dipping step is omitted

Surface-increasing mesoporous scaffold 13 deposition step is omitted

Hole transporting material (HTM) 11 deposition step is omitted

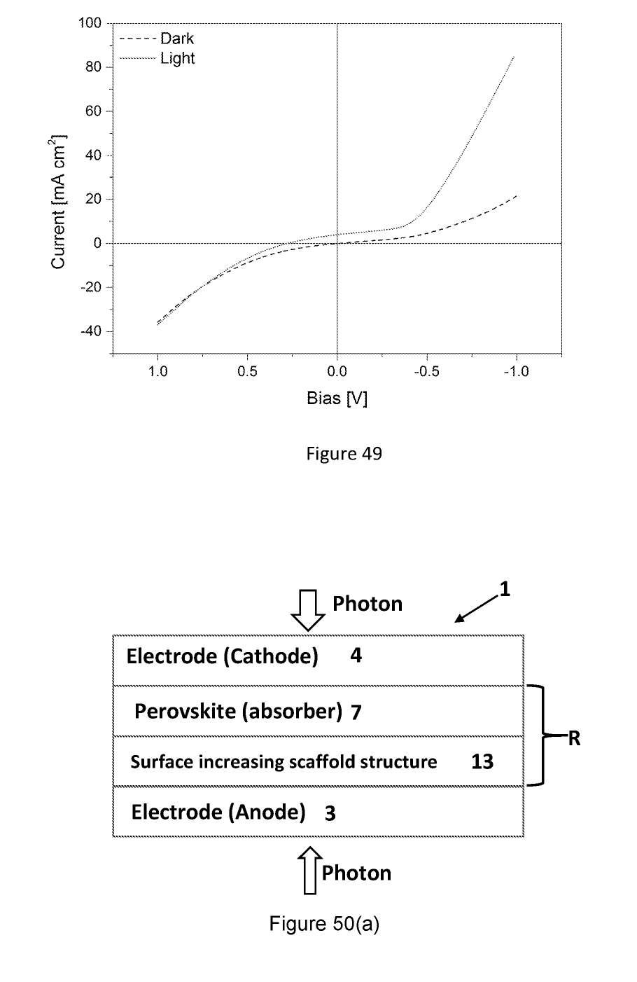

Low voltage reverse bias photocurrent amplification is produced by the S4 structure as can be seen in FIG. 49.

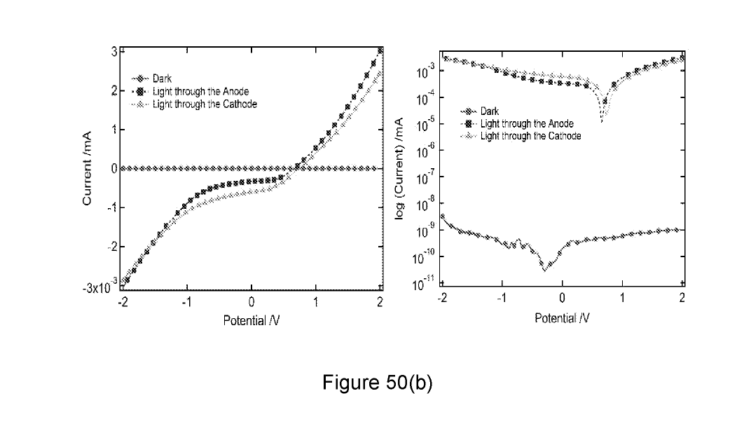

FIG. 50(a) shows a further device 1 according to the present invention. The active region R of the device 1 comprises or consists solely of a surface increasing scaffold structure (meso TiO₂) 13 and a perovskite layer 7. The first and second electrodes comprise or consist of the same material FTO. Consequently, both the first and second electrode are transparent to the incident light to be measured. This device 1 can thus receive incident light to be detected via one or both electrodes. FIG. 50(b) shows (left) the JV curve of this device with a transparent cathode and anode showing low voltage reverse bias photocurrent amplification. On the right the same JV curve is plotted in log scale.

A exemplary method for fabrication of the device of FIG. 50 is now described.

DyeSol NR30 TiO2 particle paste was diluted with terpineol in a 1:2-1:3 paste-to-solvent ratio. The diluted paste was printed with a 165-31 Y mesh to yield an about 300 nm thick mesoporous film on FTO (electrode). Dwelling time of the screen printed film was 10 min, then drying for 5 min at 125° C., followed by annealing at 550° C. for 30 min on a hotplate.

A Zirconia or Alumina paste is used to fabricate a second mesoporous layer (thickness from 100 nm to several um) from nanoparticles on top of the mesoporous TiO₂ film. In the example the second layer is printed (165-31 Y mesh) from Solaronix (Zr-Nanoxide ZT/SP). Dwelling time of the screen printed film was 10 min, then drying for 5 min at 125° C., followed by annealing at 550° C. for 30 min on a hotplate.

The “mixed perovskite” precursor solution contained FAI (1 M, Formamidiniumiodid), PbI2 (1.1 M), MABr (0.2 M, Methylammoniumiodid) and PbBr 2 (0.2 M) dissolved in anhydrous DMF:DMSO 4:1 (v:v). The perovskite solution was spin coated in a two steps program at 1000 and 6000 rpm for 10 and 30 s respectively. During the second step, 200 μL of chlorobenzene was poured on the spinning substrate 15 s prior to the end of the program. The substrates were then annealed at 100° C. for 1 h in a nitrogen filled glove box.

The second transparent electrode (cathode, FTO or ITO) was pressed against the fabricated layers, contacting the perovskite film.

Having described now the preferred embodiments of this invention, it will be apparent to one of skill in the art that other embodiments incorporating its concept may be used. This invention should not be limited to the disclosed embodiments, but rather should be limited only by the scope of the appended claims.

### REFERENCES

[1] J. Burschka, N. Pellet, S.-J. Moon, R. Humphry-Baker, P. Gao, M. K. Nazeeruddin, M. Grätzel, Nature 2013, 499, 316.

[2] N. J. Jeon, J. H. Noh, Y. C. Kim, W. S. Yang, S. Ryu, S. I. Seok, Nat Mater 2014, 13, 897.

[3] A. Kojima, K. Teshima, Y. Shirai, T. Miyasaka, Journal of the American Chemical Society 2009, 131, 6050.

[4] J.-H. Im, I.-H. Jang, N. Pellet, M. Gratzel, N.-G. Park, Nat Nano 2014, 9, 927.

[5] N. J. Jeon, J. H. Noh, W. S. Yang, Y. C. Kim, S. Ryu, J. Seo, S. I. Seok, Nature 2015, 517, 476.

[6] K. Wojciechowski, M. Saliba, T. Leijtens, A. Abate, H. J. Snaith, Energ Environ Sci 2014, 7, 1142.

[7] O. Malinkiewicz, A. Yella, Y. H. Lee, G. M. Espallargas, M. Graetzel, M. K. Nazeeruddin, H. J. Bolink, Nature Photonics 2014, 8, 128.

[8] D. Liu, T. L. Kelly, Nature Photonics 2014, 8, 133.

[9] Y. Guo, C. Liu, H. Tanaka, E. Nakamura, The Journal of Physical Chemistry Letters 2015, 5, 1748

[10] D. U, G. F. Dong, W. Z. U, L. D. Wang, Sci Rep-Uk 2015, 5.

[11] R. Dong, Y. Fang, J. Chae, J. Dai, Z. Xiao, Q. Dong, Y. Yuan, A. Centrone, X. C. Zeng, J. Huang, Adv Mater 2015, 27, 1912.

[12] X. Hu, X. D. Zhang, L. Liang, J. Bao, S. U, W. L. Yang, Y. Xie, Adv Funct Mater 2014, 24, 7373.

[13] Y. Lee, J. Kwon, E. Hwang, C. H. Ra, W. J. Yoo, J. H. Ahn, J. H. Park, J. H. Cho, Adv Mater 2015, 27, 41.

[14] H.-R. Xia, J. U, W.-T. Sun, L.-M. Peng, Chem Commun 2014, 50, 13695.

[15] Q. Lin, A. Armin, D. M. Lyons, P. L. Burn, P. Meredith, Adv Mater 2015, 27, 1969.

[16] Y. Fang, J. Huang, Adv Mater 2015, 27, 2804.

[17] S. Zhuo, J. Zhang, Y. Shi, Y. Huang, B. Zhang, Angewandte Chemie 2015, 127, 5785.

[18] L. Dou, Y. Yang, J. You, Z. Hong, W.-H. Chang, G. Li, Y. Yang, Nat Commun 2014, 5.

[19] H.-W. Chen, N. Sakai, A. K. Jena, Y. Sanehira, M. Ikegami, K.-C. Ho, T. Miyasaka, The Journal of Physical Chemistry Letters 2015, 6 , 2622.

[20] F. Li, C. Ma, H. Wang, W. Hu, W. Yu, A. D. Sheikh, T. Wu, arXiv preprint arXiv: 1502.03995 2015.

[21] Z.-K. Tan, R. S. Moghaddam, M. L. Lai, P. Docampo, R. Higler, F. Deschler, M. Price, A. Sadhanala, L. M. Pazos, D. Credgington, F. Hanusch, T. Bein, H. J. Snaith, R. H. Friend, Nat Nano 2014, 9, 687.

[22] F. Deschler, M. Price, S. Pathak, L. E. Klintberg, D.-D. Jarausch, R. Higler, S. Huttner, T. Leijtens, S. D. Stranks, H. J. Snaith, M. Atatüre, R. T. Phillips, R. H. Friend, The Journal of Physical Chemistry Letters 2014, 5, 1421.

[23] G. Xing, N. Mathews, S. S. Lim, N. Yantara, X. Liu, D. Sabba, M. Gratzel, S. Mhaisalkar, T. C. Sum, Nat Mater 2014, 13, 476.

[24] G. Xing, N. Mathews, S. Sun, S. S. Lim, Y. M. Lam, M. Grätzel, S. Mhaisalkar, T. C. Sum, Science 2013, 342, 344.

[25] W. S. Yang, J. H. Noh, N. J. Jeon, Y. C. Kim, S. Ryu, J. Seo, S. I. Seok, Science 2015, aaa 9272.

[26] T. Moehl, J. H. Im, Y. H. Lee, K. Domanski, F. Giordano, S. M. Zakeeruddin, M. I. Dar, L.-P. Heiniger, M. K. Nazeeruddin, N.-G. Park, The Journal of Physical Chemistry Letters 2014, 5, 3931.

[27] S. Donati, Photodetectors: Devices, Circuits, and Applications, Prentice Hall PTR, 2000.

[28] R. McIntyre, Measurement 1985, 3, 146.

[29] M. Liu, M. B. Johnston, H. J. Snaith, Nature 2013, 501, 395.

[30] H.-S. Kim, C.-R. Lee, J.-H. Im, K.-B. Lee, T. Moehl, A. Marchioro, S.-J. Moon, R. Humphry-Baker, J.-H. Yum, J. E. Moser, Sci Rep 2012, 2.

[31] M. Helander, M. Greiner, Z. Wang, W. Tang, Z. Lu, Journal of Vacuum Science & Technology A 2011, 29, 011019.

[32] D. A. Egger, E. Edri, D. Cahen, G. Hodes, The Journal of Physical Chemistry Letters 2015, 6, 279.

[33] R. H. Bube, C. T. Ho, Journal of Applied Physics 1966, 37, 4132.

[34] T. Y. Yang, G. Gregori, N. Pellet, M. Grätzel, J. Maier, Angewandte Chemie 2015, 127, 8016.

[35] E. T. Hoke, D. J. Slotcavage, E. R. Dohner, A. R. Bowring, H. I. Karunadasa, M. D. McGehee, Chemical Science 2015, 6, 613.

[36] E. Unger, E. Hoke, C. Bailie, W. Nguyen, A. Bowring, T. Heumüller, M. Christoforo, M. McGehee, Energ Environ Sci 2014, 7, 3690.

[37] W. Tress, N. Marinova, T. Moehl, S. Zakeeruddin, M. K. Nazeeruddin, M. Grätzel, Energ Environ Sci 2015, 8, 995.

[38] Y. Yuan, J. Chae, Y. Shao, Q. Wang, Z. Xiao, A. Centrone, J. Huang, Advanced Energy Materials 2015, 27, 1912.

[39] Z. Xiao, Y. Yuan, Y. Shao, Q. Wang, Q. Dong, C. Bi, P. Sharma, A. Gruverman, J. Huang, Nat Mater 2015, 14, 193.

[40] J. M. Azpiroz, E. Mosconi, J. Bisquert, F. De Angelis, Energ Environ Sci 2015, 8, 2118.

[41] Q. Dong, Y. Fang, Y. Shao, P. Mulligan, J. Qiu, L. Cao, J. Huang, Science 2015, 347, 967.

1-88. (canceled)

89. A device for room temperature reverse-bias operation photo-detection, the device comprising:
a planar first electrode extending in a planar direction;
a second electrode positioned above the first electrode in a direction substantially perpendicular to the planar direction; and
an active region sandwiched between the first and second electrode;
wherein the active region consists of:
a light absorbing perovskite; or
a light absorbing perovskite and a hole-transporting material; or
a light absorbing perovskite and a surface increasing scaffold structure; or
a light absorbing perovskite and a porous under-layer; or
a light absorbing perovskite, a surface increasing scaffold structure and a porous under-layer; or
a light absorbing perovskite, a hole-transporting material and a surface increasing scaffold structure; or
a light absorbing perovskite, a hole-transporting material and a porous under-layer; or
a light absorbing perovskite and an electron-transporting material layer; or
a light absorbing perovskite, an electron-transporting material layer and a surface increasing scaffold structure; or
a light absorbing perovskite, an electron-transporting material layer and a hole-transporting material; or
a light absorbing perovskite, an electron-transporting material layer, a surface increasing scaffold structure and a hole-transporting material; or
a light absorbing perovskite, a hole-transporting material, a surface increasing scaffold structure and a porous under-layer; and
wherein the light absorbing perovskite is in direct contact with at least one of the first and second electrodes.

90. The device according to claim 89, wherein the porous under-layer includes a plurality of hole conducting channels or a network of hole conducting channels inside the under-layer, the plurality of hole conducting channels or the network of hole conducting channels being in electrical communication with the first electrode and the light absorbing perovskite to permit hole conduction via the plurality of hole conducting channels or the network of hole conducting channels.

91. The device according to claim 89, wherein the porous under-layer includes a plurality of pores, a plurality of hole conducting channels or a network of hole conducting channels being delimited by a plurality of the pores.

92. The device according to claim 90, wherein the plurality of hole conducting channels or the network of hole conducting channels includes the light absorbing perovskite or the light absorbing perovskite and light absorbing perovskite preparation elements, and the light absorbing perovskite directly physically contacts the first electrode, or a light absorbing perovskite preparation element directly physically contacts the first electrode to form a rectifying contact with the first electrode.

93. The device according to claim 90, wherein the plurality of hole conducting channels or the network of hole conducting channels includes the light absorbing perovskite or the light absorbing perovskite and light absorbing perovskite preparation elements and the light absorbing perovskite is located at least within a carrier tunneling distance of the anode electrode, or a light absorbing perovskite preparation element is located at least within a carrier tunneling distance of the anode electrode.

94. The device according to claim 91, wherein the plurality of hole conducting channels or the network of hole conducting channels are formed in a plurality of pores.

95. The device according to claim 91, wherein the plurality of pores are filled or partially filled by the light absorbing perovskite, or the light absorbing perovskite and light absorbing perovskite preparation elements.

96. The device according to claim 89, wherein the porous under-layer is a non-compact structure or layer.

97. The device according to claim 89, wherein the light absorbing perovskite is provided on the surface increasing scaffold structure and is infiltrated through the surface increasing scaffold structure.

98. The device according to claim 89, wherein the electron transport material layer is porous and infiltrated by the light absorbing perovskite.

99. The device according to claim 89, wherein the active region consists of:
a porous under-layer provided on the first electrode,
a light absorbing perovskite provided on the under-layer, and
a hole-transporting material provided between the second electrode and the light absorbing perovskite.

100. The device according to claim 89, wherein the active region consists of:
a porous under-layer provided on the first electrode,
a surface increasing scaffold structure provided on the under-layer, and
a light absorbing perovskite provided on the surface increasing scaffold structure and between the second electrode and the surface increasing scaffold structure.

101. The device according to claim 89, wherein the active region consists of:
a porous under-layer provided on the first electrode, and
a light absorbing perovskite provided on the under-layer and between the second electrode and the porous under-layer.

102. The device according to claim 89, wherein the active region consists of:
a light absorbing perovskite provided on the first electrode, and
a hole-transporting material provided between the second electrode and the light absorbing perovskite.

103. The device according to claim 89, wherein the active region consists of:
a light absorbing perovskite provided between the first and second electrodes.

104. The device according to claim 89, wherein the active region consists of:
a hole-transporting material provided on the second electrode,
a light absorbing perovskite provided on the hole-transporting material and between the first electrode and the hole-transporting material.

105. The device according to claim 89, wherein the active region consists of:
a hole-transporting material provided on the second electrode,
a surface increasing scaffold structure provided on the hole-transporting material, and
a light absorbing perovskite provided on the surface increasing scaffold structure and between the first electrode and the surface increasing scaffold structure.

106. The device according to claim 89, wherein the active region consists of:
a hole-transporting material provided on the second electrode,
a light absorbing perovskite provided on the hole-transporting material, and
an electron transport material layer or porous under-layer provided on the light absorbing perovskite and between the first electrode and the light absorbing perovskite.

107. The device according to claim 89, wherein the active region consists of:
a hole-transporting material provided on the second electrode,
a surface increasing scaffold structure provided on the hole-transporting material,
a light absorbing perovskite provided on the surface increasing scaffold structure, and
an electron transport material layer or porous under-layer provided on the light absorbing perovskite and between the first electrode and the light absorbing perovskite.

108. The device according to claim 89, wherein the active region consists of:
a surface increasing scaffold structure provided on the second electrode,
a light absorbing perovskite provided on the surface increasing scaffold structure, and
an electron transport material layer or porous under-layer provided on the light absorbing perovskite and between the first electrode and the light absorbing perovskite.

109. The device according to claim 89, wherein the active region consists of:
a light absorbing perovskite provided on the second electrode, and
an electron transport material layer or porous under-layer provided on the light absorbing perovskite and between the first electrode and the light absorbing perovskite.

110. The device according to claim 89, wherein the device is a high photocurrent amplification or gain, low voltage photodetector.
